(19) United States
(12) Patent Application Publication
(10) Pub. No.: US 2022/0073817 A1
(43) Pub. Date: Mar. 10, 2022

(54) METHOD FOR PRODUCING QUANTUM DOT-CONTAINING FILM AND COMPOSITION FOR PRODUCING QUANTUM DOT-CONTAINING FILM

(71) Applicant: TOKYO OHKA KOGYO CO., LTD., Kanagawa (JP)

(72) Inventors: Yueh Chun LIAO, Kanagawa (JP); Takehiro SESHIMO, Kanagawa (JP); Kunihiro NODA, Kanagawa (JP)

(21) Appl. No.: 17/418,053

(22) PCT Filed: Dec. 24, 2019
(86) PCT No.: PCT/JP2019/050718

§ 371 Date: Jun. 24, 2021

(30) Foreign Application Priority Data
Dec. 25, 2018 (JP) 2018-241671

(51) Int. Cl. C09K 11/56; G03F 7/038; C09K 11/70; G03F 7/32

(52) U.S. Cl. CPC C09K 11/565; G03F 7/0382; B82Y 20/00; G03F 7/325; C09K 11/70

(57) ABSTRACT

Provided are: a method for producing a quantum dot-containing film enabling formation of a quantum dot-containing film exhibiting desired quantum yield; and a composition for producing a quantum dot-containing film suitably used for the method. In a method for producing a quantum dot-containing film using a composition including quantum dots (A) containing a chalcogenide as a surface material, a base component (C), and a solvent (S), a heating step to heat a quantum dot-containing film in an atmosphere with a lower oxygen concentration than air is conducted.

### TECHNICAL FIELD

The present invention relates to a method for producing a quantum dot-containing film and a composition for producing a quantum dot-containing film.

### BACKGROUND ART

An extremely small grain (dot) formed to confine electrons has been conventionally called a quantum dot, and the application thereof in a variety of fields has been investigated. Here, the size of one quantum dot is from several nanometers to tens of nanometers in diameter.

Such quantum dot can be used as a wavelength conversion material, since the quantum dot can change light-emitting fluorescent color (emission wavelength) (wavelength conversion) by changing the size thereof (changing band gap). Because of this, it has been diligently investigated that quantum dots are applied to a display element as a wavelength conversion material in recent years (see Patent Documents 1 and 2).

In addition, it has been investigated that an optical film including quantum dots is applied to various optical light-emitting elements and display elements. For example, it has been proposed that a quantum dot sheet including quantum dots dispersed in a matrix made of various polymeric materials is used as an optical film (see Patent Document 3). For example, when light rays emitted from a light source are allowed to pass through an optical film including quantum dots in elements to show an image using light emission of a light source such as a liquid crystal display element and an organic EL display element, green light and red light, which have high color purity, can be extracted by wavelength conversion. Therefore, the range of hue reproduction can be enlarged.
Patent Document 1: Japanese Unexamined Patent Application, Publication No. 2006-216560
Patent Document 2: Japanese Unexamined Patent Application, Publication No. 2008-112154
Patent Document 3: Korean Patent Application No. 10-2016-0004524

### DISCLOSURE OF THE INVENTION

### Problems to be Solved by the Invention

In order to produce a quantum dot-containing film containing dispersed quantum dots, a liquid composition including a base component such as a resin or a curable compound and a quantum dot is often used. However, in the case in which conventionally known dispersion liquid for producing a quantum dot-containing film is used, a quantum dot-containing film which exhibits desired quantum yield often can not be formed.

The present invention has been made in view of the above problem and an object of the present invention is to provide a method for producing a quantum dot-containing film enabling formation of a quantum dot-containing film exhibiting desired quantum yield; and a composition for producing a quantum dot-containing film suitably used for the method.

### Means for Solving the Problems

The present inventors have found that the above-mentioned problem can be solved by conducting a heating step to heat a quantum dot-containing film in an atmosphere with a lower oxygen concentration than air in a method for producing a quantum dot-containing film using a composition including quantum dots (A) containing a chalcogenide as a surface material, a base component (C), and a solvent (S), and accomplished the present invention. In more detail, the present invention can provide the followings.

A first aspect of the present invention is a method for producing a quantum dot-containing film using a composition comprising quantum dots (A), a base component (C) and a solvent (S),

wherein a material of surface of the quantum dots (A) comprises a chalcogenide,
a ligand can bound to the surface of the quantum dots (A), the solvent (S) comprises an organic solvent (S1) comprising a chalcogen element, and
the method comprising heating the quantum dot-containing film in an atmosphere with a lower oxygen concentration than air.

A second aspect of the present invention is a composition for producing a quantum dot-containing film comprising quantum dots (A), a base component (C) and a solvent (S), wherein a material of surface of the quantum dots (A) comprises a chalcogenide,

a ligand can bound to the surface of the quantum dots (A), and the solvent (S) comprises an organic solvent (S1) comprising a chalcogen element.

### Effects of the Invention

According to the present invention, a method for producing a quantum dot-containing film enabling formation of a quantum dot-containing film exhibiting desired quantum yield; and a composition for producing a quantum dot-containing film suitably used for the method can be provided.

### PREFERRED MODE FOR CARRYING OUT THE INVENTION

### «Method for Producing a Quantum Dot-Containing Film»

In a method for producing a quantum dot-containing film, a composition including a quantum dots (A), a base component (C) and a solvent (S) is used to produce the quantum dot-containing film. Such a method includes heating the quantum dot-containing film in an atmosphere with a lower oxygen concentration than air. a ligand can bound to the surface of the quantum dots (A). The ligand is a substance that binds to the surface of the quantum dots (A), not a material that makes up the surface of the quantum dots (A).

For the quantum dots (A), quantum dots whose surface material is made of a material containing chalcogenide are used. For the solvent (S), a solvent including an organic solvent (S1) comprising a chalcogen element is used. The quantum dot-containing film that exhibits desired quantum yield can be formed by forming a film using a composition including such a quantum dots (A) in combination with such a solvent (S) and then heating the film in an atmosphere with a lower oxygen concentration than air. Hereinafter, an atmosphere with a lower oxygen concentration than air is also simply referred to as “low oxygen concentration atmosphere”. Particularly, in the case in which a quantum dot-containing film is heated or exposed to light in oxygen-rich atmosphere such as air, a quantum dot-containing film that exhibits desired quantum yield often can not be formed. However, when the quantum dot-containing film is produced by the above method, even if the quantum yield is lowered due to heating or exposure of the quantum dot-containing film in an oxygen-rich atmosphere, the quantum yield can be recovered by heating the quantum dot-containing film in a low oxygen concentration atmosphere. This is probably due to the adhesion of the organic solvent (S1) comprising the chalcogen element to the quantum dots (A) contained in the quantum dot-containing film that exhibits lowered quantum yield. In the quantum dots (A) contained in the quantum dot-containing film that exhibits lowered quantum yield, it is thought that the chalcogenide on a surface is oxidized. By heating oxidized quantum dot, the quantum yield of the quantum dot-containing film is considered to be recovered to a high value, as a reaction to replace the oxygen in the quantum dots (A) with the chalcogen element between the organic solvent (S1) comprising the chalcogen element and the oxidized quantum dots (A) occurs by heating oxidized quantum dots (A) under low oxygen concentration atmosphere. The low oxygen concentration atmosphere is an atmosphere in which an oxygen concentration is lower than 200000 ppm, preferably 100000 ppm, and more preferably 1 ppm or more and 300 ppm or less. The low oxygen concentration atmosphere is exemplified by an inert gas atmosphere, a reduced pressure atmosphere and a vacuum atmosphere. Preferable low oxygen concentration atmosphere is exemplified by a nitrogen gas atmosphere, a forming gas atmosphere and a hydrogen gas atmosphere. Heating temperature under the low oxygen concentration atmosphere is preferably 110° C. or higher and 300° C. or lower, more preferably 110° C. or higher and 280° C. or lower, further preferably 120° C. or higher and 250° C. or lower, and particularly preferably 130° C. or higher and 200° C. or lower. Heating time under the low oxygen concentration atmosphere is preferably 5 minutes or longer and 1 day or shorter, more preferably 10 minutes or longer and 12 hours or shorter, and particularly preferably 20 minutes or longer and 1 hour or shorter.

Hereinafter, the composition used for producing the quantum dot-containing film, a method for producing the quantum dot-containing film before heating, which is provided for the heating step escribed above, and uses of the quantum dot-containing film will be described.

### <Composition>

As described above, the composition used for producing the quantum dot-containing film includes quantum dots (A), a base component, and a solvent (S). Such composition may be a photosensitive composition or a heat-sensitive composition that can be denatured by exposure or heating, or a composition that is not denatured by exposure or heating. The composition may be a photosensitive composition that can be patterned by photolithography method or a non-photosensitive composition to which patterning by photolithography method cannot be applied. When the composition used for forming the quantum dot-containing film has photosensitivity that allows application of patterning by photolithography method, as the constitution of the composition, other than the inclusion of quantum dots (A), the constitution of various conventionally known photosensitive compositions applied to patterning by the photolithography method can be adopted. When the composition used for forming the quantum dot-containing film is a photosensitive composition, the photosensitive composition may be a negative type composition that is insolubilized in a developing solution through light exposure, or a positive type composition that is solubilized in a developing solution through light exposure. A suitable typical example of the negative type composition is a composition containing an alkali-soluble resin as the base component (C), a photopolymerizable monomer, and a photopolymerization initiator as the curing agent (D) described below. A suitable typical example of the positive type composition is a composition containing an acid generator which generates an acid by irradiation of active rays or radioactive rays, and a resin for which solubility in alkali increases by action of acid as the base component (C). Hereinafter, essential and optional components that the composition may contain will be described.

### {Quantum Dots (A)}

The composition used for forming the quantum dot-containing film includes the quantum dots (A). As long as the quantum dots (A) are microparticles that function as quantum dots and the material of surface is a material containing chalcogenide, the structure and components of the quantum dots (A) are not particularly limited. The quantum dots (A) are a nanoscale material having particular optical characteristics according to quantum mechanics (quantum-confined effect described below), and commonly mean semiconductor nanoparticles. In the description, the quantum dots (A) also include quantum dots in which the surface of semiconductor nanoparticles is further covered to improve a luminescent quantum yield (quantum dots having a shell structure described below) and quantum dots which are surface-modified for stabilization. However, as mentioned above, in the specification of this application, the ligand and the like used for surface modification is assumed to be a different material from the quantum dots (A).

A chalcogenide is not particularly limited as long as it is a compound containing an inorganic element well-known as a component of a quantum dot and a chalcogen element. Here, the chalcogen elements contained in the chalcogenide are group 6B elements (old UIPAC) which are S, Se, and Te. The chalcogen elements are more preferably S and Se.

The structure of quantum dots (A) can be a homogeneous structure made of one compound, or a composite structure made of two or more compounds. In order to improve luminescent quantum yields of the above compounds, the structure of quantum dots (A) is preferably a core-shell structure in which the core is covered with one or more shell layers, and more preferably a structure in which the surface of a particle of the compound, a core material, is epitaxially covered with a semiconductor material. In the specification and claims of the present application, particles in the process of manufacturing quantum dots (A) of core-shell structure are not included in quantum dots (A).

When group II (group 2A and group 2B (old IUPAC))—group VI (group 6B (old IUPAC)) CdSe, for example, is used as a core material, ZnS, ZnSSe and the like are used as its covering layer (shell). The shell preferably has the same lattice constant as a core material has. A material combination in which the difference in the lattice constant between the core and shell is small is properly selected.

The quantum dots (A) are considered as semiconductor nanoparticles which absorb photons having energy larger than a band gap (a difference in energy between a valence band and a conduction band) and emit light with a wavelength depending on the particle diameter thereof. Elements contained in a material of the quantum dots (A) is exemplified by at least one selected from the group consisting of group II elements (group 2A and 2B (old IUPAC)), group III elements (especially group 3B (old IUPAC)), group IV elements (especially group 4B (old IUPAC)), group V elements (especially group 5B (old IUPAC)) and group VI elements (especially group 6B elements (old IUPAC)). Examples of preferred compounds or elements as materials for the quantum dots (A) includes group II-VI compounds, group III-V compounds, group IV-VI compounds, group IV elements, group IV compounds and combinations thereof.

Examples of group II-VI compounds include at least one compound selected from the group consisting of at least one compound selected from the group consisting of CdSe, CdTe, ZnS, ZnSe, ZnTe, HgS, HgSe, HgTe, MgSe, MgS and mixtures thereof; at least one compound selected from the group consisting of CdSeS, CdSeTe, CdSTe, ZnSeS, ZnSeTe, ZnSTe, HgSeS, HgSeTe, HgSTe, CdZnS, CdZnSe, CdZnSe, CdHgS, CdHgSe, CdHgSe, HgZnS, HgZnSe, HgZnSe, MgZnSe, MgZnS and mixtures thereof; and at least one compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof. All of these are chalcogenides containing at least one selected from S, Se and Te. Therefore, all of these can be used as materials for the surface of the quantum dots (A).

Among these, at least one compound selected from the group consisting of CdSe, ZnS, ZnSe, HgS, HgSe, MgSe, MgS and mixtures thereof; at least one compound selected form the group consisting of CdSeS, CdSeTe, CdSTe, ZnSeS, ZnSeTe, ZnSTe, HgSeS, HgSeTe, HgSTe, CdZnS, CdZnSe, CdHgS, CdHgSe, HgZnS, HgZnSe, MgZnSe, MgZnS and mixtures thereof; and at least one compound selected form the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof are preferable.

Examples of group III-V compounds include at least one compound selected from GaN, GaP, GaAs, GaSb, AlN, AlP, AlAs, AlSb, InN, InP, InAs, InSb and mixtures thereof; at least one compound selected from GaNP, GaNAs, GaNSb, GaPAs, GaPSb, AlNP, AlNAs, AlNSb, AlPAs, AlPSb, InNP, InNAs, InNSb, InPAs, InPSb, GaAlNP and mixtures thereof; and at least one compound selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

Examples of group IV-VI compounds include at least one compound selected from SnS, SnSe, SnTe, PbS, PbSe, PbTe and mixtures thereof; at least one compound selected from SnSeS, SnSeTe, SnSTe, PbSeS, PbSeTe, PbSTe, SnPbS, SnPbSe, SnPbSe and mixtures thereof; and at least one compound selected from SnPbSSe, SnPbSeTe, SnPbSTe and mixtures thereof. All of these are chalcogenides containing at least one selected from S, Se and Te. Therefore, all of these can be used as materials for the surface of the quantum dots (A). Among these, at least one compound selected from SnS, SnSe, PbS, PbSe, and mixtures thereof; at least one compound selected from SnSeS, SnSeTe, SnSTe, PbSeS, PbSeTe, PbSTe, SnPbS, SnPbSe and mixtures thereof; and at least one compound selected from SnPbSSe, SnPbSeTe, SnPbSTe and mixtures thereof; is preferable.

Examples of group IV elements include at least one compound selected from Si, Ge and mixtures thereof. Examples of group IV compounds include at least one compound selected from SiC, SiGe and mixtures thereof.

The quantum dots (A) preferably include a compound including Cd or In as a constituent from the viewpoint of fluorescence efficiency, and more preferably include a compound including In as a constituent when taking into account safety.

Specific suitable examples of quantum dots (A) of the homogeneous structure type not having a shell layer include AgInS₂ and Zn-doped AgInS₂. Examples of quantum dots (A) of the core-shell type include InP/ZnS, InP/ZnSSe, CuInS₂/ZnS, and (ZnS/AgInS₂) solid solution/ZnS. It should be noted that materials for quantum dots (A) of the core-shell type are described as (core material)/(shell layer material) in the above description.

A shell of the core-shell structure has preferably a multi-layer structure from the viewpoint of improvement of safety and a luminescent quantum yield and more preferably two layers. In a core-multilayer shell structure, the material of the core is preferably at least one compound selected from the group consisting of InP, ZnS and ZnSe, and more preferably includes InP. The proportion of InP included is 50% by mass or more and 100% by mass or less of the total mass of the core, preferably 60% by mass or more and 99% by mass or less, and more preferably 82% by mass or more and 95% by mass or less. In addition, the proportion of ZnS and/or ZnSe included is 0% by mass or more and 50% by mass or less of the total mass of the core, preferably 1% by mass or more and 40% by mass or less, and more preferably 5% by mass or more and 18% by mass or less.

In a multilayer shell structure, a material for the first shell is preferably one or more selected from ZnS, ZnSe and ZnSSe. The proportion of one or more selected from ZnS, ZnSe and ZnSSe included is for example 50% by mass or more and 100% by mass or less, preferably 75% by mass or more and 98% by mass or less, and more preferably 80% by mass or more and 97% by mass or less based on the total mass of the first shell. When a material for the first shell is a mixture of ZnS and ZnSe, the mixing ratio (mass ratio) is not particularly limited, and is 1/99 or more and 99/1 or less, and preferably 10/90 or more and 90/10 or less.

In a multilayer shell structure, the second shell is grown on the surface of the first shell. A material for the second shell is preferably equivalent to the material for the first shell. However, differences in the lattice constant with respect to the core differ from each material. That is, a case where 99% or more in the materials have the same quality is excluded. The proportion of one or more selected from ZnS, ZnSe and ZnSSe included is for example 50% by mass or more and 100% by mass or less, preferably 75% by mass or more and 98% by mass or less and more preferably 80% by mass or more and 97% by mass or less based on the total mass of the second shell. When a material for the second shell is a mixture of two selected from ZnS, ZnSe and ZnSSe, the mixing ratio (mass ratio) is not particularly limited, and is 1/99 or more and 99/1 or less, and 10/90 or more and 90/10 or less.

The first shell and the second shell in a multilayer shell structure have different lattice constants. A difference in the lattice constant between the core and the first shell for example is 2% or more and 8% or less, preferably 2% or more and 6% or less, and more preferably 3% or more and 5% or less. In addition, a difference in the lattice constant between the core and the second shell is 5% or more and 13% or less, preferably 5% or more and 12% or less, more preferably 7% or more and 10% or less, and further preferably 8% or more and 10% or less.

In addition, a difference in the lattice constant between the first shell and the second shell is for example 3% or more and 9% or less, preferably 3% or more and 7% or less, and more preferably 4% or more and 6% or less.

The quantum dots (A) by these core-multilayer shell structures can have an emission wavelength in a range of 400 nm or longer and 800 nm or shorter. The range of the emission wavelength is preferably 470 nm or longer and 650 nm or shorter, and particularly preferably 540 nm or higher and 580 nm or shorter.

Examples of the quantum dots (A) by these core-multilayer shell structures include InP/ZnS/ZnSe and InP/ZnSe/ZnS.

In addition, the quantum dots (A) may be surface-modified. Examples thereof include phosphorus compounds such as phosphine, phosphine oxide and trialkylphosphines; organic nitrogen compounds such as pyridine, aminoalkanes and tertiary amines; organic sulfur compounds such as mercaptoalcohol, thiol, dialkyl sulfides and dialkyl sulfoxides; higher fatty acids; and surface modifying agents (organic ligands) such as alcohols.

Two or more of the above quantum dots (A) may be used in combination. Quantum dots (A) of the core-(multilayer) shell type and quantum dots (A) of the homogeneous structure type may be used in combination.

The average particle diameter of the quantum dots (A) is not particularly limited as long as the particles can function as quantum dots. The average diameter of the quantum dots (A) is preferably 0.5 nm or more and 20 nm or less, more preferably 1.0 nm or more and 15 nm or less, and further preferably 2 nm or more and 7 nm or less. In quantum dots (A) of the core-(multilayer) shell type, the size of core is for example 0.5 nm or more and 10 nm or less, and preferably 2 nm or more and 5 nm or less. The average thickness of the shell is preferably 0.4 nm or more and 2 nm or less, and more preferably 0.4 nm or more and 1.4 nm or less. When the shell includes the first shell and the second shell, the average thickness of the first shell is for example 0.2 nm or more and 1 nm or less, and preferably 0.2 nm or more and 0.7 nm or less. The average thickness of the second shell does not depend on the average thickness of the first shell, and is for example 0.2 nm or more and 1 nm or less, and preferably 0.2 nm or more and 0.7 nm or less.

The quantum dots (A) having an average particle diameter within such range show a quantum-confined effect and function well as quantum dots, and moreover are easily prepared and have stable fluorescence characteristics. It should be noted that the average particle diameter of quantum dots (A) can be defined by, for example, applying a composition including the quantum dots (A) onto a substrate and drying the composition, removing a volatile component from a coating film and then observing the surface of the coating film with a transmission electron microscope (TEM). Typically, this average particle diameter can be defined as the number average diameter of circle equivalent diameters of particles obtained by image analysis of the TEM image.

The shape of quantum dots (A) is not particularly limited. Examples of the shape of quantum dots (A) include a spherical shape, a spheroid shape, a cylindrical shape, a polygonal shape, a disk shape, a polyhedral shape and the like. Among these, a spherical shape is preferred from the viewpoint of handleability and availability.

Because the characteristics as an optical film and wavelength conversion characteristics are good, the quantum dots (A) preferably include one or more selected from the group consisting of a compound (A1) having a fluorescence maximum in a wavelength range of 500 nm or higher and 600 nm or lower, and a compound (A2) having a fluorescence maximum in a wavelength range of 600 nm or higher and 700 nm or lower, and more preferably consists of one or more selected from the group consisting of the compound (A1) and the compound (A2).

A method for producing the quantum dots (A) is not particularly limited. Quantum dots produced by various well-known methods can be used as the quantum dots (A). As the method for producing the quantum dots (A), for example, a method in which an organometallic compound is thermally decomposed in a coordinating organic solvent can be used. In addition, the quantum dots (A) of the core-shell structure type can be produced by a method in which homogeneous cores are formed by reaction and then a shell layer precursor is allowed to react in the presence of dispersed cores to form a shell layer. In addition, for example, the quantum dots (A) having the above core-multilayer shell structure can be produced by the method described in WO 2013/127662. It should be noted that various commercially available quantum dots (A) can also be used.

### {Base Component (C)}

The composition includes a base component (C). The composition has film-forming properties by including the base component (C). The base component (C) is typically a resin material consisting of a polymer compound or a reactive low-molecular-weight compound that forms crosslinking in response to heat or light exposure to give a polymer compound. The resin material used as the base component (C) may contain a functional group that forms crosslinking in response to heat or light exposure. In other words, a thermosetting or photocurable resin may also be used as the base component (C). Further, the resin material used as the base component (C) may be a resin material that is cured by baking.

It is preferable that the base component (C) be a thermosetting or photocurable base component because a shaped body excellent in physical properties such as hardness and tensile elongation tends to be formed. Next, specific examples of the base component (C) are described in order.

### [Resin Material]

The resin material used as the base component (C) is described. The resin material may be curable or non-curable. A curable resin material will be described later.

### (Non-Curable Resin Material)

The non-curable resin material is not particularly limited as long as it is a non-curable resin material capable of giving the resulting composition with shapability such as film formation properties. Specific examples of the resin material include polyacetal resin, polyamide resin, polycarbonate resin, polyester resin (polybutylene terephthalate, polyethylene terephthalate, polyarylate and the like), FR-AS resin, FR-ABS resin, AS resin, ABS resin, polyphenylene oxide resin, polyphenylene sulfide resin, polysulfone resin, polyethersulfone resin, polyetheretherketone resin, fluorine-based resin, polyimide resin, polyamide imide resin, polyamide bismaleimide resin, polyetherimide resin, polybenzoxazole resin, polybenzothiazole resin, polybenzimidazole resin, silicone resin, BT resin, polymethylpentene, ultra high molecular weight polyethylene, FR-polypropylene, (meta)acrylic resin (polymethylmethacrylate and the like), polystyrene, and the like. Two or more of these resin materials may be used in combination.

The resin material described above is preferably dissolved in the composition. The resin material described above may be a suspension liquid such as a latex as long as the objects of the present invention are not inhibited.

### (Alkali-Soluble Resin)

When the composition for producing the quantum dot-containing film is a negative type composition, the composition preferably includes an alkali-soluble resin. The alkali-soluble resin is not particularly limited and may be a conventionally know alkali-soluble resin. This alkali-soluble resin may or may not have an ethylenically unsaturated double bond. In the present description, the alkali-soluble resin as referred to herein may be determined as follows. A solution of the resin having a resin concentration of 20% by mass (solvent: propylene glycol monomethyl ether acetate) is used to form a resin film having a thickness of 1 μm on a substrate, and immersed in an aqueous 2.38% by mass tetramethylammonium hydroxide (TMAH) solution for 1 min. When the resin was dissolved in an amount of 0.01 μm or more, the resin is defined as being alkali soluble.

For example, a resin obtained by reacting polyhydric acid anhydrides with reactants of epoxy compounds and unsaturated carboxylic acids can be used as the alkali-soluble resin having an ethylenically unsaturated group. As such a resin, a resin having constituent units derived from reactants of acrylic acids and constituent units derived from compounds represented by formula (c7) described later or glycidyl methacrylate described later or constituent units obtained by reacting above-described reactants with polyhydric acid anhydrides is preferred.

Specific examples of polyhydric acid anhydrides include maleic anhydride, succinic anhydride, itaconic anhydride, phthalic anhydride, tetrahydrophthalic anhydride, hexahydrophthalic anhydride, methyl hexahydrophthalic anhydride, trimellitic anhydride, pyromellitic anhydride, benzophenone tetracarboxylic acid dianhydride, 3-methylhexahydrophthalic anhydride, 4-methylhexahydrophthalic anhydride, 3-ethylhexahydrophthalic anhydride, 4-ethylhexahydrophthalic anhydride, tetrahydrophthalic anhydride, 3-methyltetrahydrophthalic anhydride, 4-methyltetrahydrophthalic anhydride, 3-ethyltetrahydrophthalic anhydride, 4-ethyltetrahydrophthalic, and the like.

the alkali-soluble resin having an ethylenically unsaturated group can also be obtained by reacting the reactant of unsaturated carboxylic acids and an acrylic resin containing a constituent unit having an epoxy group, and then further reacting obtained reactants with polyhydric acid anhydrides. As a specific example, when acrylic acids are reacted with constituent units derived from glycidyl methacrylate, a constituent unit having a hydroxy group shown in the following reaction formula is formed. By reacting the constituent unit having a hydroxyl group with a polyhydric acid anhydride such as tetrahydrophthalic acid, a constituent unit that gives alkali-solubility to the resin having a carboxy group is formed.

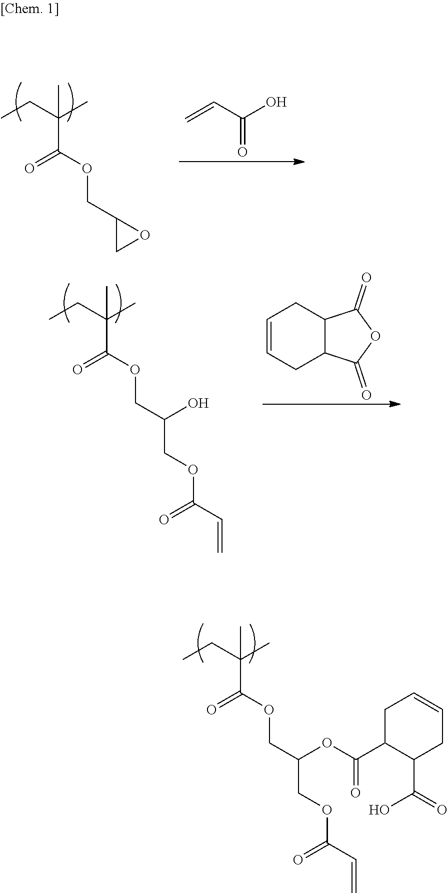

Examples of the alkali-soluble resin containing an ethylenically unsaturated group include polyester (meth)acrylates obtained by subjecting a polyester prepolymer derived from condensation between a polyhydric alcohol and a monobasic acid or a polybasic acid to reaction with (meth)acrylic acid; polyurethane (meth)acrylates obtained by subjecting a polyol and a compound having two isocyanate groups to reaction and then subjecting the resulting product to reaction with (meth)acrylic acid; and epoxy (meth)acrylate resins obtained by subjecting an epoxy resin such as a bisphenol A type epoxy resin, a bisphenol F type epoxy resin, a bisphenol S type epoxy resin, a phenol or cresol novolak type epoxy resin, a resole type epoxy resin, a triphenol methane type epoxy resin, a polycarboxylic acid polyglycidyl ester, a polyol polyglycidyl ester, an aliphatic or alicyclic epoxy resin, an amine epoxy resin, or a dihydroxybenzene type epoxy resin to reaction with (meth)acrylic acid. In the present description, “(meth)acryl” means “acryl or methacryl”. Similarly, “(meth)acrylate” means “acrylate or methacrylate”.

A resin obtained by copolymerizing unsaturated carboxylic acid and other unsaturated compound can be used as the alkali-soluble resin not having ethylenically unsaturated group. Other compound is preferably at least one selected from an epoxy group-containing unsaturated compound and an alicyclic group-containing unsaturated compound.

Examples of the unsaturated carboxylic acids include monocarboxylic acids such as (meth)acrylic acid and crotonic acid; dicarboxylic acids such as maleic acid, fumaric acid, citraconic acid, mesaconic acid, and itaconic acid; and anhydrides of these dicarboxylic acids. Among these, (meth)acrylic acid and maleic anhydride are preferred from the viewpoints of copolymerization reactivity, alkali solubility of the obtained resin, easy availability, and the like. These unsaturated carboxylic acids may be used alone or in combination of two or more kinds thereof.

Examples of the epoxy group-containing unsaturated compound include an epoxy group-containing unsaturated compound having no alicyclic group and an epoxy group-containing unsaturated compound having alicyclic group. As the epoxy group-containing unsaturated compound having alicyclic group, compounds represented by formulas (c5-1) to (c5-15) described later may be exemplified. A (meth)acrylic acid ester having an aromatic group and an epoxy group and an aliphatic (meth)acrylic acid ester having a chain aliphatic epoxy group described later for an epoxy group-containing resin can be suitably used as the epoxy group-containing unsaturated compound having no alicyclic group.

The epoxy compound is not particularly limited as long as the epoxy compound is curable by heating alone, or by the action of a thermosensitive curing agent or a photosensitive curing agent. The alicyclic group may be either monocyclic or polycyclic. Examples of the monocyclic alicyclic group include a cyclopentyl group, a cyclohexyl group, and the like. Examples of the polycyclic alicyclic group include an adamantyl group, a norbornyl group, an isobornyl group, a tricyclononyl group, a tricyclodecyl group, a tetracyclododecyl group, and the like. Specific examples of the alicyclic group-containing unsaturated compounds include compounds represented by the following formulae (c6-1) to (c6-8).

It is also preferable to copolymerize an unsaturated carboxylic acid with other compounds than above compounds. Examples of such other compounds include (meth)acrylic acid esters, (meth)acrylic acid amides, allyl compounds, vinyl ethers, vinyl esters, styrenes, maleimides, and the like. These compounds can be used individually, or two or more thereof can be used in combination.

Examples of the (meth)acrylic acid esters include linear or branched alkyl (meth)acrylates such as methyl (meth)acrylate, ethyl (meth)acrylate, propyl (meth)acrylate, amyl (meth)acrylate, and t-octyl (meth)acrylate; chloroethyl (meth)acrylate, 2,2-dimethylhydroxypropyl (meth)acrylate, 2-hydroxyethyl (meth) acrylate, trimethylolpropane mono(meth)acrylate, benzyl (meth) acrylate, furfuryl (meth)acrylate; and the like.

Specific examples of (meth)acrylamides, allyl compounds, vinyl ethers, styrenes, and maleimides will be described later in detail as monomers which give an epoxy group-containing resin.

Copolymer including at least constituent units having a portion that is polymerizable with photocurable low-molecular-weight compounds described later with constituent units derived from unsaturated carboxylic acids or copolymer including constituent units derived from unsaturated carboxylic acids, constituent units derived from epoxy group-containing unsaturated compounds and constituent units having a portion that is polymerizable with photopolymerizable compounds described later can be used as the alkali-soluble resin.

Above copolymer including constituent units having a portion that is polymerizable with photocurable low-molecular-weight compounds may further include constituent units derived from above (meth)acrylic acid esters, (meth)acrylic acid amides, allyl compounds, vinyl ethers, vinyl esters, styrenes, maleimides, and the like.

The constituent unit having the portion that is polymerizable with photocurable low-molecular-weight compounds is preferably a constituent unit having an ethylenically unsaturated double bond as the portion that is polymerizable with photocurable low-molecular-weight compounds. A copolymer having such a constituent unit can be prepared by reacting at least a part of a carboxy group included in a homopolymer of the unsaturated carboxylic acid and an epoxy group-containing unsaturated compound with each other. A copolymer having the constituent unit having a polymerizable site to the photocurable low-molecular-weight compound can be prepared also by reacting at least a part of an epoxy group included in a copolymer including a constituent unit derived from unsaturated carboxylic acid and a constituent unit derived from an epoxy group-containing unsaturated compound, with the unsaturated carboxylic acid.

The proportion of the above-mentioned constituent unit derived from unsaturated carboxylic acid in the alkali-soluble resin is preferably 3% by mass or more and 25% by mass or less, and more preferably 5% by mass or more and 25% by mass or less. Furthermore, the proportion of the constituent unit derived from the above-mentioned epoxy group-containing unsaturated compound is preferably 30% by mass or more and 95% by mass or less, and more preferably 50% by mass or more and 90% by mass or less. Furthermore, the above-mentioned proportion of the constituent unit derived from the alicyclic group-containing unsaturated compound is preferably 1% by mass or more and 30% by mass or less, more preferably 3% by mass or more and 25% by mass or less, and further preferably 5% by mass or more and 20% by mass or less. When the proportion is in the above-mentioned range, it is possible to make the alkali solubility of the obtained resin appropriate, and enhance the adhesion property and the strength of the quantum dot-containing film to a substrate.

The mass average molecular weight of the alkali-soluble resin is preferably 1,000 or more and 40,000 or less, more preferably 2,000 or more and 30,000 or less. When the mass average molecular weight is in above-mentioned range, sufficient heat resistance and strength of film can be obtained while excellent developing property is obtained.

The content of the alkali-soluble resin is preferably 5% by mass or more and 80% by mass or less, and more preferably 15% by mass or more and 50% by mass or less, based on total solid component of the composition. When the content is in the above-mentioned range, a balance of film-forming property tends to be easily achieved.

### [Thermosetting Low-Molecular-Weight Compound]

Examples of the thermosetting low-molecular-weight compound as the base component (C) that forms crosslinking in response to heat to give a polymer compound include an epoxy compound or an oxetane compound. When the composition including an epoxy compound or an oxetane compound as the base component (C) is heated to a predetermined temperature or higher, epoxy groups or oxetanyl groups of the epoxy compound or the oxetane compound crosslink with each other and thereby the resulting cured film becomes excellent in heat resistance and mechanical properties.

The epoxy compound or the oxetane compound is basically used as the thermosetting base component (C). In the case in which the epoxy compound or the oxetane compound is used in combination with an onium salt (D2) described later, the epoxy compound or the oxetane compound may be photo-cured.

Epoxy compounds and oxetane compounds described in Japanese Unexamined Patent Application Publication No. 2018-061034 can be suitably used as the epoxy compound and the oxetane compound. The epoxy compound and the oxetane compound are not limited to compounds described in Japanese Unexamined Patent Application Publication No. 2018-061034.

### (Epoxy Compound)

The epoxy compound is not particularly limited as long as the epoxy compound is curable by heating alone, or by the action of a thermosensitive curing agent or a photosensitive curing agent. The epoxy compound preferably has two or more epoxy groups. Moreover, the epoxy compound preferably includes a cyclic structure other than the oxirane ring. The use of the epoxy compound having such a structure tends to form a quantum dot-containing film that contains the quantum dots (A) in a favorable dispersion state and has a favorable fluorescence efficiency.

For the epoxy compound having a cyclic structure, the cyclic structure included in the epoxy compound is not particularly limited. The cyclic structure can be a cyclic structure including carbon as a ring-forming element such as a hydrocarbon ring structure or a heterocyclic ring structure, or can be a cyclic structure not including carbon as a ring-forming element such as a cyclic siloxane structure. Examples of heteroatoms which can be included in the heterocyclic ring structure include a nitrogen atom, an oxygen atom, a sulfur atom, a selenium atom, a silicon atom and the like. The cyclic structure can be a monocyclic structure or a polycyclic structure. The cyclic structure including carbon as a ring-forming element can be an aromatic ring structure, or an aliphatic ring structure, or a polycyclic structure in which an aromatic ring and an aliphatic ring are condensed.

Examples of rings to give the aromatic ring structure or the ring structure including an aromatic ring include a benzene ring, a naphthalene ring, an anthracene ring, a phenanthrene ring, a tetralin ring, an acenaphthene ring and a fluorene ring, and the like. Examples of rings to give the aliphatic ring structure include a monocycloalkane ring, a bicycloalkane ring, a tricycloalkane ring, a tetracycloalkane ring, and the like. Specific examples thereof include monocycloalkane rings such as a cyclopentane ring, a cyclohexane ring, a cycloheptane ring and a cyclooctane ring, an adamantane ring, a norbornane ring, an isobornane ring, a tricyclodecane ring and a tetracyclododecane ring.

Examples of epoxy compounds which can be suitably used and are widely used include bifunctional epoxy resins such as bisphenol A epoxy resin, bisphenol F epoxy resin, bisphenol S epoxy resin, bisphenol AD epoxy resin, naphthalene epoxy resin and biphenyl epoxy resin; epoxy group-containing fluorene compounds such as 9,9-bis[4-(glycidyloxy)phenyl]-9H-fluorene, 9,9-bis[4-[2-(glycidyloxy)ethoxy]phenyl]-9H-fluorene, 9,9-bis[4-[2-(glycidyloxy)ethyl]phenyl]-9H-fluorene, 9,9-bis[4-(glycidyloxy)-3-methylphenyl]-9H-fluorene, 9,9-bis[4-(glycidyloxy)-3,5-dimethylphenyl]-9H-fluorene and 9,9-bis(6-glycidyloxynaphthalen-2-yl)-9H-fluorene; glycidylamine epoxy resins such as tetraglycidylaminodiphenylmethane, triglycidyl-p-aminophenol, tetraglycidyl methaxylylenediamine and tetraglycidyl bisaminomethylcyclohexane; trifunctional epoxy resins such as phloroglycinol triglycidyl ether, trihydroxybiphenyl triglycidyl ether, trihydroxyphenylmethane triglycidyl ether, 2-[4-(2,3-epoxypropoxy)phenyl]-2-[4-[1,1-bis[4-(2,3-epoxypropoxy)phenyl]ethyl]phenyl]propane and 1,3-bis[4-[1-[4-(2,3-epoxypropoxy)phenyl]-1-[4-[1-[4-(2,3-epoxypropoxy)phenyl]-1-methylethyl]phenyl]ethyl]phenoxy]-2-propanol; tetrafunctional epoxy resins such as tetrahydroxyphenylethane tetraglycidyl ether, tetraglycidylbenzophenone, bisresorcinol tetraglycidyl ether and tetraglycidoxybiphenyl; and a 1,2-epoxy-4-(2-oxiranyl)cyclohexane adduct of 2,2-bis(hydroxymethyl)-1-butanol. The 1,2-epoxy-4-(2-oxiranyl)cyclohexane adduct of 2,2-bis(hydroxymethyl)-1-butanol is commercially available as EHPE-3150 (manufactured by Daicel Corporation).

An oligomer or polymer type polyfunctional epoxy compound can also be preferably used. Typical examples thereof include a phenol novolak epoxy compound, a brominated phenol novolak epoxy compound, an ortho-cresol novolak epoxy compound, a xylenol novolak epoxy compound, a naphthol novolak epoxy compound, a bisphenol A novolak epoxy compound, a bisphenol AD novolak epoxy compound, an epoxylated product of dicyclopentadiene phenol resin, an epoxylated product of naphthalene phenol resin, and the like.

Other examples of suitable epoxy compounds include a polyfunctional alicyclic epoxy compound having an alicyclic epoxy group. Specific examples of the alicyclic epoxy compound include 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylcyclohexanecarboxylate, ε-caprolactone-modified 3,4-epoxycyclohexylmethyl-3′,4′-epoxycyclohexanecarboxylate, trimethylcaprolactone-modified 3,4-epoxycyclohexylmethyl-3′,4′-epoxycyclohexanecarboxylate, β-methyl-δ-valerolactone-modified 3,4-epoxycyclohexylmethyl-3′,4′-epoxycyclohexanecarboxylate, methylenebis(3,4-epoxycyclohexane), di(3,4-epoxycyclohexylmethyl) ether of ethylene glycol, ethylenebis(3,4-epoxycyclohexanecarboxylate), a polyfunctional epoxy compound having a tricyclodecene oxide group, and compounds represented by the following formulas (c1-1) to (c1-5). These alicyclic epoxy compounds can be used individually or two or more alicyclic epoxy compounds can be used in combination.

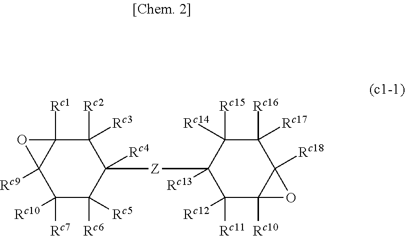

In the formula (c1-1), Z represents a single bond or a linking group (a divalent group having one or more atoms. R^{c1} to R^{c18} are each independently a group selected from the group consisting of a hydrogen atom, a halogen atom and an organic group.

Examples of the linking group Z can include a divalent group selected form the group consisting of a divalent hydrocarbon group, —O—, —O—CO—, —S—, —SO—, —SO₂—, —CBr₂—, —C(CBr₃)₂—, —C(CF₃)₂— and —R^{c19}—O—CO—, and a group formed by bonding a plural of these divalent groups, and the like.

Examples of the divalent hydrocarbon group as a linking group Z can include a linear or branched alkylene group having 1 or more and 18 or less carbon atoms, and a divalent alicyclic hydrocarbon group, and the like. Examples of the linear or branched alkylene group having 1 or more and 18 or less carbon atoms can include a methylene group, a methylmethylene group, a dimethylmethylene group, a dimethylene group, a trimethylene group, and the like. Examples of the above divalent alicyclic hydrocarbon group can include cycloalkylene groups (including cycloalkylidene groups) such as a 1,2-cyclopentylene group, a 1,3-cyclopentylene group, a cyclopentylidene group, a 1,2-cyclohexylene group, a 1,3-cyclohexylene group, a 1,4-cyclohexylene group and cyclohexylidene, and the like.

R^{c19} is an alkylene group having 1 or more and 8 or less carbon atoms and preferably a methylene group or an ethylene group.

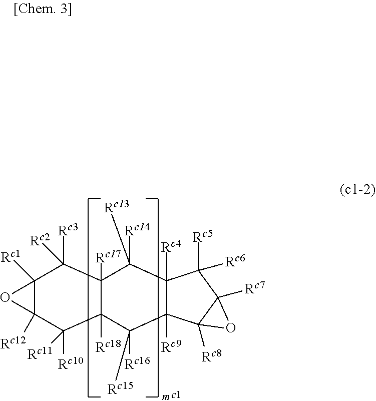

In the formula (c1-2), R^{c1} to R^{c18} are a group selected from the group consisting of a hydrogen atom, a halogen atom and an organic group. R^{c2} and R^{c10} may be bonded to each other to form a ring. R^{c13} and R^{c16} may be bonded to each other to form a ring. m^{c1} is 0 or 1.

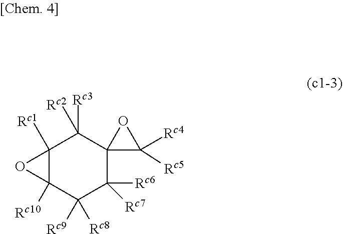

In the formula (c1-3), R^{c1} to R^{c10} are a group selected from the group consisting of a hydrogen atom, a halogen atom and an organic group. R^{c2} and R^{c8} may be bonded to each other to form a ring.

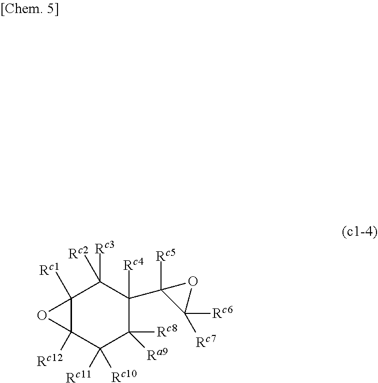

In the formula (c1-4), R^{c1} to R^{c12} are a group selected from the group consisting of a hydrogen atom, a halogen atom and an organic group. R^{c2} and R^{c10} may be bonded to each other to form a ring.

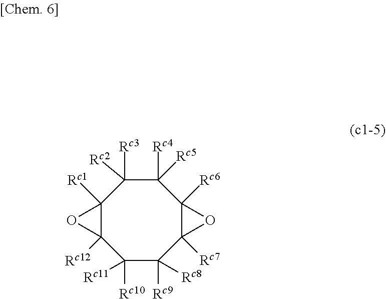

In the formula (c1-5), R^{c1} to R^{c12} are a group selected from the group consisting of a hydrogen atom, a halogen atom and an organic group.

In the formulas (c1-1) to (c1-5), when R^{c1} to R^{c18} are an organic group, the organic group is not particularly limited as long as the object of the present invention is not inhibited, and the organic group may be a hydrocarbon group, or a group including a carbon atom and a halogen atom, or a group including a heteroatom such as a halogen atom, an oxygen atom, a sulfur atom, a nitrogen atom or a silicon atom, together with a carbon atom and a hydrogen atom. Examples of the halogen atom include a chlorine atom, a bromine atom, an iodine atom and a fluorine atom, and the like.

The organic group is preferably a hydrocarbon group, a group including a carbon atom, a hydrogen atom and an oxygen atom, a halogenated hydrocarbon group, a group including a carbon atom, an oxygen atom and a halogen atom, and a group including a carbon atom, a hydrogen atom, an oxygen atom and a halogen atom. When the organic group is a hydrocarbon group, the hydrocarbon group may be an aromatic hydrocarbon group, or an aliphatic hydrocarbon group, or a group including an aromatic skeleton and an aliphatic skeleton. The number of carbon atoms of the organic group is preferably 1 or more and 20 or less, more preferably 1 or more and 10 or less, and particularly preferably 1 or more and 5 or less.

Specific examples of the hydrocarbon group include chain alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethylhexyl group, an n-nonyl group, an n-decyl group, an n-undecyl group, an n-tridecyl group, an n-tetradecyl group, an n-pentadecyl group, an n-hexadecyl group, an n-heptadecyl group, an n-octadecyl group, an n-nonadecyl group and an n-icosyl group; chain alkenyl groups such as a vinyl group, a 1-propenyl group, a 2-n-propenyl group (an allyl group), a 1-n-butenyl group, a 2-n-butenyl group and a 3-n-butenyl group; cycloalkyl groups such as a cyclopropyl group, a cyclobutyl group, a cyclopentyl group, a cyclohexyl group and a cycloheptyl group; aryl groups such as a phenyl group, an o-tolyl group, an m-tolyl group, a p-tolyl group, an α-naphthyl group, a β-naphthyl group, a biphenyl-4-yl group, a biphenyl-3-yl group, a biphenyl-2-yl group, an anthryl group and a phenanthryl group; and aralkyl groups such as a benzyl group, a phenethyl group, an α-naphthylmethyl group, a β-naphthylmethyl group, an α-naphthylethyl group and a β-naphthylethyl group.

Specific examples of the halogenated hydrocarbon group are halogenated chain alkyl groups such as a chloromethyl group, a dichloromethyl group, a trichloromethyl group, a bromomethyl group, a dibromomethyl group, a tribromomethyl group, a fluoromethyl group, a difluoromethyl group, a trifluoromethyl group, a 2,2,2-trifluoroethyl group, a pentafluoroethyl group, a heptafluoropropyl group, a perfluorobutyl group and a perfluoropentyl group, a perfluorohexyl group, a perfluoroheptyl group, a perfluorooctyl group, a perfluorononyl group and a perfluorodecyl group; halogenated cycloalkyl groups such as a 2-chlorocyclohexyl group, a 3-chlorocyclohexyl group, a 4-chlorocyclohexyl group, a 2,4-dichlorocyclohexyl group, a 2-bromocyclohexyl group, a 3-bromocyclohexyl group and a 4-bromocyclohexyl group; halogenated aryl groups such as a 2-chlorophenyl group, a 3-chlorophenyl group, a 4-chlorophenyl group, a 2,3-dichlorophenyl group, a 2,4-dichlorophenyl group, a 2,5-dichlorophenyl group, a 2,6-dichlorophenyl group, a 3,4-dichlorophenyl group, a 3,5-dichlorophenyl group, a 2-bromophenyl group, a 3-bromophenyl group, a 4-bromophenyl group, a 2-fluorophenyl group, a 3-fluorophenyl group and a 4-fluorophenyl group; and halogenated aralkyl groups such as a 2-chlorophenylmethyl group, a 3-chlorophenylmethyl group, a 4-chlorophenylmethyl group, a 2-bromophenylmethyl group, a 3-bromophenylmethyl group, a 4-bromophenylmethyl group, a 2-fluorophenylmethyl group, a 3-fluorophenylmethyl group and a 4-fluorophenylmethyl group.

Specific examples of the group including a carbon atom, a hydrogen atom and an oxygen atom are hydroxy chain alkyl groups such as a hydroxymethyl group, a 2-hydroxyethyl group, a 3-hydroxy-n-propyl group and a 4-hydroxy-n-butyl group; hydroxycycloalkyl groups such as a 2-hydroxycyclohexyl group, a 3-hydroxycyclohexyl group and a 4-hydroxycyclohexyl group; hydroxyaryl groups such as a 2-hydroxyphenyl group, a 3-hydroxyphenyl group, a 4-hydroxyphenyl group, a 2,3-dihydroxyphenyl group, a 2,4-dihydroxyphenyl group, a 2,5-dihydroxyphenyl group, a 2,6-dihydroxyphenyl group, a 3,4-dihydroxyphenyl group and a 3,5-dihydroxyphenyl group; hydroxyaralkyl groups such as a 2-hydroxyphenylmethyl group, a 3-hydroxyphenylmethyl group and a 4-hydroxyphenylmethyl group; chain alkoxy groups such as a methoxy group, an ethoxy group, an n-propoxy group, an isopropoxy group, an n-butyloxy group, an isobutyloxy group, a sec-butyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, an n-undecyloxy group, an n-tridecyloxy group, an n-tetradecyloxy group, an n-pentadecyloxy group, an n-hexadecyloxy group, an n-heptadecyloxy group, an n-octadecyloxy group, an n-nonadecyloxy group and an n-icosyloxy group; chain alkenyloxy groups such as a vinyloxy group, a 1-propenyloxy group, a 2-n-propenyloxy group (an allyloxy group), a 1-n-butenyloxy group, a 2-n-butenyloxy group and a 3-n-butenyloxy group; aryloxy groups such as a phenoxy group, an o-tolyloxy group, an m-tolyloxy group, a p-tolyloxy group, an α-naphthyloxy group, a β-naphthyloxy group, a biphenyl-4-yloxy group, a biphenyl-3-yloxy group, a biphenyl-2-yloxy group, an anthryloxy group and a phenanthryloxy group; aralkyloxy groups such as a benzyloxy group, a phenethyloxy group, an α-naphthylmethyloxy group, a β-naphthylmethyloxy group, an α-naphthylethyloxy group and a β-naphthylethyloxy group; alkoxyalkyl groups such as a methoxymethyl group, an ethoxymethyl group, an n-propoxymethyl group, a 2-methoxyethyl group, a 2-ethoxyethyl group, a 2-n-propoxyethyl group, a 3-methoxy-n-propyl group, a 3-ethoxy-n-propyl group, a 3-n-propoxy-n-propyl group, a 4-methoxy-n-butyl group, a 4-ethoxy-n-butyl group and a 4-n-propoxy-n-butyl group; alkoxyalkoxy groups such as a methoxymethoxy group, an ethoxymethoxy group, an n-propoxymethoxy group, a 2-methoxyethoxy group, a 2-ethoxyethoxy group, a 2-n-propoxyethoxy group, a 3-methoxy-n-propoxy group, a 3-ethoxy-n-propoxy group, a 3-n-propoxy-n-propoxy group, a 4-methoxy-n-butyloxy group, a 4-ethoxy-n-butyloxy group and a 4-n-propoxy-n-butyloxy group; alkoxyaryl groups such as a 2-methoxyphenyl group, a 3-methoxyphenyl group and a 4-methoxyphenyl group; alkoxyaryloxy groups such as a 2-methoxyphenoxy group, a 3-methoxyphenoxy group and a 4-methoxyphenoxy group; aliphatic acyl groups such as a formyl group, an acetyl group, a propionyl group, a butanoyl group, a pentanoyl group, a hexanoyl group, a heptanoyl group, an octanoyl group, a nonanoyl group and a decanoyl group; aromatic acyl groups such as a benzoyl group, an α-naphthoyl group and a β-naphthoyl group; chain alkyloxycarbonyl groups such as a methoxycarbonyl group, an ethoxycarbonyl group, an n-propoxycarbonyl group, an n-butyloxycarbonyl group, an n-pentyloxycarbonyl group, an n-hexyloxycarbonyl group, an n-heptyloxycarbonyl group, an n-octyloxycarbonyl group, an n-nonyloxycarbonyl group and an n-decyloxycarbonyl group; aryloxycarbonyl groups such as a phenoxycarbonyl group, an α-naphthoxycarbonyl group and a β-naphthoxycarbonyl group; aliphatic acyloxy groups such as a formyloxy group, an acetyloxy group, a propionyloxy group, a butanoyloxy group, a pentanoyloxy group, a hexanoyloxy group, a heptanoyloxy group, an octanoyloxy group, a nonanoyloxy group and a decanoyloxy group; and aromatic acyloxy groups such as a benzoyloxy group, an α-naphthoyloxy group and a β-naphthoyloxy group.

It is preferred that R^{c1} to R^{c18} be each independently a group selected from the group consisting of a hydrogen atom, a halogen atom, an alkyl group having 1 or more and 5 or less carbon atoms and an alkoxy group having 1 or more and 5 or less carbon atoms, and it is more preferred that all R^{c1} to R^{c18} be hydrogen atoms particularly because a cured film with good mechanical properties is easily formed.

In the formulas (c1-2) to (c1-5), R^{c1} to R^{c18} are the same as R^{c1} to R^{c18} in the formula (c1-1). Examples of the divalent group formed when R^{c2} and R^{c1}° are bonded to each other in the formula (c1-2) and the formula (c1-4), when R^{c13} and R^{c16} are bonded to each other in the formula (c1-2), and when R^{c2} and R^{c8} are bonded to each other in the formula (c1-3) include —CH₂— and —C(CH₃)₂—.

Specific examples of suitable compounds as the alicyclic epoxy compound represented by the formula (c1-1) can include alicyclic epoxy compounds represented by the following formulas (c1-1a), (c1-1b) and (c1-1c), 2,2-bis(3,4-epoxycyclohexan-1-yl)propane [=2,2-bis(3,4-epoxycyclohexyl)propane], and the like.

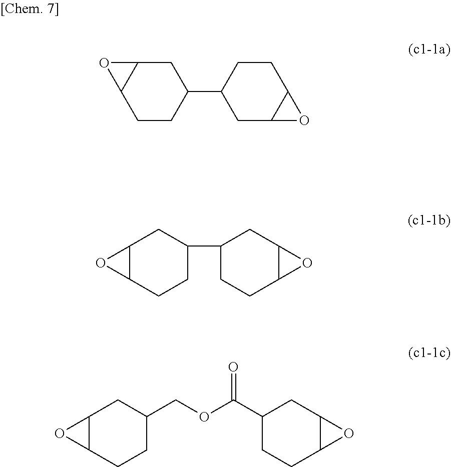 [SMILES: C1CC2OC2CC1C1CCC2OC2C1 ; C1CC2OC2CC1C1CCC2OC2C1 ; O=C(OCC1CCC2OC2C1)C1CCC2OC2C1]

Specific examples of suitable compounds as the alicyclic epoxy compound represented by the formula (c1-2) include compounds represented by the formula (c1-2a) described below and compounds represented by the formula (C1-2b) described below.

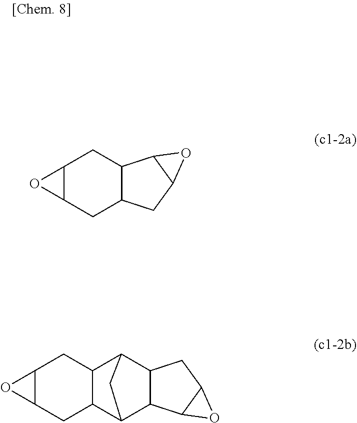 [SMILES: C1C2CC3OC3C2CC2OC12 ; C1C2OC2CC2C1C1CC2C2C1CC1OC12]

Specific examples of suitable compounds as the alicyclic epoxy compounds represented by the formula (c1-3) include S-spiro[3-oxatricyclo[3.2.1.0^{2,4}]octane-6,2′-oxirane], and the like.

Specific examples of suitable compounds as the alicyclic epoxy compound represented by the formula (c1-4) include 4-vinylcyclohexene dioxide, dipentene dioxide, limonene dioxide, 1-methyl-4-(3-methyloxiran-2-yl)-7-oxabicyclo[4.1.0]heptane, and the like.

Specific examples of suitable compounds of the alicyclic epoxy compound represented by the formula (c1-5) include 1,2,5,6-diepoxycyclooctane, and the like.

Furthermore, a compound represented by the following formula (c1) can be suitably used as the epoxy compound.

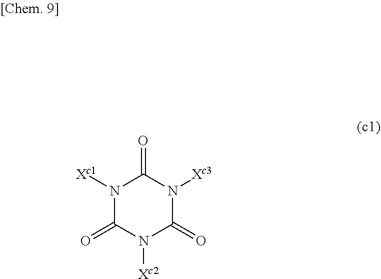

In the formula (c1), X^{c1}, X^{c2} and X^{c3} are each independently a hydrogen atom or an organic group which may include an epoxy group, and the total number of epoxy groups of X^{c1}, X^{c2} and X^{c3} is 2 or more.

The compound represented by the above formula (c1) is preferably a compound represented by the following formula (c1-6).

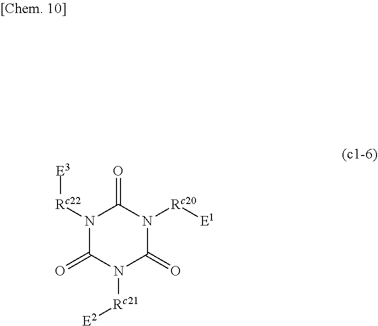

In the formula (c1-6), R^{c20} to R^{c22} are a linear, branched or cyclic alkylene group, an arylene group, —O—, —C(═O)—, —NH— and a combination thereof, and may be the same or different. E¹ to E³ are at least one substituent selected from the group consisting of an epoxy group, an oxetanyl group, an ethylenically unsaturated group, an alkoxysilyl group, an isocyanate group, a blocked isocyanate group, a thiol group, a carboxy group, a hydroxy group and a succinic acid anhydride group, or a hydrogen atom, provided that at least two of E¹ to E³ are at least one selected from the group consisting of an epoxy group and an oxetanyl group. Provided that at least two of E¹ to E³ are at least one selected from the group consisting of an epoxy group and an oxetanyl group.

In the formula (c1-6), each of at least two of a group represented by R^{c20} and E¹, a group represented by R^{c21} and E², and a group represented by R^{c22} and E³ is preferably a group represented by the following formula (c1-6a). It is more preferred that all of these groups are groups represented by the following formula (c1-6a). A plurality of groups represented by the formula (c1-6a) bonded to one compound are preferably the same.

-L-C^{c} (c1-6a)

In the formula (c1-6a), L is a linear, branched or cyclic alkylene group, an arylene group, —O—, —C(═O)—, —NH— and a combination thereof, and C^{c} is an epoxy group. In the formula (c1-6a), L and C^{c} may be bonded to each other to form a cyclic structure.

In the formula (c1-6a), the linear, branched or cyclic alkylene group as L is preferably an alkylene group having 1 or more and 10 or less carbon atoms. The arylene group as L is preferably an arylene group having 5 or more and 10 or less carbon atoms. In the formula (c1-6a), L is preferably a linear alkylene group having 1 or more and 3 or less carbon atoms, a phenylene group, —O—, —C(═O)—, —NH— and a combination thereof, and is preferably at least one of a linear alkylene group having 1 or more and 3 or less carbon atoms such as a methylene group and a phenylene group or a combination of these groups and at least one of —O—, —C(═O)— and —NH—.

As a case where L and C^{c} are bonded to each other to form a cyclic structure in the formula (c1-6a), for example when a branched alkylene group and an epoxy group are bonded to each other to form a cyclic structure (a structure having an epoxy group of an alicyclic structure), examples thereof include an organic group represented by the following formula (c1-6b) or (c1-6c).

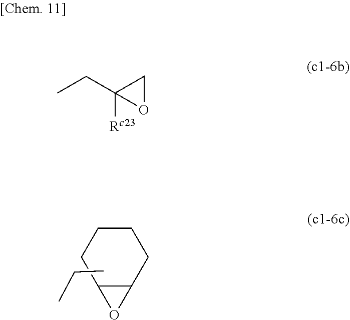

In the formula (c1-6b), R^{c23} is a hydrogen atom or a methyl group.

As examples of the compound represented by the formula (c1-6), epoxy compounds having an oxiranyl group or an alicyclic epoxy group will be exemplified. It should be noted, however, that the compound represented by the formula (c1-6) is not limited thereto.

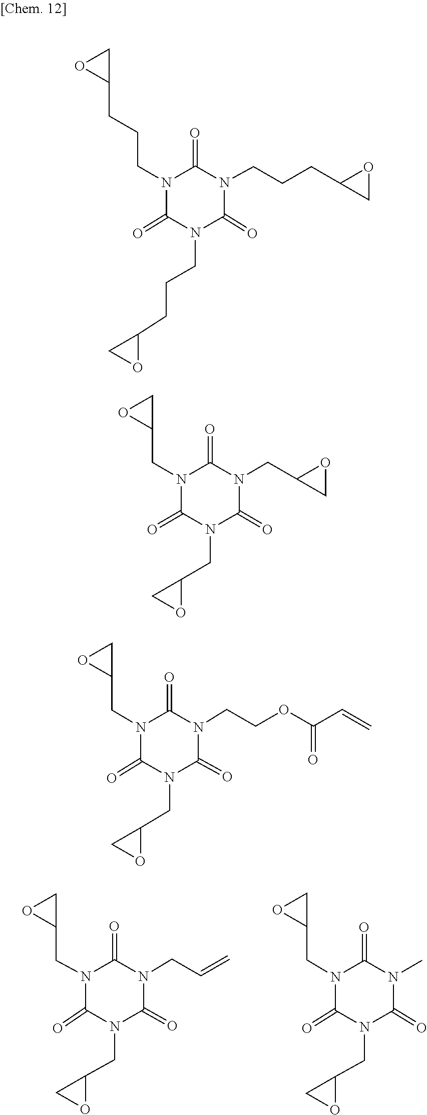

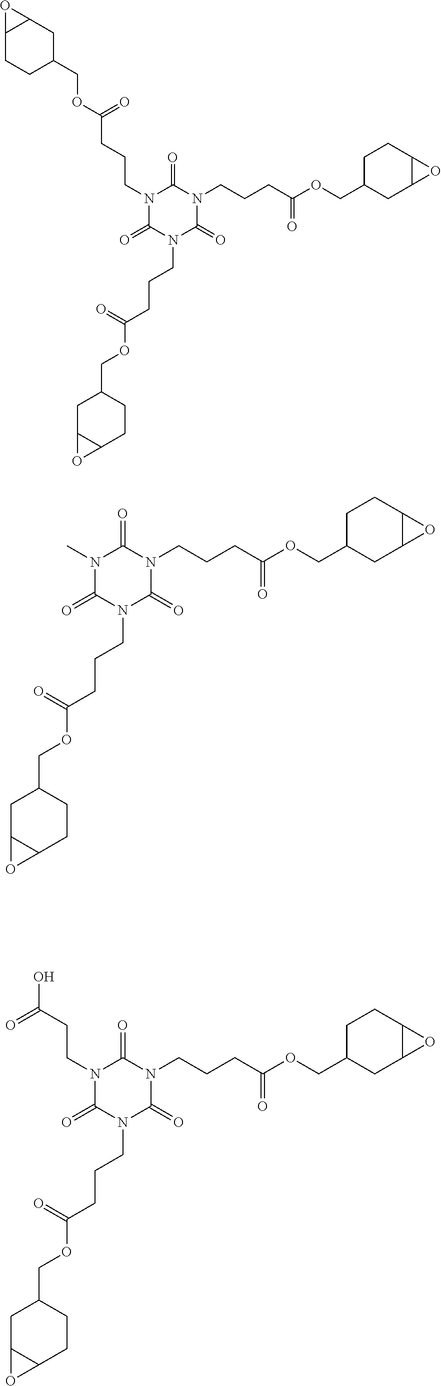 [SMILES: O=C(CCCn1c(=O)n(CCCC(=O)OCC2CCC3OC3C2)c(=O)n(CCCC(=O)OCC2CCC3OC3C2)c1=O)OCC1CCC2OC2C1 ; Cn1c(=O)n(CCCC(=O)OCC2CCC3OC3C2)c(=O)n(CCCC(=O)OCC2CCC3OC3C2)c1=O ; O=C(O)CCn1c(=O)n(CCCC(=O)OCC2CCC3OC3C2)c(=O)n(CCCC(=O)OCC2CCC3OC3C2)c1=O]

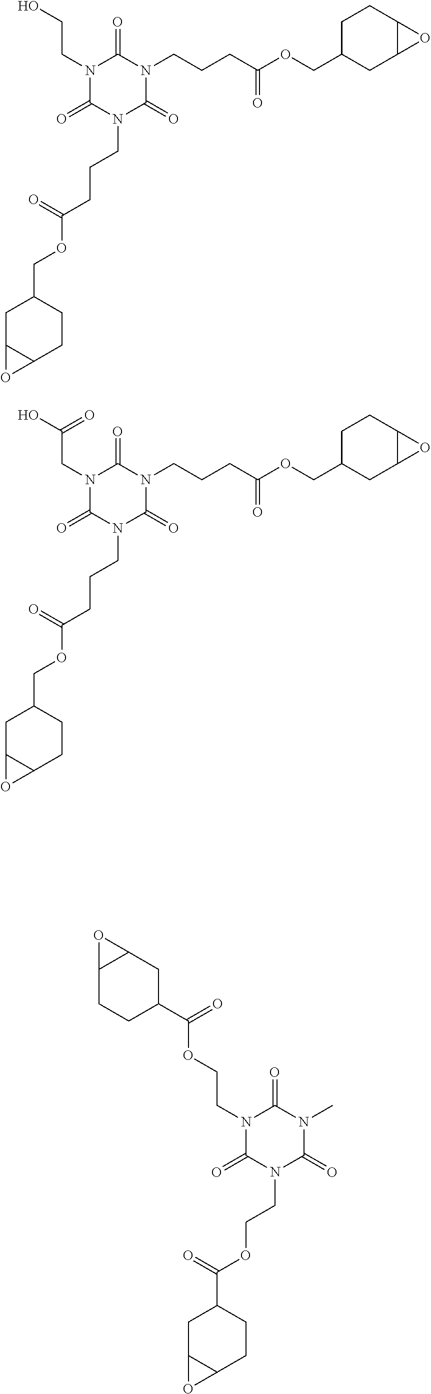 [SMILES: O=C(CCCn1c(=O)n(CCO)c(=O)n(CCCC(=O)OCC2CCC3OC3C2)c1=O)OCC1CCC2OC2C1 ; O=C(O)Cn1c(=O)n(CCCC(=O)OCC2CCC3OC3C2)c(=O)n(CCCC(=O)OCC2CCC3OC3C2)c1=O ; Cn1c(=O)n(CCOC(=O)C2CCC3OC3C2)c(=O)n(CCOC(=O)C2CCC3OC3C2)c1=O]

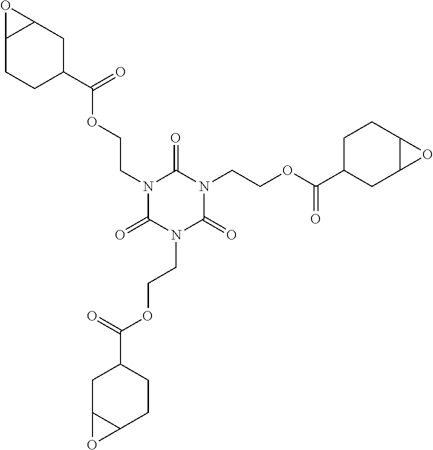 [SMILES: O=C(OCCn1c(=O)n(CCOC(=O)C2CCC3OC3C2)c(=O)n(CCOC(=O)C2CCC3OC3C2)c1=O)C1CCC2OC2C1]

Furthermore, as a compound which can preferably be used as the epoxy compound, a siloxane compound having two or more epoxy groups in a molecule (hereinafter, also simply referred to as “siloxane compound”) is exemplified.

The siloxane compound is a compound having a siloxane skeleton constituted with siloxane bonds (Si—O—Si) and two or more glycidyl groups in a molecule. Examples of the siloxane skeleton in the siloxane compound can include a cyclic siloxane skeleton, a polysiloxane skeleton and a basket or ladder type polysilsesquioxane skeleton.

As the siloxane compound, a compound having a cyclic siloxane skeleton represented by the following formula (c1-7) (hereinafter, may be referred to as “cyclic siloxane”) is preferred, among others.

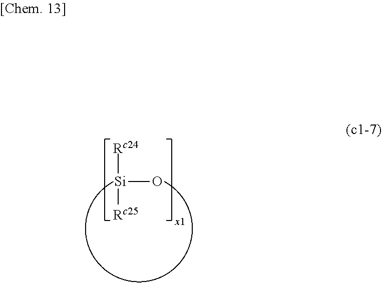

In the formula (c1-7), R^{c24} and R^{c25} represent a monovalent group including an epoxy group, or an alkyl group. However, at least two of the x1 number of R^{c24} and the x1 number of R^{c25} in the compound represented by the formula (c1-7) are a monovalent group including an epoxy group. Furthermore, x1 in the formula (c1-7) represents an integer of 3 or more. It should be noted that R^{c24} and R^{c25} in the compound represented by the formula (c1-7) may be the same or different. In addition, a plurality of R^{c24} may be the same or different. A plurality of R^{c25} may also be the same or different.

The above monovalent group including an epoxy group is preferably a glycidyl ether group represented by -D-O—R^{c26}. D represents an alkylene group, and R^{c26} represents a glycidyl group. Examples of alkylene groups as the above D can include linear or branched alkylene groups having 1 or more and 18 or less carbon atoms such as a methylene group, a methylmethylene group, a dimethylmethylene group, a dimethylene group and a trimethylene group, and the like. In addition, an alicyclic epoxy group-containing group represented by -D-R^{c27} is also preferred. R^{c27} is an epoxycycloalkyl group. D is an alkylene group as described above. Preferred examples of the alkylene group as D are also as described above. The epoxycycloalkyl group as R^{c27} is preferably a 2,3-epoxycyclopentyl group, a 3,4-epoxycyclohexyl group and a 2,3-epoxycyclohexyl group. The group represented by -D-R^{c27} is preferably a 2-(3,4-epoxycyclohexyl)ethyl group.

Preferred examples of the alkyl group as R^{c24} and R^{c25} can include linear or branched alkyl groups having 1 or more and 18 or less carbon atoms such as a methyl group, an ethyl group, a propyl group and an isopropyl group. The number of carbon atoms of the alkyl group is preferably 1 or more and 6 or less, and particularly preferably 1 or more and 3 or less.

In the formula (c1-7), x1 represents an integer of 3 or more, and particularly preferably an integer of 3 or more and 6 or less from the viewpoint of good crosslinking reactivity when a cured film is formed.

The number of epoxy groups in the molecule of the siloxane compound is 2 or more, and preferably 2 or more and 6 or less, and particularly preferably 2 or more and 4 or less from the viewpoint of good crosslinking reactivity when a cured film is formed.

The composition may include, in addition to the siloxane compound represented by the formula (c1-7), compounds having a siloxane skeleton such as alicyclic epoxy group-containing cyclic siloxane, an alicyclic epoxy group-containing silicone resin described in Japanese Unexamined Patent Application Publication No. 2008-248169, and an organopolysilsesquioxane resin having at least two epoxy functional groups in one molecule described in Japanese Unexamined Patent Application Publication No. 2008-19422.

More specific examples of the siloxane compound can include cyclic siloxane having two or more epoxy groups in a molecule represented by the following formulas, and the like. In addition, commercial products such as trade name “X-40-2670,” “X-40-2701,” “X-40-2728,” “X-40-2738” and “X-40-2740” (all manufactured by Shinetsu Chemical Co., Ltd.), for example, can be used as the siloxane compound.

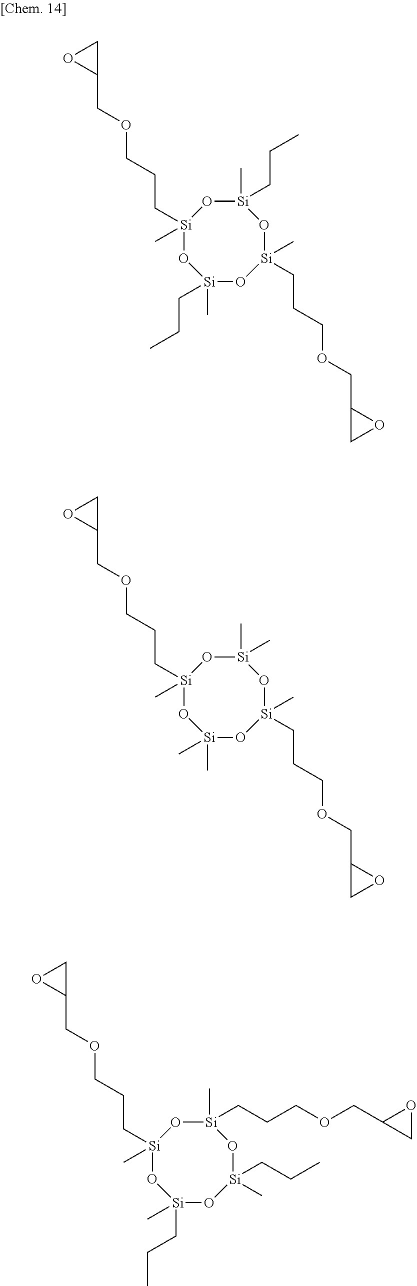 [SMILES: CCC[Si]1(C)O[Si](C)(CCCOCC2CO2)O[Si](C)(CCC)O[Si](C)(CCCOCC2CO2)O1 ; C[Si]1(C)O[Si](C)(CCCOCC2CO2)O[Si](C)(C)O[Si](C)(CCCOCC2CO2)O1 ; CCC[Si]1(C)O[Si](C)(CCC)O[Si](C)(CCCOCC2CO2)O[Si](C)(CCCOCC2CO2)O1]

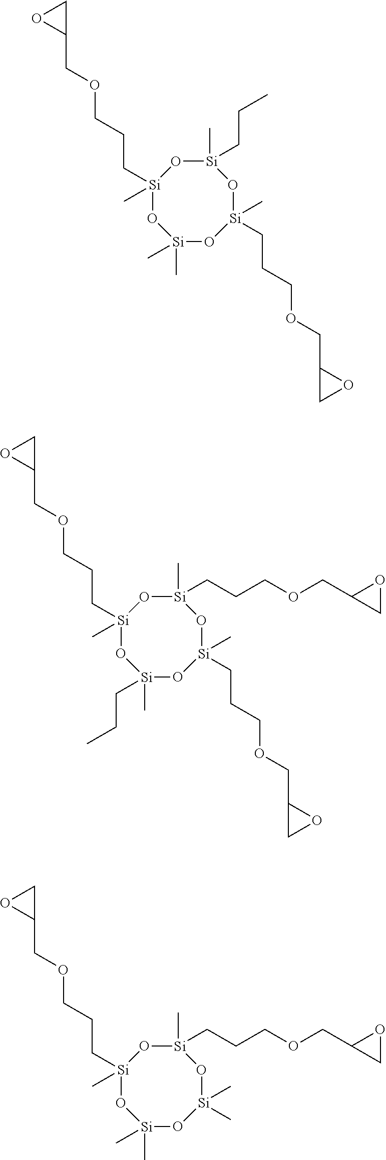 [SMILES: CCC[Si]1(C)O[Si](C)(CCCOCC2CO2)O[Si](C)(C)O[Si](C)(CCCOCC2CO2)O1 ; CCC[Si]1(C)O[Si](C)(CCCOCC2CO2)O[Si](C)(CCCOCC2CO2)O[Si](C)(CCCOCC2CO2)O1 ; C[Si]1(C)O[Si](C)(C)O[Si](C)(CCCOCC2CO2)O[Si](C)(CCCOCC2CO2)O1]

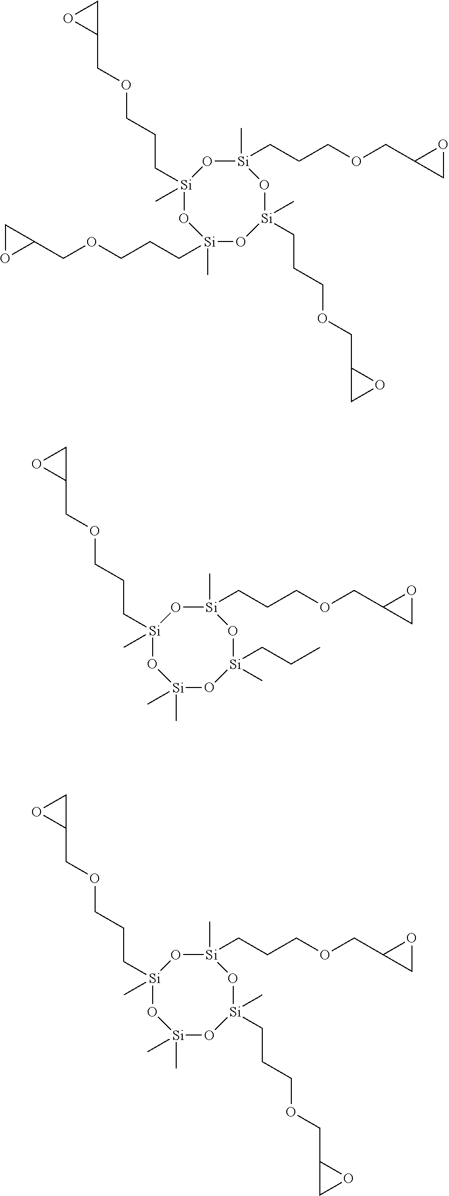 [SMILES: C[Si]1(CCCOCC2CO2)O[Si](C)(CCCOCC2CO2)O[Si](C)(CCCOCC2CO2)O[Si](C)(CCCOCC2CO2)O1 ; CCC[Si]1(C)O[Si](C)(C)O[Si](C)(CCCOCC2CO2)O[Si](C)(CCCOCC2CO2)O1 ; C[Si]1(C)O[Si](C)(CCCOCC2CO2)O[Si](C)(CCCOCC2CO2)O[Si](C)(CCCOCC2CO2)O1]

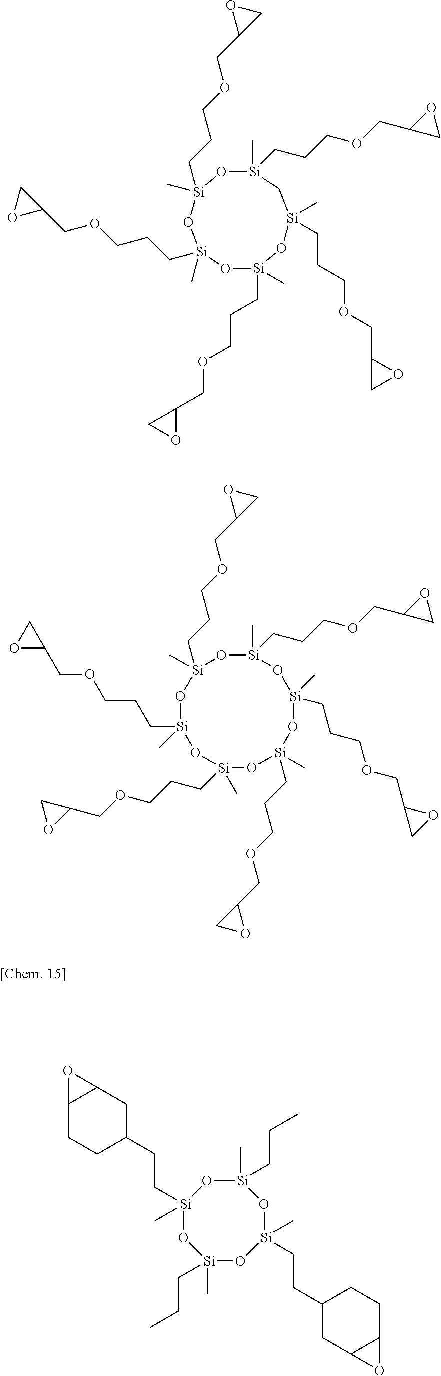 [SMILES: C[Si]1(CCCOCC2CO2)C[Si](C)(CCCOCC2CO2)O[Si](C)(CCCOCC2CO2)O[Si](C)(CCCOCC2CO2)O[Si](C)(CCCOCC2CO2)O1 ; C[Si]1(CCCOCC2CO2)O[Si](C)(CCCOCC2CO2)O[Si](C)(CCCOCC2CO2)O[Si](C)(CCCOCC2CO2)O[Si](C)(CCCOCC2CO2)O[Si](C)(CCCOCC2CO2)O1 ; CCC[Si]1(C)O[Si](C)(CCC2CCC3OC3C2)O[Si](C)(CCC)O[Si](C)(CCC2CCC3OC3C2)O1]

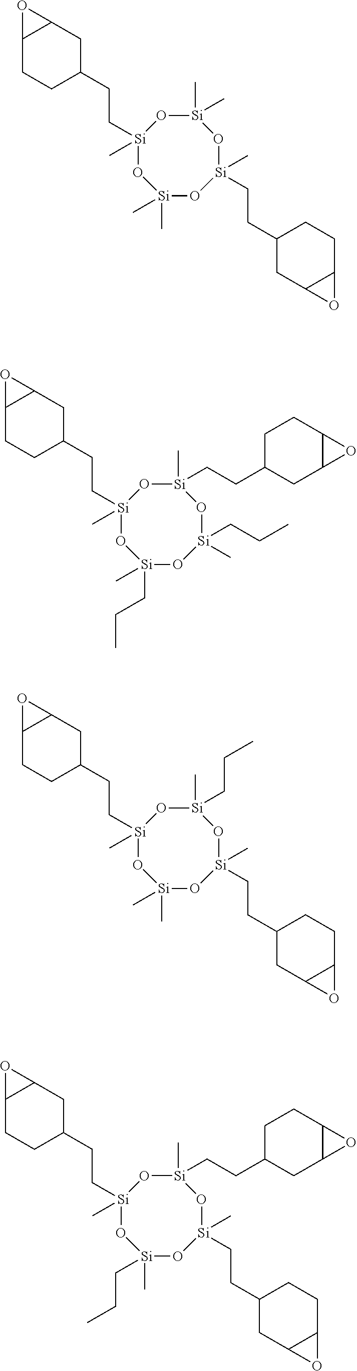 [SMILES: C[Si]1(C)O[Si](C)(CCC2CCC3OC3C2)O[Si](C)(C)O[Si](C)(CCC2CCC3OC3C2)O1 ; CCC[Si]1(C)O[Si](C)(CCC)O[Si](C)(CCC2CCC3OC3C2)O[Si](C)(CCC2CCC3OC3C2)O1 ; CCC[Si]1(C)O[Si](C)(CCC2CCC3OC3C2)O[Si](C)(C)O[Si](C)(CCC2CCC3OC3C2)O1 ; CCC[Si]1(C)O[Si](C)(CCC2CCC3OC3C2)O[Si](C)(CCC2CCC3OC3C2)O[Si](C)(CCC2CCC3OC3C2)O1]

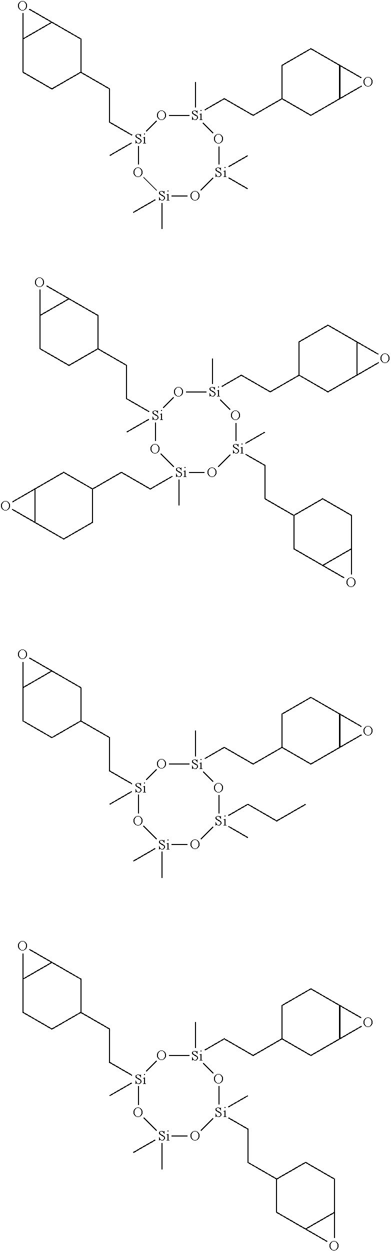 [SMILES: C[Si]1(C)O[Si](C)(C)O[Si](C)(CCC2CCC3OC3C2)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1 ; CCC[Si]1(C)O[Si](C)(C)O[Si](C)(CCC2CCC3OC3C2)O[Si](C)(CCC2CCC3OC3C2)O1 ; C[Si]1(C)O[Si](C)(CCC2CCC3OC3C2)O[Si](C)(CCC2CCC3OC3C2)O[Si](C)(CCC2CCC3OC3C2)O1]

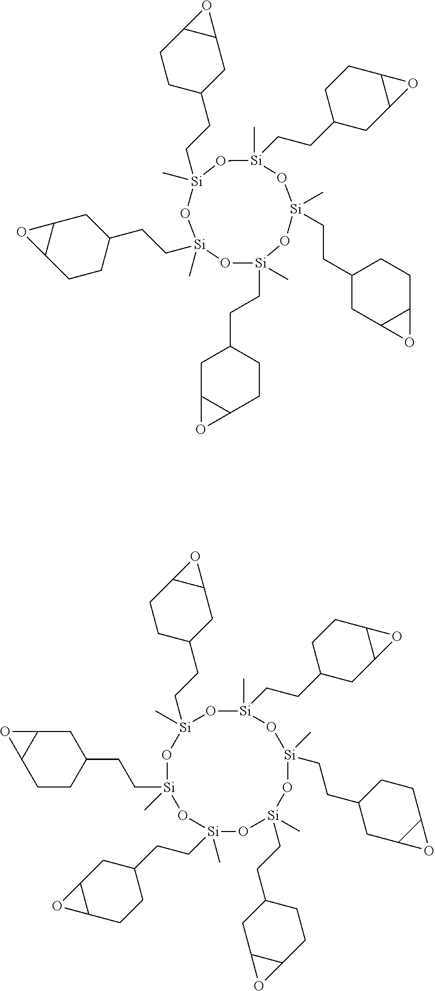 [SMILES: C[Si]1(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O1]

### [Thermosetting Polymer Compound]

Examples of the thermosetting polymer compound that may be used as the base component (C) include a resin that causes an intramolecular aromatic ring formation reaction and/or an intermolecular crosslinking reaction in response to heat, and a resin for formation of a cured film by baking. In the case in which the composition includes a resin that causes an intramolecular aromatic ring formation reaction and/or an intermolecular crosslinking reaction in response to heat, it is preferable that the composition includes a heat-responsive imidazole generator described in Japanese Unexamined Patent Application, Publication No. 2016-145308, and/or an imidazole compound described in Japanese Unexamined Patent Application, Publication No. 2017-025226 from the viewpoint of acceleration of the intramolecular aromatic ring formation reaction and/or the intermolecular crosslinking reaction in response to heat. A curing agent which may be included by the composition in the case in which the composition includes a resin for formation of a cured film by baking will be described in detail later.

In the case in which an intramolecular aromatic ring formation reaction occurs, the structure of a molecular chain constituting the resin becomes rigid and therefore the resulting composition tends to give a cured film excellent in heat resistance and mechanical properties. Examples of a preferable reaction as the intramolecular aromatic ring formation reaction include reactions shown by the following formulas (I) to (VI). The reactions in the following formulas are mere examples of the aromatic ring formation reaction. The structure of the resin used as the base component (C) that causes an intramolecular aromatic ring formation reaction in response to heat is not limited to the structures of the precursor polymers shown in the following formulas.

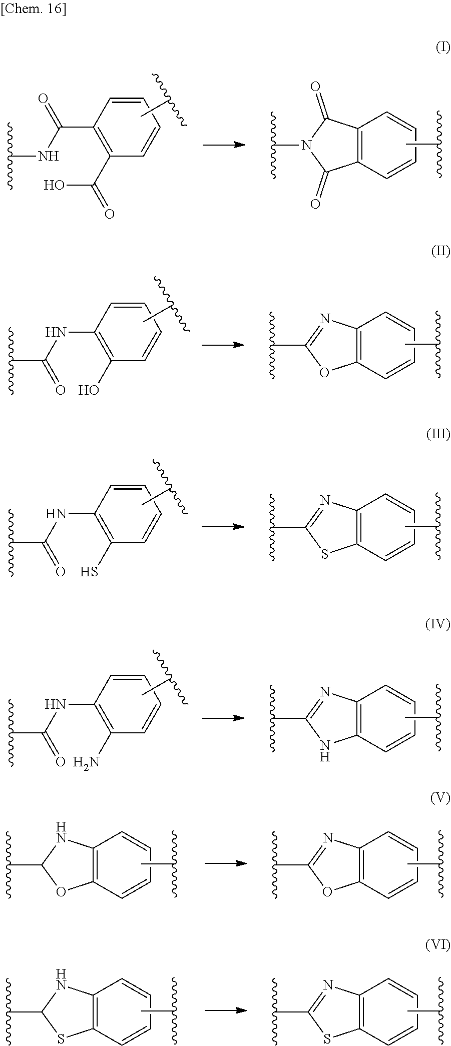

In the case in which an intermolecular crosslinking reaction occurs, molecular chains constituting the resin crosslink to each other and thereby a three-dimensional crosslinked structure is formed. Therefore, by using the composition including a resin that causes a crosslinking reaction in response to heat as the base component (C), a cured film excellent in heat resistance and mechanical properties tends to be obtained.

As the resin that causes an intermolecular crosslinking reaction in response to heat, a resin containing a group selected from a hydroxy group, a carboxylic anhydride group, a carboxy group, and an epoxy group in the molecule is preferable. In the case in which such a resin is used, crosslinking as described below takes place by the action of, for example, the aforementioned heat-responsive imidazole generator and/or the imidazole compound. In the case in which a resin containing a hydroxy group is used, crosslinking via dehydration condensation between hydroxy groups takes place between molecules in the resin. In the case in which a resin containing a carboxylic anhydride group is used, carboxy groups formed by hydrolysis of acid anhydride groups undergo dehydration condensation and thereby form crosslinks. In the case in which a resin containing a carboxy group is used, crosslinking via dehydration condensation between carboxy groups takes place between molecules in the resin. In the case in which a resin containing an epoxy group is used, crosslinking via polyaddition reaction between epoxy groups takes place between molecules in the resin.

Among these compounds that cause an intramolecular aromatic ring formation reaction or an intermolecular crosslinking reaction in response to heat, polyamic acid, a polybenzoxazole precursor, a polybenzothiazole precursor, a polybenzimidazole precursor, a styrene-(maleic acid) copolymer, and an epoxy-group-containing resin are preferable because a shaped body excellent in heat resistance tends to be formed. A conventionally known material can be used as compounds that cause an intramolecular aromatic ring formation reaction or an intermolecular crosslinking reaction in response to heat without any particular limitation. For example, compounds described in Japanese Unexamined Patent Application Publication No. 2018-061034 can be suitably used as a resin having a group selected from a hydroxy group, a carboxylic anhydride group, a carboxy group and an epoxy group, a polyamic acid, and a polybenzoxazole precursor. These compounds are not limited to compounds described in Japanese Unexamined Patent Application Publication No. 2018-061034.

### (Epoxy-Group-Containing Resin)

The epoxy-group-containing resin may be a polymer that is obtained by polymerizing a monomer having an epoxy group or a monomer mixture containing a monomer having an epoxy group. The epoxy-group-containing resin may be a polymer obtained by introducing an epoxy group into a polymer having a functional reactive group such as a hydroxy group, a carboxy group, or an amino group by using, for example, a compound having an epoxy group such as epichlorohydrin. As the polymer having an epoxy group, a polymer that is obtained by polymerizing a monomer having an epoxy group or a monomer mixture containing a monomer having an epoxy group is preferable because use of this polymer is advantageous in terms of, for example, availability, easy preparation, and easy adjustment of the amount of epoxy groups in the polymer.

Examples of a preferable epoxy-group-containing resin include novolak epoxy resins such as a phenol novolak type epoxy resin, a brominated phenol novolak type epoxy resin, an orthocresol novolak type epoxy resin, a bisphenol A novolak type epoxy resin, and a bisphenol AD novolak type epoxy resin; cyclic aliphatic epoxy resins such as an epoxidized product of a dicyclopentadiene type phenolic resin; and aromatic epoxy resins such as an epoxidized product of a naphthalene type phenolic resin.

Among the epoxy-group-containing resins, the polymer having an epoxy group is preferably a homopolymer of a (meth)acrylic acid ester having an epoxy group, or a copolymer of a (meth)acrylic acid ester having an epoxy group with other monomer in view of ease of preparation and the like.

The (meth)acrylic acid ester having an epoxy group may be either a (meth)acrylic acid ester having a chain aliphatic epoxy group, or the below-mentioned (meth)acrylic acid ester having an alicyclic epoxy group. The (meth)acrylic acid ester having an epoxy group may have an aromatic group. The (meth)acrylic acid ester having an epoxy group is preferably an aliphatic (meth)acrylic acid ester having a chain aliphatic epoxy group or an aliphatic (meth)acrylic acid ester having an alicyclic epoxy group, and more preferably an aliphatic (meth)acrylic acid ester having an alicyclic epoxy group.

Examples of the (meth)acrylic acid ester which has an aromatic group and an epoxy group include 4-glycidyloxyphenyl (meth) acrylate, 3-glycidyloxyphenyl (meth) acrylate, 2-glycidyloxyphenyl (meth) acrylate, 4-glycidyloxyphenylmethyl (meth)acrylate, 3-glycidyloxyphenylmethyl (meth)acrylate, and 2-glycidyloxyphenylmethyl (meth) acrylate.

Examples of the aliphatic (meth)acrylic acid ester having a chain aliphatic epoxy group include (meth)acrylic acid esters in which a chain aliphatic epoxy group is combined with an oxy group (—O—) in an ester group (—O—CO—), such as epoxyalkyl (meth)acrylate and epoxyalkyloxyalkyl (meth)acrylate. Such a chain aliphatic epoxy group possessed by the (meth)acrylic acid ester may have one or a plurality of oxy groups (—O—) in the chain. The number of carbon atoms of the chain aliphatic epoxy group is not particularly limited, and is preferably 3 or more and 20 or less, more preferably 3 or more and 15 or less, and particularly preferably 3 or more and 10 or less.

Specific examples of the aliphatic (meth)acrylic acid ester having a chain aliphatic epoxy group include epoxyalkyl (meth)acrylates such as glycidyl (meth)acrylate, 2-methyl glycidyl (meth)acrylate, 3,4-epoxybutyl (meth)acrylate, and 6,7-epoxyheptyl (meth)acrylate; and epoxyalkyloxyalkyl (meth)acrylates such as 2-glycidyloxyethyl (meth)acrylate, 3-glycidyloxy-n-propyl (meth) acrylate, 4-glycidyloxy-n-butyl (meth)acrylate, 5-glycidyloxy-n-hexyl (meth)acrylate, and 6-glycidyloxy-n-hexyl (meth) acrylate.

Specific examples of the aliphatic (meth)acrylic acid ester having an alicyclic epoxy group include compounds represented by the following formulas (c5-1) to (c5-15). Of these compounds, compounds represented by the following formulas (c5-1) to (c5-5) are preferable, and compounds represented by the following formulas (c5-1) to (c5-3) are more preferable.

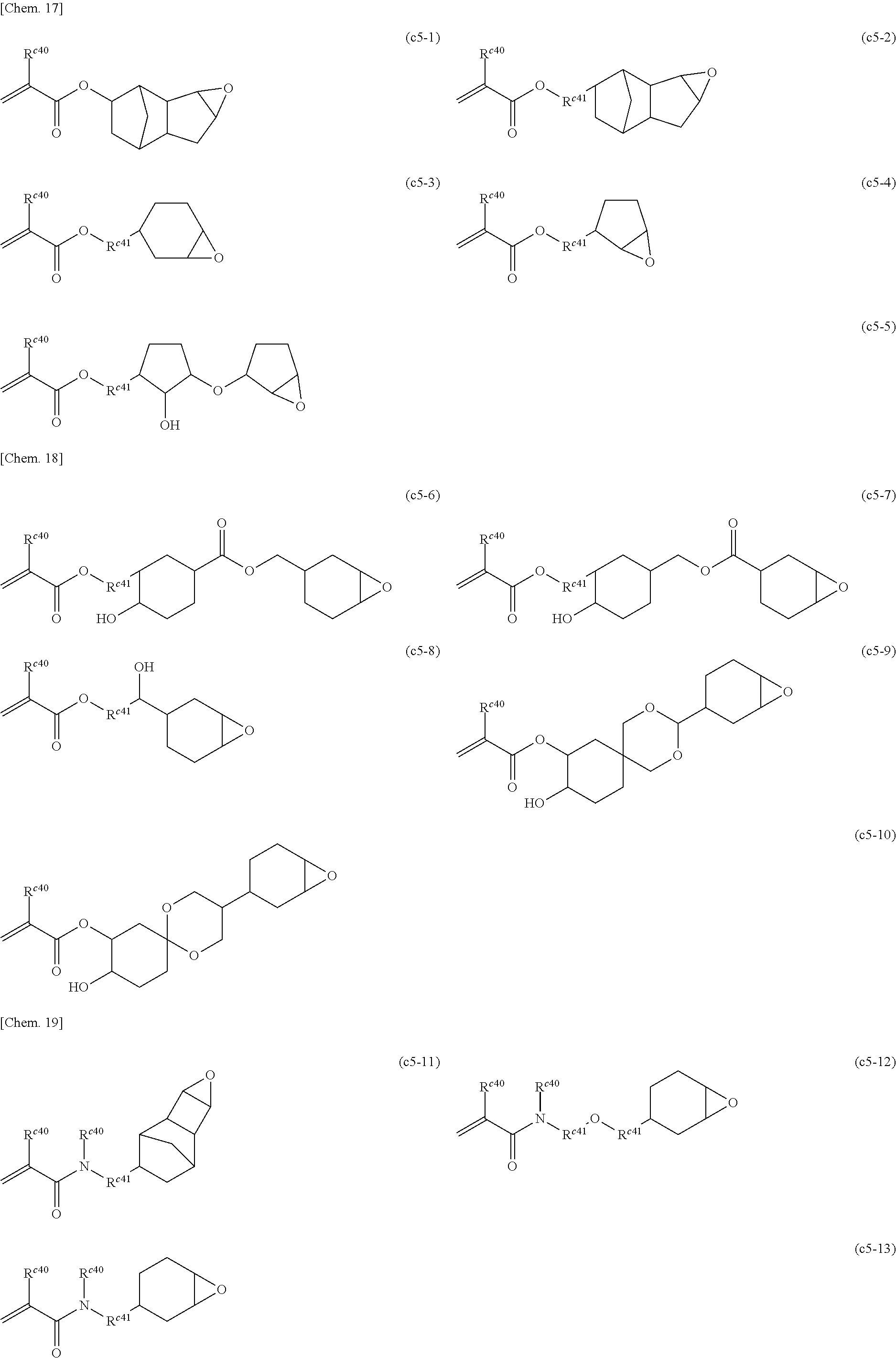

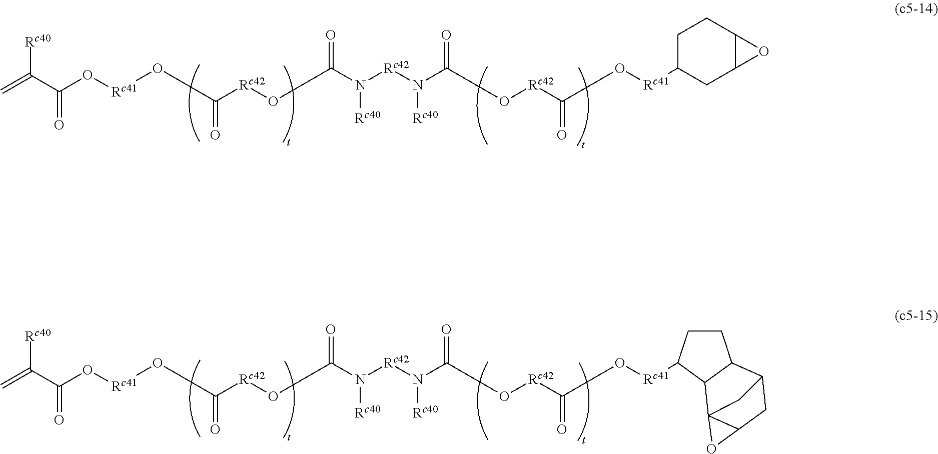

In the above formulas, R^{c40} represents a hydrogen atom or a methyl group. R^{c41} represents a divalent aliphatic saturated hydrocarbon group having 1 or more and 6 or less carbon atoms. R^{c42} represents a divalent hydrocarbon group having 1 or more and 10 or less carbon atoms. t represents an integer of 0 or more and 10 or less. R^{c41} is a linear or branched alkylene group and is preferably, for example, a methylene group, an ethylene group, a propylene group, a tetramethylene group, an ethylethylene group, a pentamethylene group, or a hexamethylene group. R^{c42} is preferably, for example, a methylene group, an ethylene group, a propylene group, a tetramethylene group, an ethylethylene group, a pentamethylene group, a hexamethylene group, a phenylene group, or a cyclohexylene group.

It is possible to use, as the polymer having an epoxy group, both of a homopolymer of a (meth)acrylic acid ester having an epoxy group, and a copolymer of a (meth)acrylic acid ester having an epoxy group with the other monomer. The content of a unit derived from the (meth)acrylic acid ester having an epoxy group in the polymer having an epoxy group is preferably 70% by mass or more, more preferably 80% by mass or more, particularly preferably 90% by mass or more, and most preferably 100% by mass.

When the polymer having an epoxy group is a copolymer of the (meth)acrylic acid ester having an epoxy group with the other monomer, examples of the other monomer include an unsaturated carboxylic acid, a (meth)acrylic acid ester having no epoxy group, (meth)acrylamides, an allyl compound, vinyl ethers, vinyl esters, styrenes, maleimide, and the like. These compounds can be used individually, or two or more thereof can be used in combination. In view of storage stability of the composition, and chemical resistance of a cured film formed using the composition against alkali, it is preferred that the copolymer of the (meth)acrylic acid ester having an epoxy group with other monomer does not include a unit derived from an unsaturated carboxylic acid.

Examples of the unsaturated carboxylic acid include (meth)acrylic acid; (meth)acrylic acid amide; crotonic acid; maleic acid, fumaric acid, citraconic acid, mesaconic acid, itaconic acid, and anhydrides of these dicarboxylic acids.

Examples of the (meth)acrylic acid ester having no epoxy group include linear or branched alkyl (meth)acrylates such as methyl (meth)acrylate, ethyl (meth)acrylate, propyl (meth)acrylate, amyl (meth)acrylate, and t-octyl (meth)acrylate; chloroethyl (meth)acrylate, 2,2-dimethylhydroxypropyl (meth) acrylate, 2-hydroxyethyl (meth)acrylate, trimethylolpropane mono(meth)acrylate, benzyl (meth)acrylate, furfuryl (meth)acrylate; and a (meth)acrylic acid ester having a group with an alicyclic skeleton. Of (meth)acrylic acid esters having no epoxy group, a (meth)acrylic acid ester having a group with an alicyclic skeleton is preferable.

In the (meth)acrylic acid ester having a group with an alicyclic skeleton, an alicyclic group composing the alicyclic skeleton may be either monocyclic or polycyclic. Examples of the monocyclic alicyclic group include a cyclopentyl group, a cyclohexyl group, and the like. Examples of the polycyclic alicyclic group include a norbornyl group, an isobornyl group, a tricyclononyl group, a tricyclodecyl group, a tetracyclododecyl group, and the like.

Examples of the (meth)acrylic acid ester having a group with an alicyclic skeleton include compounds represented by the following formulas (c6-1) to (c6-8). Of these compounds, compounds represented by the following formulas (c6-3) to (c6-8) are preferable, and compounds represented by the following formulas (c6-3) or (c6-4) are more preferable.

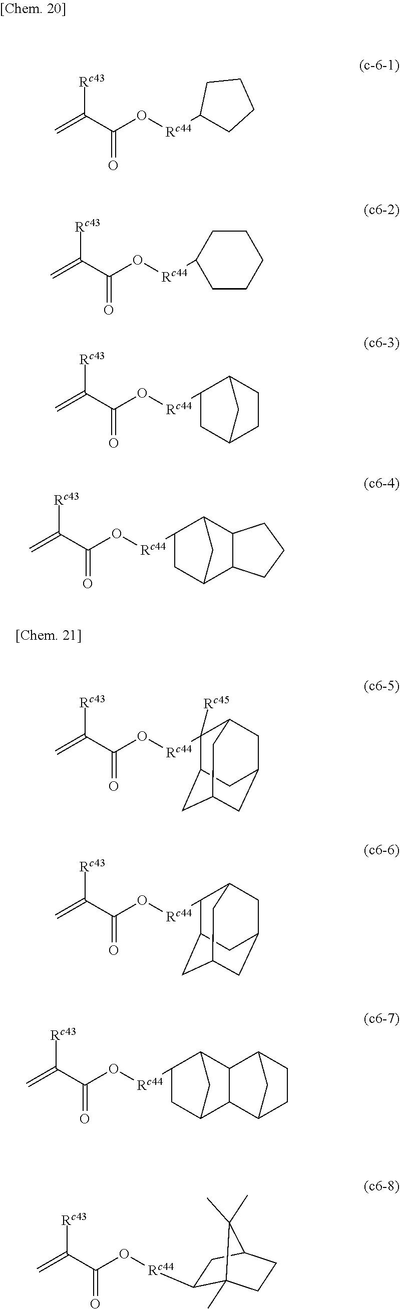

In the above formulas, R^{c43} represents a hydrogen atom or a methyl group. R^{c44} represents a single bond or a divalent aliphatic saturated hydrocarbon group having 1 or more and 6 or less carbon atoms. R^{c45} represents a hydrogen atom or an alkyl group having 1 or more and 5 or less carbon atoms. R^{c44} is preferably a single bond, or a linear or branched alkylene group, for example, a methylene group, an ethylene group, a propylene group, a tetramethylene group, an ethylethylene group, a pentamethylene group, or a hexamethylene group. R^{c45} is preferably a methyl group or an ethyl group.

Examples of (meth)acrylamides include (meth)acrylamide, N-alkyl(meth)acrylamide, N-aryl(meth)acrylamide, N,N-dialkyl(meth)acrylamide, N,N-aryl(meth)acrylamide, N-methyl-N-phenyl(meth)acrylamide, N-hydroxyethyl-N-methyl(meth)acrylamide, and the like.

Examples of the allyl compound include allyl esters such as allyl acetate, allyl caproate, allyl caprylate, allyl laurate, allyl palmitate, allyl stearate, allyl benzoate, allyl acetoacetate, and allyl lactate; allyloxyethanol, and the like.

Examples of vinyl ethers include aliphatic vinyl ethers such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, and tetrahydrofurfuryl vinyl ether; vinyl aryl ethers such as vinyl phenyl ether, vinyl tolyl ether, vinyl chlorophenyl ether, vinyl-2,4-dichlorophenyl ether, vinyl naphthyl ether, and vinyl anthranyl ether; and the like.

Examples of vinyl esters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl β-phenylbutyrate, vinyl benzoate, vinyl salicylate, vinyl chlorobenzoate, vinyl tetrachlorobenzoate, vinyl naphthoate, and the like.

Examples of styrenes include styrene; alkylstyrenes such as methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, and acetoxymethylstyrene; alkoxystyrenes such as methoxystyrene, 4-methoxy-3-methylstyrene, and dimethoxystyrene; halostyrenes such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene; and the like.

Examples of maleimides include maleimides N-substituted with alkyl group having 1 or more and 10 or less carbon atoms such as N-methylmaleimide, N-ethylmaleimide, N-n-propylmaleimide, N-isopropylmaleimide, N-n-butylmaleimide, N-n-pentylmaleimide, and N-n-hexylmaleimide; maleimides N-substituted with cycloalkyl group having 3 or more and 20 or less carbon atoms such as N-cyclopentylmaleimide, N-cyclohexylmaleimide, and N-cycloheptylmaleimide; N-arylmaleimides N-substituted with aryl group having 6 or more and 20 or less carbon atoms; N-aralkylmaleimides N-substituted with aralkyl group having 7 or more and 20 or less carbon atoms such as N-benzylmaleimide, and N-phenethylmaleimide.

The molecular weight of the epoxy-group-containing resin is not particularly limited as long as the object of the present invention is not impaired, but the molecular weight is preferably 3,000 or more and 30,000 or less, more preferably 5,000 or more and 15,000 or less in terms of the mass average molecular weight of polystyrene.

### [Photocurable Low-Molecular-Weight Compounds]

The composition may include a photopolymerizable low-molecular-weight compound (photopolymerizable monomer) as the base component (C). In the case in which a polyfunctional photopolymerizable low-molecular-weight compound is included, a photopolymerization initiator described below or the like is preferably contained in the composition. The photopolymerizable low-molecular-weight compound may be a monofunctional monomer or a polyfunctional monomer. Next, the monofunctional monomer and the polyfunctional monomer are described in order.

Examples of the monofunctional monomer include (meth) acrylamide, methylol (meth) acrylamide, methoxymethyl(meth)acrylamide, ethoxymethyl(meth)acrylamide, propoxymethyl(meth)acrylamide, butoxymethoxymethyl(meth)acrylamide, N-methylol (meth) acrylamide, N-hydroxymethyl(meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamide sulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerol mono(meth)acrylate, tetrahydrofurfuryl (meth)acrylate, N,N-dimethyl-2-aminoethyl (meth)acrylate, glycidyl (meth)acrylate, 2,2,2-trifluoroethyl (meth)acrylate, 2,2,3,3-tetrafluoropropyl (meth)acrylate, and half (meth)acrylates of phthalic acid derivatives. These monofunctional monomers may be used individually, or two or more thereof may be used in combination.

Examples of the polyfunctional monomer include polyfunctional monomers such as ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerol di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, ethylene glycol diglycidyl ether di(meth)acrylate, diethylene glycol diglycidyl ether di(meth)acrylate, phthalic acid diglycidyl ester di(meth)acrylate, glycerol triacrylate, glycerol polyglycidyl ether poly(meth)acrylate, urethane (meth)acrylate (in other words, a reaction product of tolylene diisocyanate, trimethylhexamethylene diisocyanate, hexamethylene diisocyanate, or the like with 2-hydroxyethyl (meth)acrylate), methylenebis(meth)acrylamide, (meth)acrylamide methylene ether, condensates of a polyhydric alcohol and N-methylol (meth)acrylamide, and triacrylformal. These polyfunctional monomers may be used individually, or two or more thereof may be used in combination.

### [Photopolymerizable Polymer Compound]

The composition may contain a photopolymerizable polymer compound as the base component (C). As the photopolymerizable polymer compound, a resin containing an ethylenically unsaturated group is preferably used. Examples of the resin containing an ethylenically unsaturated group include oligomers derived from polymerization of (meth)acrylic acid, fumaric acid, maleic acid, monomethyl fumarate, monoethyl fumarate, 2-hydroxyethyl (meth)acrylate, ethylene glycol monomethyl ether (meth)acrylate, ethylene glycol monoethyl ether (meth)acrylate, glycerol (meth)acrylate, (meth) acrylamide, acrylonitrile, methacrylonitrile, methyl (meth)acrylate, ethyl (meth)acrylate, isobutyl (meth)acrylate, 2-ethylhexyl (meth)acrylate, benzyl (meth)acrylate, ethylene glycol di(meth)acrylate, diethylene glycol di(meth)acrylate, triethylene glycol di(meth)acrylate, tetraethylene glycol di(meth)acrylate, butylene glycol di(meth)acrylate, propylene glycol di(meth)acrylate, trimethylolpropane tri(meth)acrylate, tetramethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, 1,6-hexanediol di(meth)acrylate, and cardo epoxy diacrylate; polyester (meth)acrylates obtained by subjecting a polyester prepolymer derived from condensation between a polyhydric alcohol and a monobasic acid or a polybasic acid to reaction with (meth)acrylic acid; polyurethane (meth)acrylates obtained by subjecting a polyol and a compound having two isocyanate groups to reaction and then subjecting the resulting product to reaction with (meth)acrylic acid; and epoxy (meth)acrylate resins obtained by subjecting an epoxy resin such as a bisphenol A type epoxy resin, a bisphenol F type epoxy resin, a bisphenol S type epoxy resin, a phenol or cresol novolak type epoxy resin, a resole type epoxy resin, a triphenol methane type epoxy resin, a polycarboxylic acid polyglycidyl ester, a polyol polyglycidyl ester, an aliphatic or alicyclic epoxy resin, an amine epoxy resin, or a dihydroxybenzene type epoxy resin to reaction with (meth)acrylic acid. A resin obtained by subjecting an epoxy (meth)acrylate resin to reaction with a polybasic acid anhydride may also be suitable for use. In the present description, “(meth)acryl” means “acryl or methacryl”.

A preferable resin containing an ethylenically unsaturated group is a resin obtained by subjecting a product of reaction between an epoxy compound and a carboxylic acid compound containing an unsaturated group to another reaction with a polybasic acid anhydride or a resin obtained by subjecting at least some of the carboxy groups of a polymer including a unit derived from an unsaturated carboxylic acid to reaction with a (meth)acrylic acid ester having an alicyclic epoxy group and/or a (meth)acrylic acid epoxyalkyl ester (hereinafter, these resins are collectively called “resin containing a constituent unit having an ethylenically unsaturated group”). The ethylenically unsaturated group of the constituent unit having an ethylenically unsaturated group is preferably a (meth)acryloyloxy group.

Among these, a resin containing a constituent unit having an ethylenically unsaturated group or a compound represented by the following formula (c7) is preferable. This compound represented by the formula (c7) is preferable because the compound itself is highly photocurable.

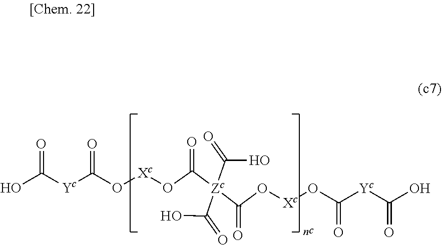

In the formula (c7), X^{c} represents a group represented by the following formula (c8).

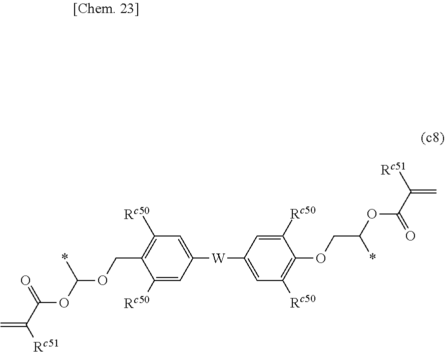

In the formula (c8), R^{c50} represents each independently a hydrogen atom, a hydrocarbon group having 1 or more and 6 or less carbon atoms, or a halogen atom. R^{c51} represents each independently a hydrogen atom or a methyl group. W represents a single bond or a group represented by the following structural formula (c9). In the formulas (c8) and (c9), “*” represents the position where the divalent group is bonded.

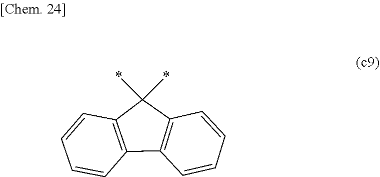

In the formula (c7), Y^{c} represents a residue that is obtained by removing an acid anhydride group (—CO—O—CO—) from a dicarboxylic anhydride. Examples of the dicarboxylic anhydride include maleic anhydride, succinic anhydride, itaconic anhydride, phthalic anhydride, tetrahydrophthalic anhydride, hexahydrophthalic anhydride, methylendomethylene tetrahydrophthalic anhydride, chlorendic anhydride, methyltetrahydrophthalic anhydride, and glutaric anhydride.

In the formula (c7), Z^{c} represents a residue that is obtained by removing two acid anhydride groups from a tetracarboxylic dianhydride. Examples of the tetracarboxylic dianhydride include pyromellitic anhydride, benzophenonetetracarboxylic dianhydride, biphenyltetracarboxylic dianhydride, and biphenyl ether tetracarboxylic dianhydride. In the formula (c7), n^{c} represents an integer of 0 or more and 20 or less.

The acid value of the resin containing an ethylenically unsaturated group is preferably 10 mg KOH/g or more and 150 mg KOH/g or less, more preferably 70 mg KOH/g or more and 110 mg KOH/g or less in terms of resin solid content. The acid value is preferably not lower than 10 mg KOH/g to be likely to obtain a composition having sufficient solubility in a developing solution in the case of imparting photolithography properties to the composition. The acid value is preferably not higher than 150 mg KOH/g to obtain sufficient curability and excellent surface properties.

The mass average molecular weight of the resin containing an ethylenically unsaturated group is preferably 1,000 or more and 40,000 or less, more preferably 2,000 or more and 30,000 or less. The mass average molecular weight is preferably not lower than 1,000 to be likely to form a cured film excellent in heat resistance and excellent film strength. The mass average molecular weight is preferably not higher than 40,000 to achieve excellent development.

### {Resin for Formation of Cured Film by Baking}

The resin for formation of a cured film a by baking is exemplified by a silicon-containing resin. Examples of a preferred silicon-containing resin include one or more selected from a siloxane resin and polysilane. Application of the composition including these silicon-containing resins gives a quantum dot-containing film that includes the silicon-containing resin, and baking of the quantum dot-containing film gives a silica-based quantum dot-containing film. Preferred examples of the silicon-containing resin such as siloxane resin and polysilane include a silicon-containing resin described in from paragraph [0022] to paragraph [0070] of Japanese Unexamined Patent Application Publication No. 2018-109761.

The content of the silicon-containing resin in the composition is not particularly limited and may be determined depending on the desired film thickness. From the viewpoint of film-forming properties, the content of the silicon-containing resin in the composition is preferably 1% by mass or more and 50% by mass or less, more preferably 5% by mass or more and 40% by mass or less, particularly preferably 10% by mass or more and 35% by mass or less.

The content of the base component (C) in the composition is not limited as long as a desired amount of the quantum dots (A) is included in the composition, and (A):(C) in terms of the mass ratio is preferably 99:1 to 1:99, and more preferably 90:10 to 10:90.

### {Curing Agent (D)}

In the case in which the composition includes, as the base component (C), a component such as an epoxy compound or an oxetane compound, a photocurable component, and/or a silicon-containing resin, the composition preferably includes a curing agent (D) as a component for curing the base component (C). Here, in the present description, the curing agent (D) is not particularly limited as long as the curing agent (D) can cause curing of the base component (C). For example, the so-called photopolymerization initiator and the like falls under the curing agent (D) in the present description. It should be noted that in the case in which the base component (C) included in the composition is an epoxy compound or an oxetane compound having a functional group such as a carboxy group, a carboxylic anhydride group or an amino group, which is reactive with an epoxy group or an oxetanyl group, the composition does not necessarily contain the curing agent.

### [Photopolymerization Initiator (D1)]

A photopolymerization initiator (D1) is used in combination with the photocurable base component (C) having an unsaturated double bond and cures the photocurable base component (C) through light exposure. The photopolymerization initiator (D1) is not particularly limited and may be a conventionally known photopolymerization initiator.

Specific examples of the photopolymerization initiator (D1) include 1-hydroxycyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl) ketone, 2-methyl-1-[4-(methylthio)phenyl]-2-morpholinopropan-1-one, 2-benzyl-2-dimethylamino-1-(4-morpholinophenyl)-butan-1-one, 0-acetyl-1-[6-(2-methylbenzoyl)-9-ethyl-9H-carbazol-3-yl]ethanone oxime, (9-ethyl-6-nitro-9H-carbazol-3-yl)[4-(2-methoxy-1-methylethoxy)-2-methylphenyl]methanon 0-acetyloxime, 1,2-octanedione, 1-[4-(phenylthio)-, 2-(benzoyloxime), 2,4,6-trimethylbenzoyldiphenylphosphine oxide, 4-benzoyl-4′-methyldimethyl sulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-(3-methoxyethyl acetal, benzyl dimethyl ketal, 1-phenyl-1,2-propanedion-2-(O-ethoxycarbonyl) oxime, methyl o-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzil, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, dibenzosuberone, pentyl 4-dimethylaminobenzoate, 9-phenylacridine, 1,7-bis-(9-acridinyl)heptane, 1,5-bis-(9-acridinyl)pentane, 1,3-bis-(9-acridinyl) propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(furan-2-yl)ethenyl]-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, and 2,4-bis-trichloromethyl-6-(2-bromo-4-methoxy)styrylphenyl-s-triazine. The photopolymerization initiator (D1) may be used either individually or in combination of two or more.

Among these, an oxime-type photopolymerization initiator is particularly preferable from the viewpoint of sensitivity. Examples of the particularly preferable oxime-type photopolymerization initiator include O-acetyl-1-[6-(2-methylbenzoyl)-9-ethyl-9H-carbazol-3-yl]ethanone oxime, 0-acetyl-1-[6-(2-methylbenzoyl)-9-ethyl-9H-carbazol-3-yl]ethanone oxime, and 1,2-octanedione, 1-[4-(phenylthio)-, 2-(0-benzoyloxime)]. In addition, an oxime ester compound described later as a curing agent for a silicon-containing resin is also preferably used as the photopolymerization initiator.

The content of the photopolymerization initiator (D1) is preferably 0.5 parts by mass or more and 30 parts by mass or less, more preferably 1 part by mass or more and 20 parts by mass or less parts by mass relative to 100 parts by mass of the solid content of the composition.

The photopolymerization initiator (D1) may be used in combination with a photoinitiator aid. Examples of the photoinitiator aid include triethanolamine, methyldiethanolamine, triisopropanolamine, methyl 4-dimethylaminobenzoate, ethyl 4-dimethylaminobenzoate, isoamyl 4-dimethylaminobenzoate, 2-ethylhexyl 4-dimethylaminobenzoate, 2-dimethylaminoethyl benzoate, N,N-dimethyl-p-toluidine, 4,4′-bis(dimethylamino)benzophenone, 9,10-dimethoxyanthracene, 2-ethyl-9,10-dimethoxyanthracene, 9,10-diethoxyanthracene, 2-ethyl-9,10-diethoxyanthracene, and thiol compounds such as 2-mercaptobenzothiazole, 2-mercaptobenzoxazole, 2-mercaptobenzimidazole, 2-mercapto-5-methoxybenzothiazole, 3-mercaptopropionic acid, methyl 3-mercaptopropionate, pentaerythritol tetramercaptoacetate, and 3-mercaptopropionate. The photoinitiator aid may be used either individually or in combination of two or more.

### [Onium Salt (D2)]

The onium salt (D2) can be used together with an epoxy-group-containing resin, an epoxy compound, an oxetane compound, or the like, and accelerates curing of the epoxy-group-containing resin, the epoxy compound, the oxetane compound or the like by the action of light or heat. The onium salt is exemplified by a diazonium salt, an ammonium salt, an iodonium salt, a sulfonium salt, a phosphonium salt, an oxonium salt, and the like. Among these, a sulfonium salt and an iodonium salt are preferable in light of availability and favorable curing. The onium salt (D2) is appropriately selected from conventionally known onium salts used for curing epoxy group-containing resins, epoxy compounds, oxetane compounds or the like.

Next, examples of a preferable onium salt (D2) are described. As a preferable example of the onium salt (D2), a sulfonium salt represented by the following formula (D-I) (hereinafter, also referred to as “sulfonium salt (Q)”) can be mentioned.

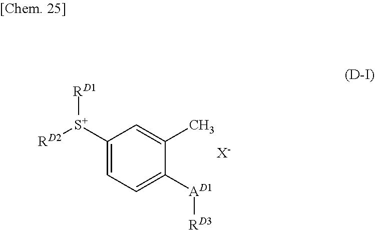

In the formula (D-I), R^{D1} and R^{D2} independently represent an alkyl group optionally substituted with a halogen atom or a group represented by the following formula (D-II); R^{D1} and R^{D2} may be bonded to each other to form a ring together with the sulfur atom in the formula; R^{D3} represents a group represented by the following formula (D-III) or a group represented by the following formula (D-IV); A^{D1} represents S, O or Se; X⁻ represents a monovalent anion; with the proviso that R^{D1} and R^{D2} are not simultaneously an alkyl group optionally substituted with a halogen atom.

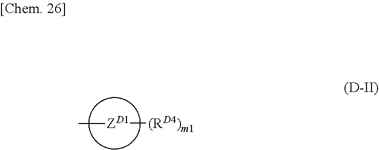

In the formula (D-II), a ring Z^{D1} represents an aromatic hydrocarbon ring; R^{D4} represents an alkyl group optionally substituted with a halogen atom, a hydroxy group, an alkoxy group, an alkylcarbonyl group, an alkoxycarbonyl group, an acyloxy group, an alkylthio group, a thienyl group, a thienylcarbonyl group, a furanyl group, a furanylcarbonyl group, a selenophenyl group, a selenophenylcarbonyl group, a heterocyclic aliphatic group, an alkylsulfinyl group, an alkylsulfonyl group, a hydroxy(poly)alkyleneoxy group, an optionally substituted amino group, a cyano group, a nitro group or a halogen atom; and m1 represents an integer of 0 or more.

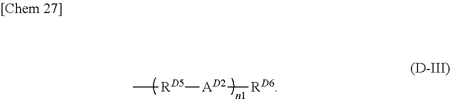

In the formula (D-III), R^{D5} represents an alkylene group optionally substituted with a hydroxy group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, a hydroxy(poly)alkyleneoxy group, an optionally substituted amino group, a cyano group, a nitro group or a halogen atom, or a group represented by the following formula (D-V); R^{D6} represents an alkyl group optionally substituted with a hydroxy group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, a hydroxy(poly)alkyleneoxy group, an optionally substituted amino group, a cyano group, a nitro group or a halogen atom, or a group represented by the following formula (D-VI); A^{D2} represents a single bond, S, O, a sulfinyl group or a carbonyl group; and n1 represents 0 or 1.

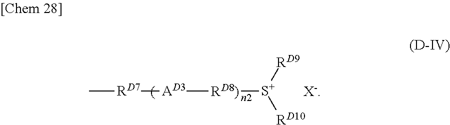

In the formula (D-IV), R^{D7} and R^{D8} independently represent an alkylene group optionally substituted with a hydroxy group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, a hydroxy(poly)alkyleneoxy group, an optionally substituted amino group, a cyano group, a nitro group or a halogen atom, or a group represented by the following formula (D-V); R^{D9} and R^{D10} independently represent an alkyl group optionally substituted with a halogen atom or a group represented by the above formula (D-II); R^{D9} and R^{D10} may be bonded to each other to form a ring together with the sulfur atom in the formula; A^{D3} represents a single bond, S, O, a sulfinyl group or a carbonyl group; X⁻ is the same as defined above; n2 represents 0 or 1; with the proviso that R^{D9} and R^{D10} are not simultaneously an alkyl group optionally substituted with a halogen atom.

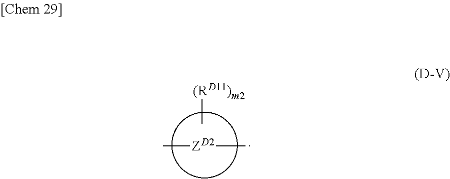

In the formula (D-V), a ring Z^{D2} represents an aromatic hydrocarbon ring; R^{D11} represents an alkyl group optionally substituted with a halogen atom, a hydroxy group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, a hydroxy(poly)alkyleneoxy group, an optionally substituted amino group, a cyano group, a nitro group or a halogen atom; and m2 represents an integer of 0 or more.

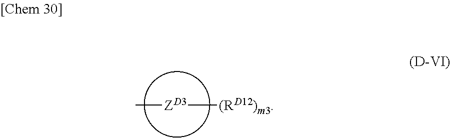

In the formula (D-VI), a ring Z^{D3} represents an aromatic hydrocarbon ring; R^{D12} represents an alkyl group optionally substituted with a halogen atom, a hydroxy group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, a thienylcarbonyl group, a furanylcarbonyl group, a selenophenylcarbonyl group, an aryl group, a heterocyclic group, an aryloxy group, an alkylsulfinyl group, an arylsulfinyl group, an alkylsulfonyl group, an arylsulfonyl group, a hydroxy(poly)alkyleneoxy group, an optionally substituted amino group, a cyano group, a nitro group or a halogen atom; and m3 represents an integer of 0 or more.

### (Sulfonium Salt (Q))

The sulfonium salt (Q) will now be described. The sulfonium salt (Q) is characterized in that a methyl group is bonded to the carbon atom at the ortho position of the carbon atom to which A^{D1} is bonded in the benzene ring in the above formula (D-I). Because of the methyl group at the above-described position, the sulfonium salt (Q) easily generates a proton and is highly sensitive to active energy rays such as ultraviolet rays compared to conventional sulfonium salts.

In the above formula (D-I), both of R^{D1} and R^{D2} are preferably a group represented by the above formula (D-II). R^{D1} and R^{D2} may be the same or different. In the formula (D-I), when R^{D1} and R^{D2} are bonded to each other to form a ring together with the sulfur atom in the formula, the number of atoms constituting a ring formed is preferably 3 or more and 10 or less including the sulfur atom, and more preferably 5 or more and 7 or less. The ring thus formed may be a polycyclic ring, and is preferably a polycyclic ring obtained by condensation of monocycles in which the number of atoms constituting the rings is 5 or more and 7 or less. In the above formula (D-I), both R^{D1} and R^{D2} are preferably a phenyl group. In the above formula (D-I), R^{D3} is preferably a group represented by the above formula (D-III). In the above formula (D-I), A^{D1} is preferably S or O, and more preferably S.

In the above formula (D-II), R^{D4} is preferably an alkyl group optionally substituted with a halogen atom, a hydroxy group, an alkylcarbonyl group, a thienylcarbonyl group, a furanylcarbonyl group, a selenophenylcarbonyl group, an optionally substituted amino group or a nitro group, and more preferably an alkyl group optionally substituted with a halogen atom, an alkylcarbonyl group or a thienylcarbonyl group. In the above formula (D-II), m1 can be selected depending on the type of the ring Z^{D1}, and may be, for example, an integer of 0 or more and 4 or less, preferably an integer of 0 or more and 3 or less, and more preferably an integer of 0 or more and 2 or less.

In the above formula (D-III), R^{D5} is preferably an alkylene group; an alkylene group substituted with a hydroxy group, an optionally substituted amino group or a nitro group; or a group represented by the above formula (D-V); and more preferably a group represented by the above formula (D-V). In the above formula (D-III), R^{D6} is preferably an alkyl group; an alkyl group substituted with a hydroxy group, an optionally substituted amino group or a nitro group; or a group represented by the above formula (D-VI); and more preferably a group represented by the above formula (D-VI). In the above formula (D-III), A^{D2} is preferably S or O, and more preferably S. In the above formula (D-III), n1 is preferably 0.

In the above formula (D-IV), R^{D7} and R^{D8} are independently preferably an alkylene group; an alkylene group substituted with a hydroxy group, an optionally substituted amino group or a nitro group; or a group represented by the above formula (D-V); and more preferably a group represented by the above formula (D-V). R^{D7} and R^{D8} may be the same or different. In the above formula (D-IV), both R^{D9} and R^{D10} are preferably a group represented by the above formula (D-II). R^{D9} and R^{D10} may be the same or different. In the above formula (D-IV), when R^{D9} and R^{D10} are bonded to each other to form a ring together with the sulfur atom in the formula, the number of atoms constituting a ring formed is preferably 3 or more and 10 or less including the sulfur atom, and more preferably 5 or more and 7 or less. The ring thus formed may be a polycyclic ring, and is preferably a polycyclic ring obtained by condensation of monocycles in which the number of atoms constituting the rings is 5 or more and 7 or less. In the above formula (D-IV), A^{D3} is preferably S or O, and more preferably S. In the above formula (D-IV), n2 is preferably 0.

In the above formula (D-V), R^{D11} is preferably an alkyl group optionally substituted with a halogen atom, a hydroxy group, an optionally substituted amino group or a nitro group, and more preferably an alkyl group optionally substituted with a halogen atom. In the above formula (D-V), m2 can be selected depending on the type of the ring Z^{D2}, and may be, for example, an integer of 0 or more and 4 or less, preferably an integer of 0 or more and 3 or less, and more preferably an integer of 0 or more and 2 or less.

In the above formula (D-VI), R^{D12} is preferably an alkyl group optionally substituted with a halogen atom, a hydroxy group, an alkylcarbonyl group, a thienylcarbonyl group, a furanylcarbonyl group, a selenophenylcarbonyl group, an optionally substituted amino group or a nitro group, and more preferably an alkyl group optionally substituted with a halogen atom, an alkylcarbonyl group or a thienylcarbonyl group. In the above formula (D-VI), m3 can be selected depending on the type of the ring Z^{D3} and may be, for example, an integer of 0 or more and 4 or less, preferably an integer of 0 or more and 3 or less, and more preferably an integer of 0 or more and 2 or less.

In the above formula (D-I), X⁻ is a monovalent anion. Suitable examples of X⁻ include a monovalent polyatomic anion, and X⁻ is more preferably an anion represented by MYₐ⁻, (Rf)_{b}PF_{6-b}⁻, R^{x1}_{c} BY_{4-c}⁻, R^{x1}_{c}GaY_{4-c}⁻, R^{x2}SO₃⁻, (R^{x2}SO₂)₃C⁻ or (R^{x2}SO₂)₂N⁻. In addition, X⁻ may be a halogen anion and examples thereof include a fluoride ion, a chloride ion, a bromide ion, an iodide ion and the like.

M represents a phosphorus atom, a boron atom or an antimony atom. Y represents a halogen atom (preferably a fluorine atom).

Rf represents an alkyl group in which 80 mol % or higher of hydrogen atoms are substituted with fluorine atoms (an alkyl group having 1 or more and 8 or less carbon atoms is preferred). Examples of the alkyl group which is used as Rf by fluorine substitution include linear alkyl groups (such as methyl, ethyl, propyl, butyl, pentyl and octyl), branched alkyl groups (such as isopropyl, isobutyl, sec-butyl and tert-butyl), and cycloalkyl groups (such as cyclopropyl, cyclobutyl, cyclopentyl and cyclohexyl) and the like. The proportion of hydrogen atoms substituted with fluorine atoms in these alkyl groups in Rf is preferably 80 mol % or higher, further preferably 90% or higher, particularly preferably 100% based on the number of moles of hydrogen atoms included in an original alkyl group. When the proportion of substitution with fluorine atoms is within these preferred ranges, the sulfonium salt (Q) has a further good light sensitivity. Particularly preferred examples of Rf include CF₃⁻, CF₃CF₂—, (CF₃)₂CF⁻, CF₃CF₂CF₂⁻, CF₃CF₂CF₂CF₂⁻, (CF₃)₂CFCF₂⁻, CF₃CF₂ (CF₃) CF⁻ and (CF₃)₃C⁻. The b number of Rf are independent from each other and thus may be the same or different.

P represents a phosphorus atom, and F represents a fluorine atom.

R^{x1} represents a phenyl group in which part of the hydrogen atoms are substituted with at least one element or electron-withdrawing group. Examples of the one element include halogen atoms such as a fluorine atom, a chlorine atom and a bromine atom. Examples of the electron-withdrawing group include a trifluoromethyl group, a nitro group and a cyano group, and the like. Among these, a phenyl group in which at least one hydrogen atom is substituted with a fluorine atom or a trifluoromethyl group is preferred. The c number of R^{x1} are independent from each other and thus may be the same or different.

B represents a boron atom, and Ga represents a gallium atom.

R^{x2} represents an alkyl group having 1 or more and 20 or less carbon atoms, a fluoroalkyl group having 1 or more and 20 or less carbon atoms, or an aryl group having 6 or more and 20 or less carbon atoms, the alkyl group and the fluoroalkyl group may be linear, branched or cyclic, and the alkyl group, fluoroalkyl group or aryl group may be unsubstituted or have a substituent. Examples of the above substituent include a hydroxy group, an optionally substituted amino group, a nitro group and the like. For example, examples of the optionally substituted amino group include the groups exemplified in the description described below regarding the above formulas (D-II) to (D-VI). In addition, the carbon chain of the alkyl group, fluoroalkyl group or aryl group represented by R^{x2} may have a heteroatom such as an oxygen atom, a nitrogen atom or a sulfur atom. In particular, the carbon chain of the alkyl group or fluoroalkyl group represented by R^{x2} may have a divalent functional group (for example, an ether bond, a carbonyl bond, an ester bond, an amino bond, an amide bond, an imide bond, a sulfonyl bond, a sulfonylamide bond, a sulfonylimide bond, a urethane bond, etc.). When the alkyl group, fluoroalkyl group or aryl group represented by R^{x2} has the above substituent, heteroatom or functional group, the number of the above substituents, heteroatoms or functional groups may be one or two or more.

S represents a sulfur atom, 0 represents an oxygen atom, C represents a carbon atom, and N represents a nitrogen atom. a represents an integer of 4 or more and 6 or less. b is preferably an integer of 1 or more and 5 or less, further preferably an integer of 2 or more and 4 or less, and particularly preferably 2 or 3. c is preferably an integer of 1 or more and 4 or less, and further preferably 4.

Examples of the anion represented by MYₐ⁻ include an anion represented by SbF₆⁻, PF₆⁻ or BF₄⁻, and the like.

Examples of the anion represented by (Rf)_{b}PF_{6-b}⁻ include an anion represented by (CF₃CF₂)₂PF₄⁻, (CF₃CF₂)₃PF₃⁻, ((CF₃)₂CF)₂PF₄⁻, ((CF₃)₂CF)₃PF₃⁻, (CF₃CF₂CF₂)₂PF₄⁻, (CF₃CF₂CF₂)₃PF₃⁻, ((CF₃)₂CFCF₂)₂PF₄⁻, ((CF₃)₂CFCF₂)₃PF₃⁻, (CF₃CF₂CF₂CF₂)₂PF₄⁻ or (CF₃CF₂CF₂CF₂)₃PF₃⁻, and the like. Among these, an anion represented by (CF₃CF₂)₃PF₃⁻, (CF₃CF₂CF₂)₃PF₃⁻, ((CF₃)₂CF)₃PF₃⁻, ((CF₃)₂CF)₂PF₄⁻, ((CF₃)₂CFCF₂)₃PF₃⁻ or ((CF₃)₂CFCF₂)₂PF₄⁻ is preferred.

The anion represented by R^{x1}_{c}BY_{4-c}⁻ is preferably: R^{x1}_{c}BY_{4-c}⁻,

herein R^{x1} represents a phenyl group in which at least part of hydrogen atoms are substituted with a halogen atom or an electron-withdrawing group, Y represents a halogen atom, and c represents an integer of 1 or more and 4 or less, and examples thereof include an anion represented by (C₆F₅)₄B⁻, ((CF₃)₂C₆H₃)₄B⁻, (CF₃C₆H₄)₄B⁻, (C₆F₅)₂BF₂⁻, C₆F₅BF₃⁻ or (C₆H₃F₂)₄B⁻, and the like. Among these, an anion represented by (C₆F₅)₄B⁻ or ((CF₃)₂C₆H₃)₄B⁻ is preferred. Examples of the anions represented by R^{x1}_{c}GaY_{4-c}⁻ include tetrakis (nonafluorobiphenyl-4-yl)gallate anion, tetrakis(heptafluoronaphthalene-1-yl)gallate anion, tetrakis(pentafluorophenyl)gallate anion, tetrakis(3,4,5-trifluorophenyl) gallate anion, tetrakis(nonafluorobiphenyl-2-yl)gallate anion, tetrakis(hephtafluoronaphthalene-2-yl)gallate anion, tetrakis(nonafluoroanthracene-7-yl)gallate anion, tetrakis(4′-(methoxy)-octafluorobiphenyl-4-yl)gallate anion, tetrakis(2,4,6-tris(trifluoromethyl)phenyl)gallate anion, tetrakis(3,5-bis(trifluoromethyl)phenyl)gallate anion, tetrakis(2,3-bis(pentafluoroethyl)naphthyl)gallate anion, tetrakis(2-isopropoxy-hexafluoronaphthyl)gallate anion, tetrakis(9,10-bis(hepthafluoropropyl)heptafluoroanthryl)gallate anion, tetrakis(9-nonafluorophenanthryl)gallate anion, tetrakis(4-[tri(isopropyl)silyl]-tetrafluorophenyl)gallate anion, tetrakis(9,10-bis(p-tolyl)-heptafluorophenanthryl)gallate anion, tetrakis(4-[dimethyl(t-butyl)silyl]-tetrafluorophenyl) gallate anion, monophenyl-tris(pentafluorophenyl)gallate anion, monoperfluorobutyl-tris(pentafluorophenyl)gallate anion, monoperfluorobutyl-tris(pentafluorophenyl)gallate anion and the like.

More preferably, an anion represented by (C₆F₅)₄Ga⁻, ((CF₃)₂C₆H₃)₄Ga⁻, (CF₃C₆H₄)₄Ga—, (C₆F₅)₂GaF₂—, C₆F₅GaF₃— or (C₆H₃F₂)₄Ga— is exemplified. Among these, the anion represented by (C₆F₅)₄Ga⁻ or ((CF₃)₂C₆H₃)₄Ga⁻ is further preferable.

Examples of the anion represented by R^{x2}SO₃⁻ include a trifluoromethanesulfonate anion, a pentafluoroethanesulfonate anion, a heptafluoropropanesulfonate anion, a nonafluorobutanesulfonate anion, a pentafluorophenylsulfonate anion, a p-toluenesulfonate anion, a benzenesulfonate anion, a camphorsulfonate anion, a methanesulfonate anion, an ethanesulfonate anion, a propanesulfonate anion and a butanesulfonate anion, and the like. Among these, a trifluoromethanesulfonate anion, a nonafluorobutanesulfonate anion, a methanesulfonate anion, a butanesulfonate anion, a camphorsulfonate anion, a benzenesulfonate anion or a p-toluenesulfonate anion is further preferred.

Examples of the anion represented by (R^{x2}SO₂)₃C⁻ include an anion represented by (CF₃SO₂)₃C⁻, (C₂F₅SO₂)₃C⁻, (C₃F₇SO₂)₃C⁻ or (C₄F₉SO₂)₃C⁻, and the like.

Examples of the anion represented by (R^{x2}SO₂)₂N⁻ include an anion represented by (CF₃SO₂)₂N⁻, (C₂F₅SO₂)₂N⁻, (C₃F₇SO₂)₂N⁻ or (C₄F₉SO₂)₂N⁻, and the like.

As the monovalent polyatomic anion, in addition to an anion represented by MYₐ⁻, (Rf)_{b}PF_{6-b}⁻, R^{x1}_{c}BY_{4-c}⁻, R^{x1}_{c}GaY_{4-c}⁻, R^{x2}SO₃⁻, (R^{x2}SO₂)₃C⁻ or (R^{x2}SO₂)₂N⁻, perhalogenate ions (such as ClO₄⁻ and BrO₄⁻), halogenated sulfonate ions (such as FSO₃⁻ and ClSO₃⁻), sulfate ions (such as CH₃SO₄⁻, CF₃SO₄⁻ and HSO₄⁻), carbonate ions (such as HCO₃⁻ and CH₃CO₃⁻), aluminate ions (such as AlCl₄⁻ and AlF₄⁻), hexafluorobismuthate ion (BiF₆⁻), carboxylate ions (such as CH₃COO⁻, CF₃COO⁻, C₆H₅COO⁻, CH₃C₆H₄COO⁻, C₆F₅COO⁻ and CF₃C₆H₄COO⁻), arylborate ions (such as B(C₆H₅)₄⁻ and CH₃CH₂CH₂CH₂B(C₆H₅)₃⁻), thiocyanate ion (SCN⁻), and nitrate ion (NO₃⁻), and the like can be used.

Among these X⁻, anions represented by MYₐ⁻, (Rf)_{b}PF_{6-b}⁻, R^{x1}_{c}BY_{4-c}⁻, R^{x1}_{c}GaY_{4-c}⁻ and (R^{x2}SO₂)₃C⁻ are preferred, SbF₆⁻, PF₆⁻, (CF₃CF₂)₃PF₃⁻, (C₆F₅)₄B⁻, (CF₃)₂C₆H₃)₄B⁻, (C₆F₅)₄Ga⁻, ((CF₃)₂C₆H₃)₄Ga⁻ and (CF₃SO₂)₃C⁻ are more preferred, and R^{x1}_{c}BY_{4-c}⁻ is further preferred from the viewpoint of cationic polymerization performance.

Examples of the aromatic hydrocarbon ring in the above formulas (D-II), (D-V) and (D-VI) include a benzene ring, condensed polycyclic aromatic hydrocarbon rings [for example, condensed di- to tetracyclic aromatic hydrocarbon rings such as condensed dicyclic hydrocarbon rings (preferably C₈₋₂₀ condensed dicyclic hydrocarbon rings such as a naphthalene ring, and more preferably C₁₀₋₁₆ condensed dicyclic hydrocarbon rings) and condensed tricyclic aromatic hydrocarbon rings (for example, an anthracene ring, a phenanthrene ring, etc.)] and the like. The aromatic hydrocarbon ring is preferably a benzene ring or a naphthalene ring, more preferably a benzene ring.

Examples of the halogen atom in the above formulas (D-I) to (D-VI) include a fluorine atom, a chlorine atom, a bromine atom and an iodine atom, and the like.

Examples of the alkyl group in the above formulas (D-I) to (D-VI) include linear alkyl groups having 1 or more and 18 or less carbon atoms (such as a methyl group, an ethyl group, an n-propyl group, an n-butyl group, an n-pentyl group, an n-octyl group, an n-decyl group, an n-dodecyl group, an n-tetradecyl group, an n-hexadecyl group, and an n-octadecyl group), branched alkyl groups having 3 or more and 18 or less carbon atoms (such as an isopropyl, an isobutyl group, a sec-butyl group, a tert-butyl group, an isopentyl group, a neopentyl group, a tert-pentyl group, an isohexyl group, and an isooctadecyl group), and cycloalkyl groups having 3 or more and 18 or less carbon atoms (such as a cyclopropyl group, a cyclobutyl group, a cyclopentyl group, a cyclohexyl group, and a 4-decylcyclohexyl group). In particular, the alkyl group optionally substituted with a halogen atom in the above formulas (D-I), (D-II) and (D-IV) to (D-VI) means an alkyl group and an alkyl group substituted with a halogen atom. Examples of the alkyl group substituted with a halogen atom include groups in which at least one hydrogen atom in the above linear alkyl groups, branched alkyl groups or cycloalkyl groups is substituted with a halogen atom (such as a monofluoromethyl group, a difluoromethyl group and a trifluoromethyl group) and the like. Among the alkyl groups optionally substituted with a halogen atom, R^{D1}, R^{D2}, R^{D9} or R^{D1}° is particularly preferably a trifluoromethyl group, and R^{D4}, R^{D6}, R^{D11} or R^{D12} is particularly preferably a methyl group.

Examples of the alkoxy group in the above formulas (D-II) to (D-VI) include linear or branched alkoxy groups having 1 or more and 18 or less carbon atoms (such as a methoxy group, an ethoxy, propoxy group, an isopropoxy, butoxy group, an isobutoxy group, a sec-butoxy group, a tert-butoxy group, a hexyloxy group, a decyloxy group, a dodecyloxy group and an octadecyloxy group) and the like.

Examples of the alkyl group in the alkylcarbonyl group in the above formulas (D-II) to (D-VI) include the above linear alkyl groups having 1 or more and 18 or less carbon atoms, branched alkyl groups having 3 or more and 18 or less carbon atoms, or cycloalkyl groups having 3 or more and 18 or less carbon atoms, and examples of the alkylcarbonyl group include linear, branched or cyclic alkylcarbonyl groups having 2 or more and 18 or less carbon atoms (such as an acetyl group, a propionyl group, a butanoyl group, a 2-methylpropionyl group, a heptanoyl group, a 2-methylbutanoyl group, a 3-methylbutanoyl group, an octanoyl, decanoyl group, a dodecanoyl group, an octadecanoyl group, a cyclopentanoyl group and a cyclohexanoyl group) and the like.

Examples of the arylcarbonyl group in the above formulas (D-III) to (D-VI) include arylcarbonyl groups having 7 or more and 11 or less carbon atoms (such as a benzoyl group and a naphthoyl group) and the like.

Examples of the alkoxycarbonyl group in the above formulas (D-II) to (D-VI) include linear or branched alkoxycarbonyl groups having 2 or more and 19 or less carbon atoms (such as a methoxycarbonyl group, an ethoxycarbonyl group, a propoxycarbonyl group, an isopropoxycarbonyl group, a butoxycarbonyl group, an isobutoxycarbonyl group, a sec-butoxycarbonyl group, a tert-butoxycarbonyl group, an octyloxycarbonyl group, a tetradecyloxycarbonyl group and an octadecyloxycarbonyl group) and the like.

Examples of the aryloxycarbonyl group in the above formulas (D-III) to (D-VI) include aryloxycarbonyl groups having 7 or more and 11 or less carbon atoms (such as a phenoxycarbonyl group and a naphthoxycarbonyl group) and the like.

Examples of the arylthiocarbonyl group in the above formulas (D-III) to (D-VI) include arylthiocarbonyl groups having 7 or more and 11 or less carbon atoms (such as a phenylthiocarbonyl group and a naphthoxythiocarbonyl group) and the like.

Examples of the acyloxy group in the above formulas (D-II) to (D-VI) include linear or branched acyloxy groups having 2 or more and 19 or less carbon atoms (such as an acetoxy group, an ethylcarbonyloxy group, a propylcarbonyloxy group, an isopropylcarbonyloxy group, a butylcarbonyloxy group, an isobutylcarbonyloxy group, a sec-butylcarbonyloxy group, a tert-butylcarbonyloxy group, an octylcarbonyloxy group, a tetradecylcarbonyloxy group and an octadecylcarbonyloxy group) and the like.

Examples of the arylthio group in the above formulas (D-III) to (D-VI) include arylthio groups having 6 or more and 20 or less carbon atoms (such as a phenylthio group, a 2-methylphenylthio group, a 3-methylphenylthio group, a 4-methylphenylthio group, a 2-chlorophenylthio group, a 3-chlorophenylthio group, a 4-chlorophenylthio group, a 2-bromophenylthio group, a 3-bromophenylthio group, a 4-bromophenylthio group, a 2-fluorophenylthio group, a 3-fluorophenylthio group, a 4-fluorophenylthio group, a 2-hydroxyphenylthio group, a 4-hydroxyphenylthio group, a 2-methoxyphenylthio group, a 4-methoxyphenylthio group, a 1-naphthylthio group, a 2-naphthylthio group, a 4-[4-(phenylthio)benzoyl]phenylthio group, a 4-[4-(phenylthio)phenoxy]phenylthio group, a 4-[4-(phenylthio)phenyl]phenylthio group, a 4-(phenylthio)phenylthio group, a 4-benzoylphenylthio group, a 4-benzoyl-2-chlorophenylthio group, a 4-benzoyl-3-chlorophenylthio group, a 4-benzoyl-3-methylthiophenylthio group, a 4-benzoyl-2-methylthiophenylthio group, a 4-(4-methylthiobenzoyl)phenylthio group, a 4-(2-methylthiobenzoyl)phenylthio group, a 4-(p-methylbenzoyl)phenylthio group, a 4-(p-ethylbenzoyl)phenylthio group, a 4-(p-isopropylbenzoyl)phenylthio group and a 4-(p-tert-butylbenzoyl)phenylthio group) and the like.

Examples of the alkylthio group in the above formulas (D-II) to (D-VI) include linear or branched alkylthio groups having 1 or more and 18 or less carbon atoms (such as a methylthio group, an ethylthio group, a propylthio group, an isopropylthio group, a butylthio group, an isobutylthio group, sec-butylthio group, a tert-butylthio group, a pentylthio group, an isopentylthio group, a neopentylthio group, a tert-pentylthio group, an octylthio group, a decylthio group, a dodecylthio group and an isooctadecylthio group) and the like.

Examples of the aryl group in the above formulas (D-III) to (D-VI) include aryl groups having 6 or more and 10 or less carbon atoms (such as a phenyl group, a tolyl group, a dimethylphenyl group and a naphthyl group) and the like.

Examples of the heterocyclic aliphatic group in the above formula (D-II) include heterocyclic groups having 2 or more and 20 or less (preferably 4 or more and 20 or less) carbon atoms (such as a pyrrolidinyl group, a tetrahydrofuranyl group, a tetrahydrothienyl group, a piperidinyl group, a tetrahydropyranyl group, a tetrahydrothiopyranyl group and a morpholinyl group) and the like.

Examples of the heterocyclic group in the above formulas (D-III) to (D-VI) include heterocyclic groups having 4 or more and 20 or less carbon atoms (such as a thienyl group, a furanyl group, selenophenyl, a pyranyl group, a pyrrolyl group, an oxazolyl group, a thiazolyl group, a pyridyl group, a pyrimidyl group, a pyrazinyl group, an indolyl group, a benzofuranyl group, a benzothienyl group, a quinolyl group, an isoquinolyl group, a quinoxalinyl group, a quinazolinyl group, a carbazolyl group, an acridinyl group, a phenothiazinyl group, a phenazinyl group, a xanthenyl group, a thianthrenyl group, a phenoxazinyl group, a phenoxathiinyl group, a chromanyl group, an isochromanyl group, a dibenzothienyl group, a xanthonyl group, a thioxanthonyl group and a dibenzofuranyl group) and the like.

Examples of the aryloxy group in the above formulas (D-III) to (D-VI) include aryloxy groups having 6 or more and 10 or less carbon atoms (such as a phenoxy group and a naphthyloxy group) and the like.

Examples of the alkylsulfinyl group in the above formulas (D-II) to (D-VI) include linear or branched sulfinyl groups having 1 or more and 18 or less carbon atoms (such as a methylsulfinyl group, an ethylsulfinyl group, a propylsulfinyl group, an isopropylsulfinyl group, a butylsulfinyl group, an isobutylsulfinyl group, a sec-butylsulfinyl group, a tert-butylsulfinyl group, a pentylsulfiny group, an isopentylsulfinyl group, a neopentylsulfinyl group, a tert-pentylsulfinyl, an octylsulfinyl group and an isooctadecylsulfinyl) and the like.

Examples of the arylsulfinyl group in the above formulas (D-III) to (D-VI) include arylsulfinyl groups having 6 or more and 10 or less carbon atoms (such as a phenylsulfinyl group, a tolylsulfinyl group and a naphthylsulfinyl group) and the like.

Examples of the alkylsulfonyl group in the above formulas (D-II) to (D-VI) include linear or branched alkylsulfonyl groups having 1 or more and 18 or less carbon atoms (such as a methylsulfonyl group, an ethylsulfonyl group, a propylsulfonyl group, an isopropylsulfonyl group, a butylsulfonyl group, an isobutylsulfonyl group, a sec-butylsulfonyl group, a tert-butylsulfonyl group, a pentylsulfonyl group, an isopentylsulfonyl group, a neopentylsulfonyl group, a tert-pentylsulfonyl group, an octylsulfonyl group and an octadecylsulfonyl group) and the like.

Examples of the arylsulfonyl group in the above formulas (D-III) to (D-VI) include arylsulfonyl groups having 6 or more and 10 or less carbon atoms (such as a phenylsulfonyl group, a tolylsulfonyl group (a tosyl group) and a naphthylsulfonyl group) and the like.

Examples of the hydroxy(poly)alkyleneoxy group in the above formulas (D-II) to (D-VI) include a hydroxy(poly)alkyleneoxy group represented by HO(AO)_{q}— (wherein AO independently represents an ethyleneoxy group and/or a propyleneoxy group, and q represents an integer of 1 or more and 5 or less) and the like.

Examples of the optionally substituted amino group in the above formulas (D-II) to (D-VI) include an amino group (—NH₂), substituted amino groups having 1 or more and 15 or less carbon atoms (such as a methylamino group, a dimethylamino group, an ethylamino group, a methylethylamino group, a diethylamino group, an n-propylamino group, a methyl-n-propylamino group, an ethyl-n-propylamino group, an n-propylamino group, an isopropylamino group, an isopropylmethylamino group, an isopropylethylamino group, a diisopropylamino group, a phenylamino group, a diphenylamino group, a methylphenylamino group, an ethylphenylamino group, an n-propylphenylamino group and an isopropylphenylamino group) and the like.

Examples of the alkylene group in the above formulas (D-III) and (D-IV) include linear or branched alkylene groups having 1 or more and 18 or less carbon atoms (such as a methylene group, a 1,2-ethylene group, a 1,1-ethylene group, a propane-1,3-diyl group, a propane-1,2-diyl group, a propane-1,1-diyl group, a propane-2,2-diyl group, a butane-1,4-diyl group, a butane-1,3-diyl group, a butane-1,2-diyl group, a butane-1,1-diyl group, a butane-2,2-diyl group, a butane-2,3-diyl group, a pentane-1,5-diyl group, a pentane-1,4-diyl group, a hexane-1,6-diyl group, a heptane-1,7-diyl group, an octane-1,8-diyl group, a 2-ethylhexane-1,6-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group and a hexadecane-1,16-diyl group) and the like.

The sulfonium salt (Q) can be synthesized, for example, according to the following scheme. Specifically, 1-fluoro-2-methyl-4-nitrobenzene represented by the following formula (D-1) is allowed to react with a compound represented by the following formula (D-2) in the presence of a base such as potassium hydroxide to obtain a nitro compound represented by the following formula (D-3), which is then reduced in the presence of reduced iron to obtain an amine compound represented by the following formula (D-4). This amine compound and a nitrite (for example, sodium nitrite) represented by MaNO₂ (wherein Ma represents a metal atom, for example an alkali metal atom such as sodium atom) are allowed to react to obtain a diazo compound, which is then mixed with a cuprous halide represented by CuX′ (wherein X′ represents a halogen atom such as a bromine atom; the same applies hereinafter) and a hydrogen halide represented by HX′, and reaction is allowed to proceed to obtain a halide represented by the following formula (D-5). Grignard reagent is prepared from this halide and magnesium, and a sulfonium salt represented by the following formula (D-7) can be then obtained by the reaction of this Grignard reagent and a sulfoxide compound represented by the following formula (D-6) in the presence of chlorotrimethylsilane. Furthermore, this sulfonium salt is allowed to react with a salt represented by Mb⁺X″⁻ (wherein Mb⁺ represents a metal cation, for example an alkali metal cation such as a potassium ion and X″⁻ represents a monovalent anion represented by X⁻ (excluding halogen anions)) to carry out salt conversion, and a sulfonium salt represented by the following formula (D-8) can be obtained thereby. In the following formulas (D-2) to (D-8), R^{D1} to R^{D3} and A^{D1} are the same as those of the above formula (D-I).

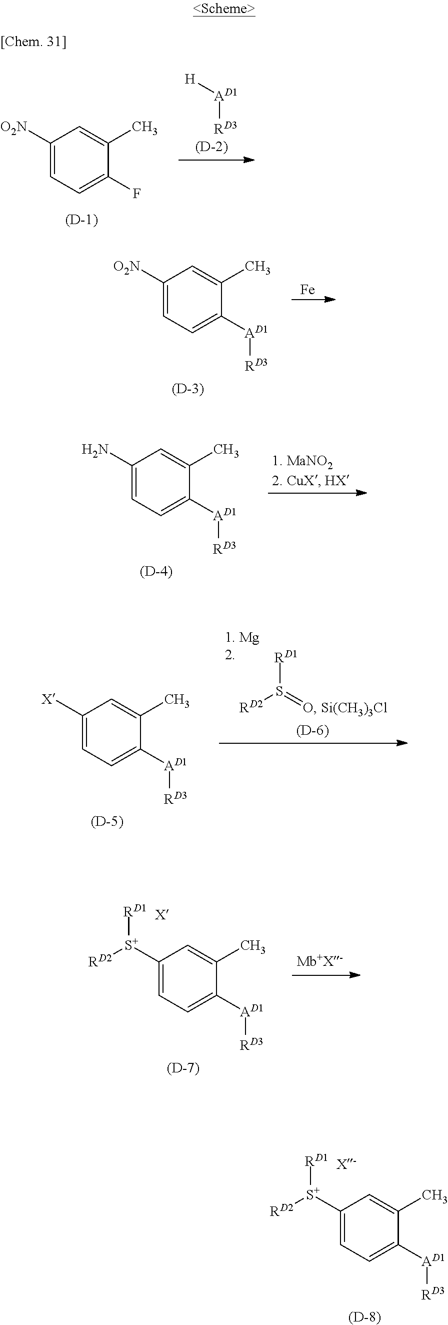

Specific examples of the cation portion of the sulfonium salt (Q) represented by the above formula (D-I) are given below. Specific examples of the anion portion of the sulfonium salt (Q) represented by the above formula (D-I) can include conventionally known anions such as anions mentioned in the above description of X⁻. The sulfonium salt (Q) represented by the above formula (D-I) can be synthesized according to the above scheme. The cation portion can be combined with a desired anion portion by further salt conversion as needed. In particular, a combination with an anion represented by R^{x1}_{c}BY_{4-c}⁻ is preferred. In the formula, R^{x1} represents a phenyl group in which at least part of the hydrogen atoms are substituted with a halogen atom or an electron-withdrawing group. Y represents a halogen atom.

c represents an integer of 1 or more and 4 or less.

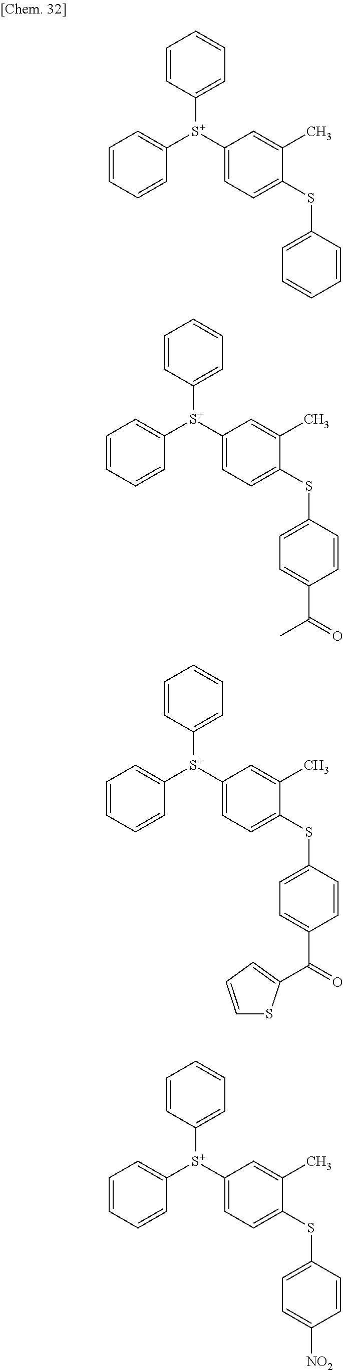 [SMILES: Cc1cc([S+](c2ccccc2)c2ccccc2)ccc1Sc1ccccc1 ; CC(=O)c1ccc(Sc2ccc([S+](c3ccccc3)c3ccccc3)cc2C)cc1 ; Cc1cc([S+](c2ccccc2)c2ccccc2)ccc1Sc1ccc(C(=O)c2cccs2)cc1 ; Cc1cc([S+](c2ccccc2)c2ccccc2)ccc1Sc1ccc([N+](=O)[O-])cc1]

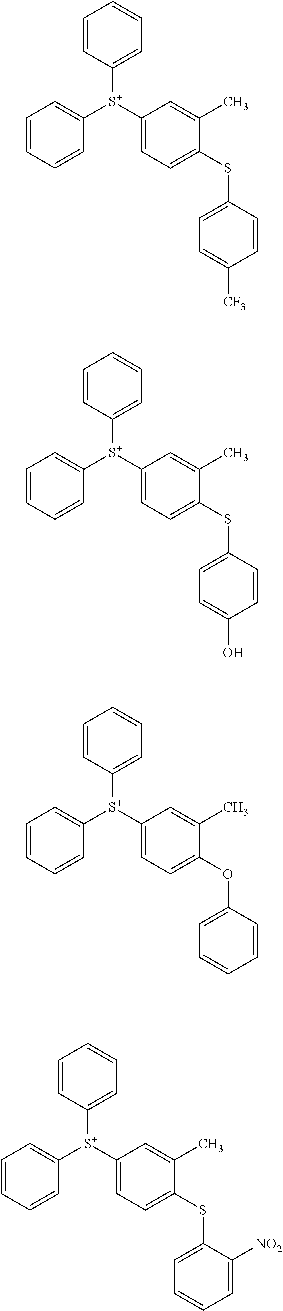 [SMILES: Cc1cc([S+](c2ccccc2)c2ccccc2)ccc1Sc1ccc(C(F)(F)F)cc1 ; Cc1cc([S+](c2ccccc2)c2ccccc2)ccc1Sc1ccc(O)cc1 ; Cc1cc([S+](c2ccccc2)c2ccccc2)ccc1Oc1ccccc1 ; Cc1cc([S+](c2ccccc2)c2ccccc2)ccc1Sc1ccccc1[N+](=O)[O-]]

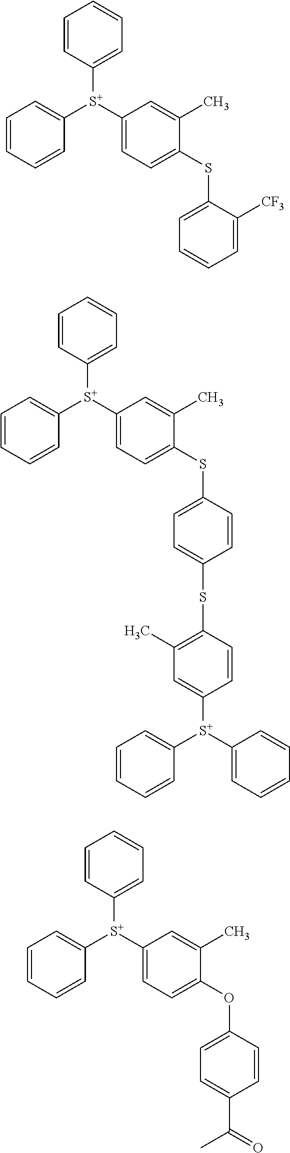 [SMILES: Cc1cc([S+](c2ccccc2)c2ccccc2)ccc1Sc1ccccc1C(F)(F)F ; Cc1cc([S+](c2ccccc2)c2ccccc2)ccc1Sc1ccc(Sc2ccc([S+](c3ccccc3)c3ccccc3)cc2C)cc1 ; CC(=O)c1ccc(Oc2ccc([S+](c3ccccc3)c3ccccc3)cc2C)cc1]

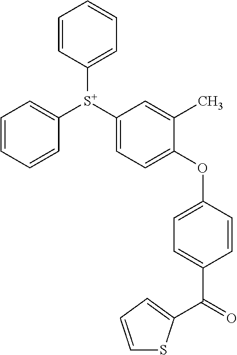 [SMILES: Cc1cc([S+](c2ccccc2)c2ccccc2)ccc1Oc1ccc(C(=O)c2cccs2)cc1]

Among the aforementioned group of preferred cation portions, the cation portion represented by the following formula is more preferable.

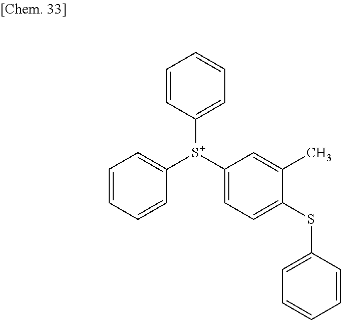 [SMILES: Cc1cc([S+](c2ccccc2)c2ccccc2)ccc1Sc1ccccc1]

When the onium salt (D2) includes the above sulfonium salt (Q), the onium salt (D2) may include other onium salts other than the sulfonium salt (Q) along with the above sulfonium salt (Q). In this case, the content of the sulfonium salt (Q) in the onium salt (D2) is not particularly limited, and typically 70% by mass or more is preferred, 80% by mass or more is more preferred, 90% by mass or more is particularly preferred, and 100% by mass is most preferred. When the composition includes an onium salt containing a gallate anion and/or a borate anion as the onium salt (D2), a cation portion of the onium salt is not limited to the cation portion of the sulfonium salt represented by formula (D-I) described above, but can also be an onium salt containing the cation portion described in the other acid generators described later. When the composition includes the onium salt containing gallate anion and/or borate anion as the onium salt (D2), various properties of the composition such as curability are excellent.

### (Other Onium Salt)

Various onium salts conventionally used to cure epoxy compounds can be used as other onium salt than the sulfonium salt (Q) without any particular limitation. Other onium salt is preferably onium salt such as iodonium salt and sulfonium salt, and more preferably other onium salt than the sulfonium salt (Q).

Hereinafter, a sulfonium salt other than the sulfonium salt (Q) is referred to as “sulfonium salt (Q′)”. Other sulfonium salt (Q′), same as the sulfonium salt (Q), preferably includes the anion represented by R^{x1}_{c}BY_{4-c}⁻ described above or the anion represented by R^{x1}_{c}GaY_{4-c}⁻ described above as the monovalent anion X.

The sulfonium salt (Q′) having a monovalent anion represented by R^{x1}_{c}BY_{4-c}⁻ sulfonium salt is exemplified by a sulfonium salt represented by following formula (D-A). The sulfonium salt (Q′) having a monovalent anion represented by R^{x1}_{c}GaY_{4-c}⁻ is a sulfonium salt in which B in the following formula (D-A) is replaced by Ga.

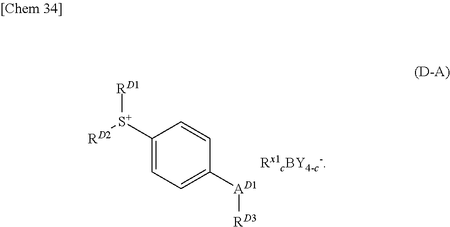

In the formula, R^{D1}, R^{D2}, R^{D3}, A^{D1}, R^{x1}, Y and c are same as defined above.

Specific examples of a cation portion of the sulfonium salt (Q′) represented by above formula (D-A) include following cations.

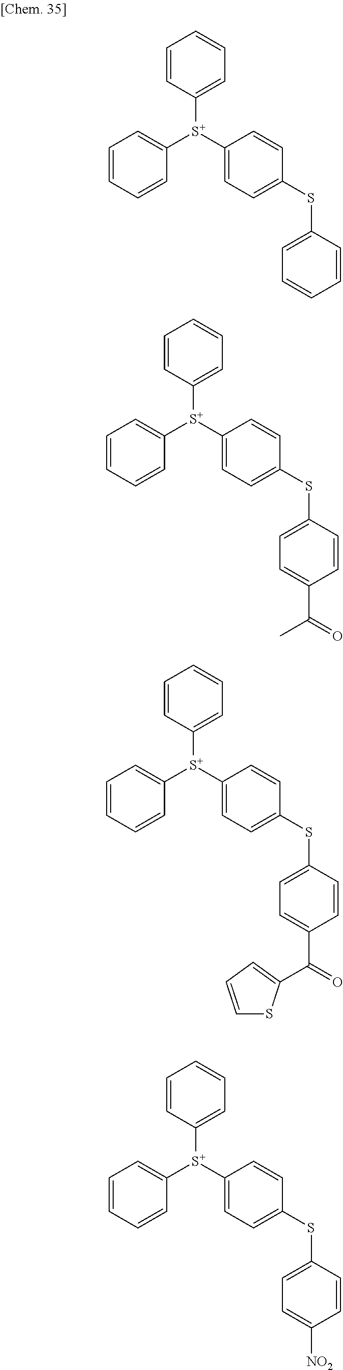 [SMILES: c1ccc(Sc2ccc([S+](c3ccccc3)c3ccccc3)cc2)cc1 ; CC(=O)c1ccc(Sc2ccc([S+](c3ccccc3)c3ccccc3)cc2)cc1 ; O=C(c1ccc(Sc2ccc([S+](c3ccccc3)c3ccccc3)cc2)cc1)c1cccs1 ; O=[N+]([O-])c1ccc(Sc2ccc([S+](c3ccccc3)c3ccccc3)cc2)cc1]

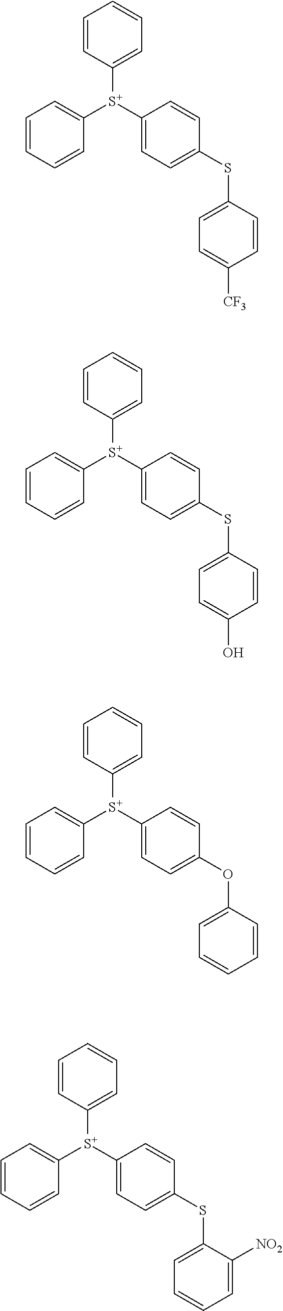 [SMILES: FC(F)(F)c1ccc(Sc2ccc([S+](c3ccccc3)c3ccccc3)cc2)cc1 ; Oc1ccc(Sc2ccc([S+](c3ccccc3)c3ccccc3)cc2)cc1 ; c1ccc(Oc2ccc([S+](c3ccccc3)c3ccccc3)cc2)cc1 ; O=[N+]([O-])c1ccccc1Sc1ccc([S+](c2ccccc2)c2ccccc2)cc1]

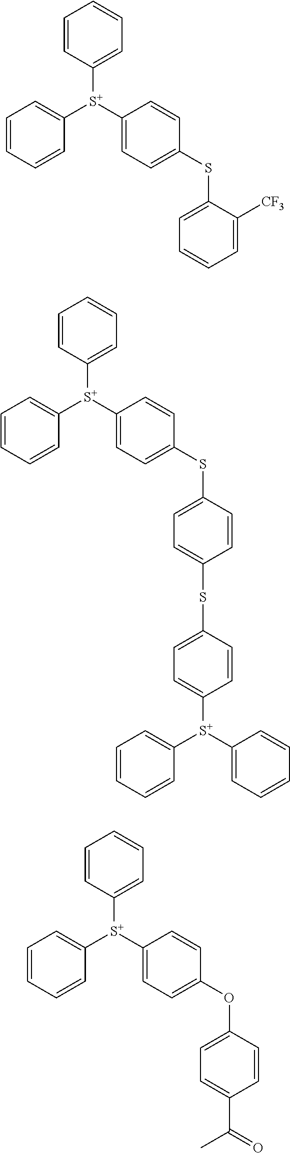 [SMILES: FC(F)(F)c1ccccc1Sc1ccc([S+](c2ccccc2)c2ccccc2)cc1 ; c1ccc([S+](c2ccccc2)c2ccc(Sc3ccc(Sc4ccc([S+](c5ccccc5)c5ccccc5)cc4)cc3)cc2)cc1 ; CC(=O)c1ccc(Oc2ccc([S+](c3ccccc3)c3ccccc3)cc2)cc1]

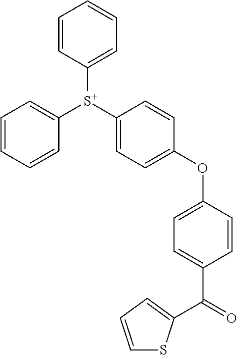 [SMILES: O=C(c1ccc(Oc2ccc([S+](c3ccccc3)c3ccccc3)cc2)cc1)c1cccs1]

Typical examples of the cation portion of the sulfonium salt (Q′) also include following cations.

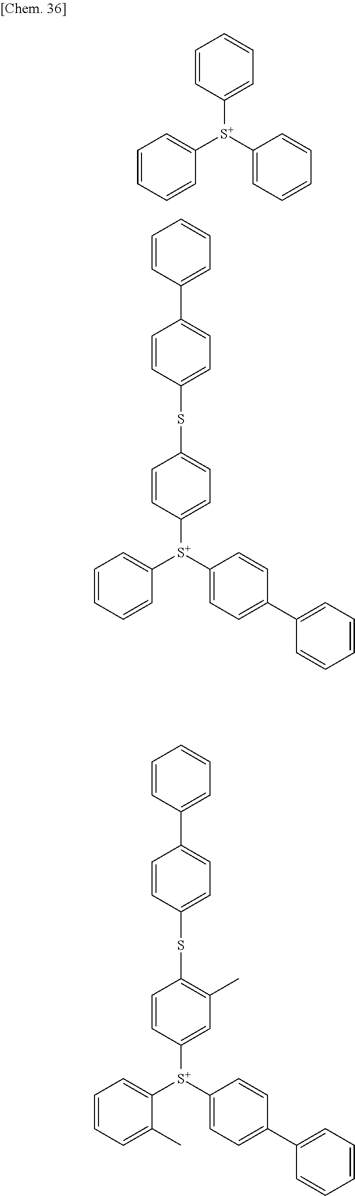 [SMILES: c1ccc([S+](c2ccccc2)c2ccccc2)cc1 ; c1ccc(-c2ccc(Sc3ccc([S+](c4ccccc4)c4ccc(-c5ccccc5)cc4)cc3)cc2)cc1 ; Cc1cc([S+](c2ccc(-c3ccccc3)cc2)c2ccccc2C)ccc1Sc1ccc(-c2ccccc2)cc1]

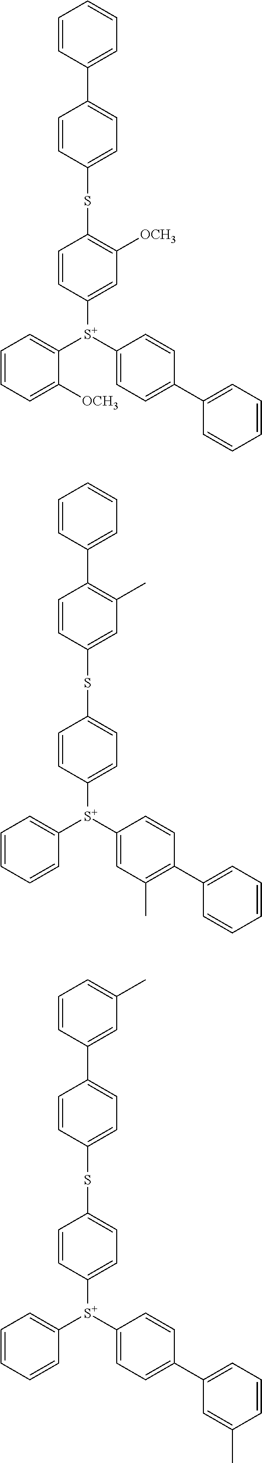 [SMILES: COc1cc([S+](c2ccc(-c3ccccc3)cc2)c2ccccc2OC)ccc1Sc1ccc(-c2ccccc2)cc1 ; Cc1cc(Sc2ccc([S+](c3ccccc3)c3ccc(-c4ccccc4)c(C)c3)cc2)ccc1-c1ccccc1 ; Cc1cccc(-c2ccc(Sc3ccc([S+](c4ccccc4)c4ccc(-c5cccc(C)c5)cc4)cc3)cc2)c1]

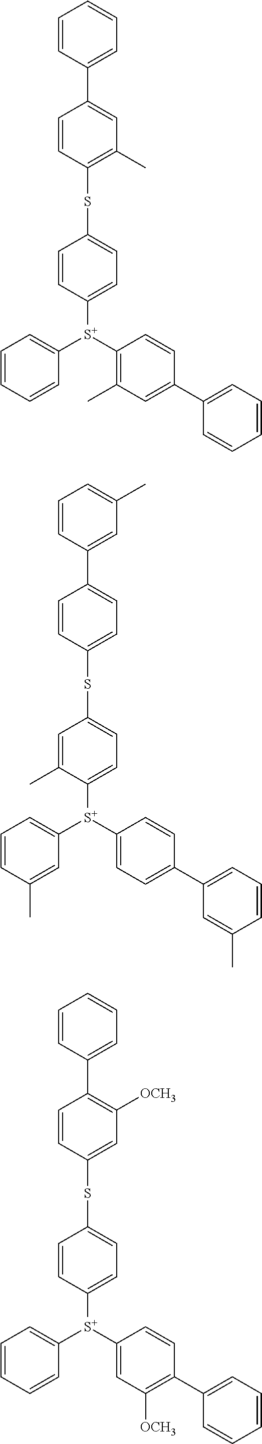 [SMILES: Cc1cc(-c2ccccc2)ccc1Sc1ccc([S+](c2ccccc2)c2ccc(-c3ccccc3)cc2C)cc1 ; Cc1cccc(-c2ccc(Sc3ccc([S+](c4ccc(-c5cccc(C)c5)cc4)c4cccc(C)c4)c(C)c3)cc2)c1 ; COc1cc(Sc2ccc([S+](c3ccccc3)c3ccc(-c4ccccc4)c(OC)c3)cc2)ccc1-c1ccccc1]

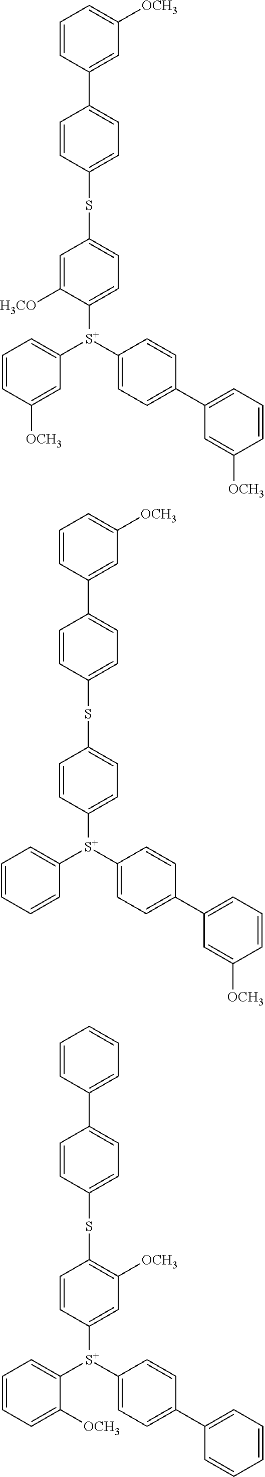 [SMILES: COc1cccc(-c2ccc(Sc3ccc([S+](c4ccc(-c5cccc(OC)c5)cc4)c4cccc(OC)c4)c(OC)c3)cc2)c1 ; COc1cccc(-c2ccc(Sc3ccc([S+](c4ccccc4)c4ccc(-c5cccc(OC)c5)cc4)cc3)cc2)c1 ; COc1cc([S+](c2ccc(-c3ccccc3)cc2)c2ccccc2OC)ccc1Sc1ccc(-c2ccccc2)cc1]

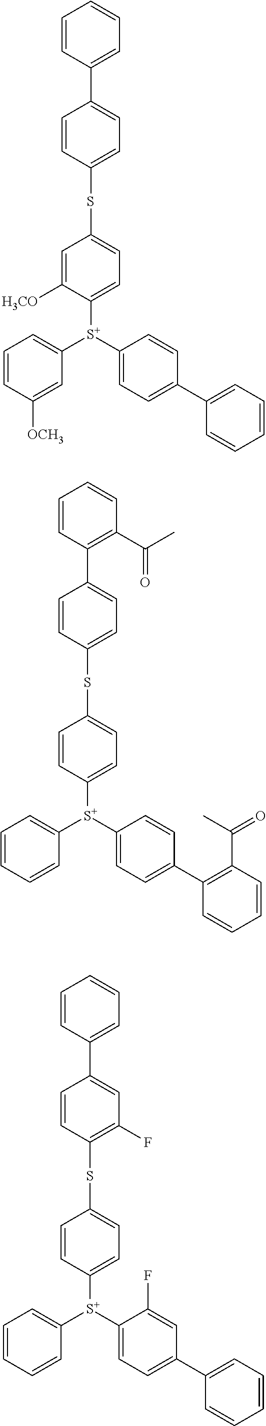 [SMILES: COc1cccc([S+](c2ccc(-c3ccccc3)cc2)c2ccc(Sc3ccc(-c4ccccc4)cc3)cc2OC)c1 ; CC(=O)c1ccccc1-c1ccc(Sc2ccc([S+](c3ccccc3)c3ccc(-c4ccccc4C(C)=O)cc3)cc2)cc1 ; Fc1cc(-c2ccccc2)ccc1Sc1ccc([S+](c2ccccc2)c2ccc(-c3ccccc3)cc2F)cc1]

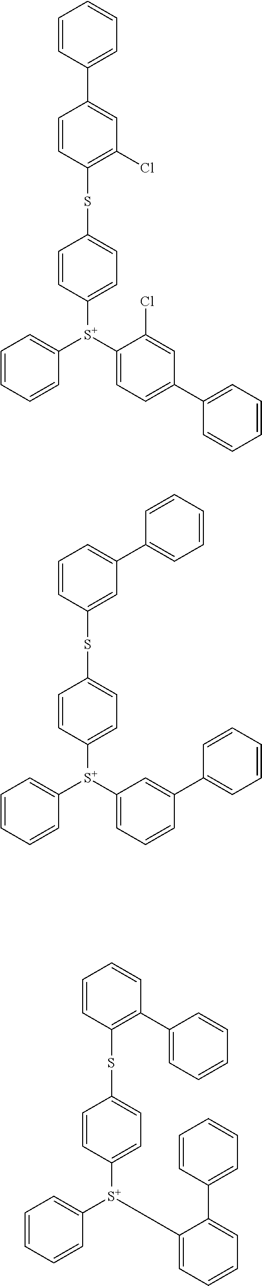 [SMILES: Clc1cc(-c2ccccc2)ccc1Sc1ccc([S+](c2ccccc2)c2ccc(-c3ccccc3)cc2Cl)cc1 ; c1ccc(-c2cccc(Sc3ccc([S+](c4ccccc4)c4cccc(-c5ccccc5)c4)cc3)c2)cc1 ; c1ccc(-c2ccccc2Sc2ccc([S+](c3ccccc3)c3ccccc3-c3ccccc3)cc2)cc1]

The content of the onium salt (D2) in the composition is not particularly limited as long as the curing of the composition favorably proceeds. The content of the onium salt (D2) in the composition relative to 100 parts by mass of the material to be cured by the onium salt (D2) such as the epoxy-group-containing resin, the epoxy compound, or the oxetane compound is typically 0.01 parts by mass or more and 50 parts by mass or less, preferably 0.01 parts by mass or more and 30 parts by mass or less, more preferably 0.01 parts by mass or more and 20 parts by mass or less, even more preferably 0.05 parts by mass or more and 15 parts by mass or less, and particularly preferably 1 part by mass or more and 10 parts by mass or less from the viewpoint of ease of favorably curing the composition.

### [Curing Agent for Epoxy-Group-Containing Resin, Epoxy Compound or Oxetane Compound (D3)]

A curing agent for an epoxy-group-containing resin, an epoxy compound or an oxetane compound (D3) (hereinafter, also referred to as “curing agent (D3)”) can be appropriately selected from curing agents which are conventionally known and other than the onium salt (D2) described above. The curing agent (D3) can be used together with the epoxy-group-containing resin, the epoxy compound or the oxetane compound, and contributes to curing by heating.

Examples of the curing agent (D3) include a phenol-based curing agent, an acid anhydride-based curing agent, a polyamine-based curing agent, and catalytic curing agent. The amount of the phenol-based curing agent and the acid anhydride-based curing agent used relative to 100 parts by mass of the amount of the base component (C), in particular total of the amount of the epoxy compound and the amount of the oxetanyl compound, in the composition is preferably 1 part by mass or more and 200 parts by mass or less, more preferably 50 parts by mass or more and 150 parts by mass or less, and particularly preferably 80 parts by mass or more and 120 parts by mass or less. The epoxy compound and the oxetanyl compound include a resin containing epoxy and/or oxetanyl groups. The phenol-based curing agent, and the acid anhydride-based curing agent can be each used individually or two or more thereof can be used in combination. The amount of the polyamine-based curing agent used relative to 100 parts by mass of the amount of the base component (C), in particular total of the amount of the epoxy compound and the amount of the oxetanyl compound, in the composition is preferably 0.1 parts by mass or more and 50 parts by mass or less, more preferably 0.5 parts by mass or more and 30 parts by mass or less, and particularly preferably 1 part by mass 15 parts by mass. The epoxy compound and the oxetanyl compound include a resin containing epoxy and/or oxetanyl groups. These polyamine-based curing agents can be used individually or two or more polyamine-based curing agents can be used in combination. The amount of the catalytic curing agent used relative to 100 parts by mass of the amount of the base component (C), in particular total of the amount of the epoxy compound and the amount of the oxetanyl compound, in the liquid composition is preferably 1 part by mass or more and 100 parts by mass or less, more preferably 1 part by mass or more and 80 parts by mass or less, and particularly preferably 1 part by mass or more and 50 parts by mass or less. The epoxy compound and the oxetanyl compound include a resin containing epoxy and/or oxetanyl groups. These catalytic curing agents can be used individually or two or more catalytic curing agents can be used in combination.

### [Curing Agent for Silicon-Containing Resin (D4)]

The composition including the silicon-containing resin as the base component (C) may comprise a curing agent for a silicon-containing resin (D4) (hereinafter, referred to as “curing agent (D4)”). When the composition including the silicon-containing resin comprises the curing agent (D4), it is likely to form a quantum dot-containing film that is not readily subjected to dissolution, swelling, or deformation by the action of an organic solvent such as N-methyl-2-pyrrolidone and thus has an excellent organic solvent resistance.

Examples of a suitable curing agent (D4) include Brønsted acids such as hydrochloric acid, sulfuric acid, nitric acid, benzenesulfonic acid, and p-toluenesulfonic acid; imidazoles such as 2-methylimidazole and 2-ethyl-4-methylimidazole; organic amines such as 2,4,6-tris(dimethylaminomethyl)phenol, benzylmethylamine, DBU (1,8-diazabicyclo[5.4.0]-7-undecene), and DCMU (3-(3,4-dichlorophenyl)-1,1-dimethylurea);

phosphorus compounds represented by PX₃ (in the formula, X represents a halogen atom, a hydroxyl group, or an alkoxy group having 1 or more and 6 or less carbon atoms) such as phosphorus trichloride, phosphorus tribromide, phosphorous acid, trimethyl phosphite, triethyl phosphite and tripropyl phosphite;
phosphorus compounds represented by POX₃ (in the formula, X represents a halogen atom, a hydroxyl group, or an alkoxy group having 1 or more and 6 or less carbon atoms) such as oxyphosphorus trichloride, oxyphosphorus tribromide, phosphoric acid, trimethyl phosphate, triethyl phosphate and tripropyl phosphate;
phosphorus pentoxide;
phosphorus compounds represented by H(HPO₃)ₓOH (in the formula, x is an integer of 1 or more) such as polyphosphoric acid and polyphosphoric acid esters;
phosphorus compounds represented by R^{D0}PX₂ (in the formula, R^{D0} represents a hydrogen atom or an organic group having 1 or more and 30 or less carbon atoms, in which a hydrogen atom in the organic group is optionally substituted with a halogen atom; X represents a halogen atom, a hydroxyl group, or an alkoxy group having 1 or more and 6 or less carbon atoms) such as methyldichlorophosphine, ethyldichlorophosphine and methoxydichlorophosphine;
phosphorus compounds represented by represented by R^{D0}POX₂ (in the formula, R^{D0} represents a hydrogen atom or an organic group having 1 or more and 30 or less carbon atoms, in which a hydrogen atom in the organic group is optionally substituted with a halogen atom; X represents a halogen atom, a hydroxyl group, or an alkoxy group having 1 or more and 6 or less carbon atoms such as dimethyl phosphite, diethyl phosphite, methylphosphonic acid, dimethyl methylphosphonate, methylphosphonic dichloride, phenylphosphonic acid, phenylphosphonic dichloride and diethyl benzylphosphonate; organophosphorus compounds such as tributylphosphine, triphenylphosphine, tris(p-tolyl)phosphine, tris(m-tolyl)phosphine, tris(o-tolyl)phosphine, diphenylcyclohexylphosphine, tricyclohexylphosphine, tris(dimethoxyphenyl)phosphine, ethyltriphenylphosphonium bromide, benzyltriphenylphosphonium chloride, and 1,4-bis(diphenylphosphino)butane;
boron compounds represented by BX₃ (in the formula, X represents a halogen atom, a hydroxyl group, or an alkoxy group having 1 or more and 6 or less carbon atoms) such as boron trifluoride, boron trichloride, boric acid, trimethyl borate, triethyl borate, tripropyl borate, tributyl borate, triamyl borate, trihexyl borate, tricyclopentyl borate, tricyclohexyl borate, triallyl borate, triphenyl borate and ethyl dimethyl borate;
boron oxide (B₂O₃);
boron compounds represented by R^{D0}BX₂ (in the formula, R^{D0} represents a hydrogen atom or an organic group having 1 or more and 30 or less carbon atoms, in which a hydrogen atom in the organic group is optionally substituted with a halogen atom; X represents a halogen atom, a hydroxyl group, or an alkoxy group having 1 or more and 6 or less carbon atoms) such as phenylboronic acid, diisopropoxy(methyl)borane, methylboronic acid and cyclohexylboronic acid;
organophosphorus compound complexes such as triphenylphosphine triphenylborane, tetraphenylphosphonium tetra-p-tolylborate, tetraphenylphosphonium tetraphenylborate, tetraphenylphosphonium thiocyanate, tetraphenylphosphonium dicyanamide, and n-butyltriphenylphosphonium dicyanamide; complexes of a Lewis acid such as boron trifluoride and an organic amine (the organic amine is piperidine, for example); and
amidines such as azabicycloundecene, diazabicycloundecene toluenesulfonic acid salt, and diazabicycloundecene octylic acid salt.

When the polysilane is used as the base component (C), it is preferable to use, in addition to the curing agent (D4) or alone, a curing agent that generates a base by the action of light or heat.

(Curing Agent that Generates Base Component by Action of Heat)

The curing agent that generates a base component by the action of heat is not particularly limited as far as it is a compound conventionally used as a heat-responsive base generator. As the curing agent that generates a base component by the action of heat, 2-benzyl-2-dimethylamino-1-(4-morpholinophenyl)-butan-1-one may be used, for example. 2-Benzyl-2-dimethylamino-1-(4-morpholinophenyl)-butan-1-one also generates a base by the action of light.

A compound that generates an imidazole compound by the action of heat (hereinafter, this compound is also referred to as a heat-responsive imidazole generator) is also preferably used as the curing agent. Examples of such heat-responsive imidazole generator include heat-responsive imidazole generators described in Japanese Unexamined Patent Application Publication No. 2016-145308 and imidazole compounds described in Japanese Unexamined Patent Application Publication No. 2017-025226.

### (Oxime Ester Compound)

An oxime ester compound degrades by the action of light and generates a base. Examples of a suitable oxime ester compound include a compound represented by the following formula (d01).

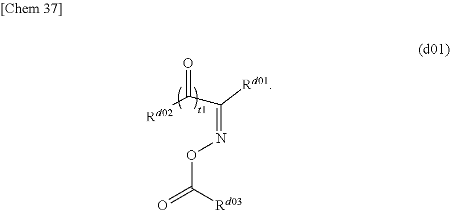

In the formula (d01), R^{d01} represents an alkyl group having 1 or more and 10 or less carbon atoms, an optionally substituted phenyl group, or an optionally substituted carbazolyl group.

t1 is 0 or 1. R^{d02} represents an optionally substituted alkyl group having 1 or more and 10 or less carbon atoms, an optionally substituted phenyl group, or an optionally substituted carbazolyl group. R^{d03} represents a hydrogen atom, an alkyl group having 1 or more and 6 or less carbon atoms, or an optionally substituted phenyl group.

When R^{d01} is an alkyl group having 1 or more and 10 or less carbon atoms, the alkyl group may be linear or branched. In this case, the number of carbon atoms in the alkyl group is preferably 1 or more and 8 or less, and more preferably 1 or more and 5 or less.

When R^{d01} is an optionally substituted phenyl group, the type of the substituent is not particularly limited as long as the objects of the present invention are not inhibited. Examples of a suitable substituent that the phenyl group may have include an alkyl group, an alkoxy group, an cycloalkyl group, an cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an amino group, an amino group substituted with one or two organic groups, a morpholin-1-yl group, a piperazin-1-yl group, a halogen, a nitro group, a cyano group, and the like. When R^{d01} is an optionally substituted phenyl group and the phenyl group has a plurality of substituents, the plurality of substituents may be the same as or different from each other.

When a substituent of the phenyl group is an alkyl group, the number of carbon atoms of the alkyl group is preferably 1 or more and 20 or less, more preferably 1 or more and 10 or less, further preferably 1 or more and 6 or less, particularly preferably 1 or more and 3 or less, and most preferably 1. The alkyl group may be linear or branched. When a substituent of the phenyl group is an alkyl group, specific examples thereof include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. The alkyl group may have an ether bond (—O—) in the carbon chain. In this case, examples of a substituent of the phenyl group include an alkoxyalkyl group and an alkoxyalkoxyalkyl group. When a substituent of the phenyl group is an alkoxyalkyl group, a group represented by —R^{d04}—O—R^{d05} is preferable. R^{d04} represents a linear or branched alkylene group having 1 or more and 10 or less carbon atoms. R^{d05} represents a linear or branched alkyl group having 1 or more and 10 or less carbon atoms. The number of carbon atoms of R^{d04} is preferably 1 or more and 8 or less, more preferably 1 or more and 5 or less, and particularly preferably 1 or more and 3 or less. The number of carbon atoms of R^{d05} is preferably 1 or more and 8 or less, more preferably 1 or more and 5 or less, particularly preferably 1 or more and 3 or less, and most preferably 1. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, a methoxypropyl group, and the like.

When a substituent of the phenyl group is an alkoxy group, the number of carbon atoms of the alkoxy group is preferably 1 or more and 20 or less, and more preferably 1 or more and 6 or less. The alkoxy group may be linear or branched. When a substituent of the phenyl group is an alkoxy group, specific examples thereof include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, an isodecyloxy group, and the like. The alkoxy group may include an ether bond (—O—) in the carbon chain. Examples of the alkoxy group having an ether bond in the carbon chain include a methoxyethoxy group, an ethoxyethoxy group, a 2-methoxy-1-methylethoxy group, a methoxyethoxyethoxy group, an ethoxyethoxyethoxy group, a propyloxyethoxyethoxy group, a methoxypropyloxy group, and the like.

When a substituent of the phenyl group is a cycloalkyl group or a cycloalkoxy group, the number of carbon atoms of the cycloalkyl group or the cycloalkoxy group is preferably 3 or more and 10 or less, and more preferably 3 or more and 6 or less. When a substituent of the phenyl group is a cycloalkyl group, specific examples thereof include a cyclopropyl group, a cyclobutyl group, a cyclopentyl group, a cyclohexyl group, a cycloheptyl group, a cyclooctyl group, and the like. When a substituent of the phenyl group is a cycloalkoxy group, specific examples include a cyclopropyloxy group, a cyclobutyloxy group, a cyclopentyloxy group, a cyclohexyloxy group, a cycloheptyloxy group, a cyclooctyloxy group, and the like.

When a substituent of the phenyl group is a saturated aliphatic acyl group or a saturated aliphatic acyloxy group, the number of carbon atoms of the saturated aliphatic acyl group or the saturated aliphatic acyloxy group is preferably 2 or more and 20 or less, and more preferably 2 or more and 7 or less. When a substituent of the phenyl group is a saturated aliphatic acyl group, specific examples thereof include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, an n-hexadecanoyl group, and the like. When a substituent of the phenyl group is a saturated aliphatic acyloxy group, specific examples thereof include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, an n-hexadecanoyloxy group, and the like.

When a substituent of the phenyl group is an alkoxycarbonyl group, the number of carbon atoms of the alkoxycarbonyl group is preferably 2 or more and 20 or less, and more preferably 2 or more and 7 or less. When a substituent of the phenyl group is an alkoxycarbonyl group, specific examples thereof include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, an isodecyloxycarbonyl group, and the like.

When a substituent of the phenyl group is a phenylalkyl group, the number of carbon atoms of the phenylalkyl group is preferably 7 or more and 20 or less, more preferably 7 or more and 10 or less. When a substituent of the phenyl group is a naphthylalkyl group, the number of carbon atoms of the naphthylalkyl group is preferably 11 or more and 20 or less, more preferably 11 or more and 14 or less. When a substituent of the phenyl group is a phenylalkyl group, specific examples thereof include a benzyl group, a 2-phenylethyl group, a 3-phenylpropyl group, and a 4-phenylbutyl group. When a substituent of the phenyl group is a naphthylalkyl group, specific examples include an α-naphthylmethyl group, a β-naphthylmethyl group, a 2-(α-naphthyl)ethyl group, and a 2-β-naphthyl)ethyl group. When a substituent of the phenyl group is a phenylalkyl group or a naphthylalkyl group, the substituent may further have a substituent on the phenyl group or the naphthyl group.

When a substituent of the phenyl group is a heterocyclyl group, the heterocyclyl group is a 5- or 6-membered monocycle including one or more N, S, and O, or a heterocyclyl group in which these monocycles are condensed with each other, or the monocycle and a benzene ring are condensed. When the heterocyclyl group is a condensed ring, the number of rings constituting the condensed ring is 3 or less. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, and the like. When a substituent of the phenyl group is a heterocyclyl group, the heterocyclyl group may further have a substituent.

When a substituent of the phenyl group is an amino group substituted with one or two organic groups, suitable examples of the organic group include an alkyl group having 1 or more and 20 or less carbon atoms, a cycloalkyl group having 3 or more and 10 or less carbon atoms, a saturated aliphatic acyl group having 2 or more and 20 or less carbon atoms, a saturated aliphatic acyloxy group having 2 or more and 20 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more and 20 or less carbon atoms, a heterocyclyl group, and the like. Specific examples of suitable organic groups are the same as the groups described above as the substituent of the phenyl group. Specific examples of the amino group substituted with one or two organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoylamino group, an n-hexanoylamino group, an n-heptanoylamino group, an n-octanoylamino group, an n-decanoylamino group, a benzoylamino group, an α-naphthoylamino group, a β-naphthoylamino group, an N-acetyl-N-acetyloxyamino group, and the like.

When a phenyl group, a naphthyl group, and a heterocyclyl group included in a substituent of the phenyl group further have a substituent, examples of the further substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group which has an alkyl group having 1 or more and 6 or less carbon atoms, a dialkylamino group which has an alkyl group having 1 or more and 6 or less carbon atoms, a morpholin-1-yl group, a piperazin-1-yl group, halogen, a nitro group, a cyano group, and the like. When a phenyl group, a naphthyl group, and a heterocyclyl group included in a substituent of the phenyl group further have a substituent, the number of further substituents is not particularly limited as long as the object of the present invention is not inhibited, and is preferably 1 or more and 4 or less. When a phenyl group, a naphthyl group, and a heterocyclyl group included in a substituent of the phenyl group have a plurality of substituents, the plurality of substituents may be the same as or different from each other.

Substituents for the case in which R^{d01} is an optionally substituted phenyl group are described above. Among those substituents, an alkyl group or an alkoxyalkyl group is preferable.

When R^{d01} is an optionally substituted phenyl group, neither the number of substituents nor the position to which a substituent is bonded is particularly limited as long as the objects of the present invention are not inhibited. When R^{d01} is an optionally substituted phenyl group, the optionally substituted phenyl group is preferably an optionally substituted o-tolyl group for excellent efficiency of base generation.

When R^{d01} is an optionally substituted carbazolyl group, the type of the substituent is not particularly limited as long as the objects of the present invention are not inhibited. Examples of a suitable substituent that the carbazolyl group may have on a carbon atom include an alkyl group having 1 or more and 20 or less carbon atoms, an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, an optionally substituted phenyl group, an optionally substituted phenoxy group, an optionally substituted phenylthio group, an optionally substituted phenylcarbonyl group, an optionally substituted benzoyl group, an optionally substituted phenoxycarbonyl group, an optionally substituted benzoyloxy group, an optionally substituted phenylalkyl group having 7 or more and 20 or less carbon atoms, an optionally substituted naphthyl group, an optionally substituted naphthoxy group, an optionally substituted naphthylcarbonyl group, an optionally substituted naphthoyl group, an optionally substituted naphthoxycarbonyl group, an optionally substituted naphthoyloxy group, an optionally substituted naphthylalkyl group having 11 or more and 20 or less carbon atoms, an optionally substituted heterocyclyl group, an optionally substituted heterocyclylcarbonyl group, an amino group, an amino group substituted with one or two organic groups, a morpholin-1-yl group, a piperazin-1-yl group, a halogen, a nitro group, and a cyano group.

When R^{d01} is an optionally substituted carbazolyl group, examples of a suitable substituent that the carbazolyl group may have on the nitrogen atom include an alkyl group having 1 or more and 20 or less carbon atoms, a cycloalkyl group having 3 or more and 10 or less carbon atoms, a saturated aliphatic acyl group having 2 or more and 20 or less carbon atoms, an alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthyl group, an optionally substituted naphthoyl group, an optionally substituted naphthoxycarbonyl group, an optionally substituted naphthylalkyl group having 11 or more and 20 or less carbon atoms, an optionally substituted heterocyclyl group, and an optionally substituted heterocyclylcarbonyl group. Among these substituents, an alkyl group having 1 or more and 20 or less carbon atoms is preferable, an alkyl group having 1 or more and 6 or less carbon atoms is more preferable, and an ethyl group is particularly preferable.

For an alkyl group, an alkoxy group, a cycloalkyl group, a cycloalkoxy group, a saturated aliphatic acyl group, an alkoxycarbonyl group, a saturated aliphatic acyloxy group, an optionally substituted phenylalkyl group, an optionally substituted naphthylalkyl group, an optionally substituted heterocyclyl group, and an amino group substituted with one or two organic groups, specific examples of the substituent that the carbazolyl group may have are the same as the examples of a substituent of the phenyl group when R^{d01} is an optionally substituted phenyl group.

For R^{d01}, when a phenyl group, a naphthyl group, and a heterocyclyl group in a substituent of the carbazolyl group further have a substituent, examples of the further substituent include an alkyl group having 1 or more and 6 or less carbon atoms; an alkoxy group having 1 or more and 6 or less carbon atoms; a saturated aliphatic acyl group having 2 or more and 7 or less carbon atoms; an alkoxycarbonyl group having 2 or more and 7 or less carbon atoms; a saturated aliphatic acyloxy group having 2 or more and 7 or less carbon atoms; a phenyl group; a naphthyl group; a benzoyl group; a naphthoyl group; a benzoyl group substituted with a group selected from the group consisting of an alkyl group having 1 or more and 6 or less carbon atoms, a morpholin-1-yl group, a piperazin-1-yl group, and a phenyl group; a monoalkylamino group having an alkyl group having 1 or more and 6 or less carbon atoms; a dialkylamino group having an alkyl group having 1 or more and 6 or less carbon atoms; a morpholin-1-yl group; a piperazin-1-yl group; a halogen; a nitro group; and a cyano group. When a phenyl group, a naphthyl group, and a heterocyclyl group in a substituent of the carbazolyl group further have a substituent, the number of further substituents is not limited as long as the objects of the present invention are not inhibited, and is preferably 1 or more and 4 or less. When the phenyl group, the naphthyl group, and the heterocyclyl group have a plurality of substituents, the plurality of substituents may be the same as or different from each other.

R^{d02} represents an optionally substituted alkyl group having 1 or more and 10 or less carbon atoms, an optionally substituted phenyl group, or an optionally substituted carbazolyl group.

When R^{d02} is an optionally substituted alkyl group having 1 or more and 10 or less carbon atoms, the alkyl group may be linear or branched. In this case, the number of carbon atoms of the alkyl group is preferably 1 or more and 8 or less, and more preferably 1 or more and 5 or less.

For R^{d02}, there is no particular limitation for substituents on the alkyl group, the phenyl group, or the carbazolyl group as long as the object of the present invention is not inhibited. Examples of suitable substituents which the alkyl group may have on the carbon atom include an alkoxy group having 1 or more and 20 or less carbon atoms, a cycloalkyl group having 3 or more and 10 or less carbon atoms, a cycloalkoxy group having 3 or more and 10 or less carbon atoms, a saturated aliphatic acyl group having 2 or more and 20 or less carbon atoms, an alkoxycarbonyl group having 2 or more and 20 or less carbon atoms, a saturated aliphatic acyloxy group having 2 or more and 20 or less carbon atoms, an optionally substituted phenyl group, an optionally substituted phenoxy group, an optionally substituted phenylthio group, an optionally substituted benzoyl group, an optionally substituted phenoxycarbonyl group, an optionally substituted benzoyloxy group, an optionally substituted phenylalkyl group having 7 or more and 20 or less carbon atoms, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group having 11 or more and 20 or less carbon atoms, an optionally substituted heterocyclyl group, an optionally substituted heterocyclylcarbonyl group, an amino group, an amino group substituted with one or two organic groups, a morpholin-1-yl group, a piperazin-1-yl group, halogen, a nitro group, a cyano group and the like. Examples of a suitable substituent that the phenyl group and the carbazolyl group may have on a carbon atom include the above examples of groups as a suitable substituent that the alkyl group may have on a carbon atom and an alkyl group having 1 or more and 20 or less carbon atoms.

For an alkyl group, an alkoxy group, a cycloalkyl group, a cycloalkoxy group, a saturated aliphatic acyl group, an alkoxycarbonyl group, a saturated aliphatic acyloxy group, an optionally substituted phenylalkyl group, an optionally substituted naphthylalkyl group, an optionally substituted heterocyclyl group and an amino group substituted with one or two organic groups, specific examples of optional substituents on the alkyl group, the phenyl group, or the carbazolyl group are the same as the examples of a substituent of the phenyl group when R^{d01} is an optionally substituted phenyl group.

In a case where the phenyl group, the naphthyl group and the heterocyclyl group included in the substituent on the alkyl group, the phenyl group, or the carbazolyl group in R^{d02} further have a substituent, examples of the further substituent include an alkyl group having 1 or more and 6 or less carbon atoms; an alkoxy group having 1 or more and 6 or less carbon atoms; a saturated aliphatic acyl group having 2 or more and 7 or less carbon atoms; an alkoxycarbonyl group having 2 or more and 7 or less carbon atoms; a saturated aliphatic acyloxy group having 2 or more and 7 or less carbon atoms; a phenyl group; a naphthyl group; a benzoyl group; a naphthoyl group; a benzoyl group substituted with a group selected from the group consisting of an alkyl group having 1 or more and 6 or less carbon atoms, a morpholin-1-yl group, a piperazin-1-yl group and a phenyl group; a monoalkylamino group having an alkyl group having 1 or more and 6 or less carbon atoms; a dialkylamino group having an alkyl group having 1 or more and 6 or less carbon atoms; a morpholin-1-yl group; a piperazin-1-yl group; halogen; a nitro group; and a cyano group. In a case where the phenyl group, the naphthyl group and the heterocyclyl group included in the substituent on the alkyl group or the phenyl group further have a substituent, the number of further substituents is not limited as long as the objects of the present invention are not inhibited, and is preferably 1 or more and 4 or less. In a case where the phenyl group, the naphthyl group and the heterocyclyl group have a plurality of substituents, the substituents may be the same as or different from each other.

From a viewpoint of efficiency of base generation of the compound represented by the formula (d01), as R^{d02}, a group represented by the following formula (d02):

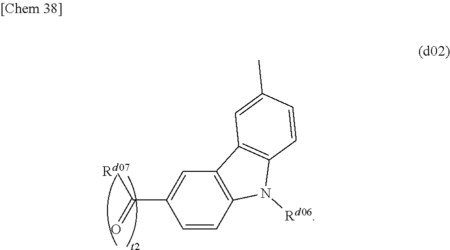

and a group represented by the following formula (d03):

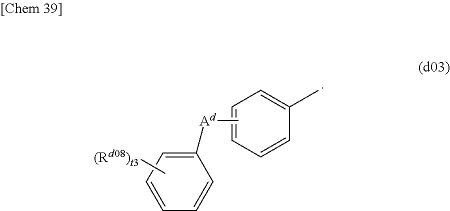

are preferable.

In the formula (d02), R^{d06} and R^{d07} each represent a monovalent organic group and t2 is 0 or 1. In the formula (d03), R^{d08} represents a group selected from the group consisting of a monovalent organic group, an amino group, a halogen, a nitro group, and a cyano group, A^{d} represents S or O, and t3 is an integer of 0 or more and 4 or less.

R^{d06} in the formula (d02) may be selected from various organic groups as long as the objects of the present invention are not inhibited. Examples of suitable R^{d06} include an alkyl group having 1 or more and 20 or less carbon atoms, a cycloalkyl group having 3 or more and 10 or less carbon atoms, a saturated aliphatic acyl group having 2 or more and 20 or less carbon atoms, an alkoxycarbonyl group having 2 or more and 20 or less carbon atoms, an optionally substituted phenyl group, an optionally substituted benzoyl group, an optionally substituted phenoxycarbonyl group, an optionally substituted phenylalkyl group having 7 or more and 20 or less carbon atoms, an optionally substituted naphthyl group, an optionally substituted naphthoyl group, an optionally substituted naphthoxycarbonyl group, an optionally substituted naphthylalkyl group having 11 or more and 20 or less carbon atoms, an optionally substituted heterocyclyl group, and an optionally substituted heterocyclylcarbonyl group.

Among the above groups as R^{d06}, an alkyl group having 1 or more and 20 or less carbon atoms is preferable, an alkyl group having 1 or more and 6 or less carbon atoms is more preferable, and an ethyl group is particularly preferable.

R^{d07} in the formula (d02) is not particularly limited as long as the objects of the present invention are not inhibited, and may be selected from various organic groups. Specific examples of a suitable group as R^{d07} include an alkyl group having 1 or more and 20 or less carbon atoms, an optionally substituted phenyl group, an optionally substituted naphthyl group, and an optionally substituted heterocyclyl group. Among these groups, R^{d07} is more preferably an optionally substituted phenyl group and an optionally substituted naphthyl group, and particularly preferably a 2-methylphenyl group and a naphthyl group.

When a phenyl group, a naphthyl group, and a heterocyclyl group in R^{d06} or R^{d07} further have a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having an alkyl group having 1 or more and 6 or less carbon atoms, a dialkylamino group having an alkyl group having 1 or more and 6 or less carbon atoms, a morpholin-1-yl group, a piperazin-1-yl group, a halogen, a nitro group, and a cyano group. When a phenyl group, a naphthyl group, and a heterocyclyl group in R^{d06} or R^{d07} further have a substituent, the number of substituents is not limited as long as the objects of the present invention are not inhibited, and is preferably 1 or more and 4 or less. When a phenyl group, a naphthyl group, and a heterocyclyl group in R^{d06} or R^{d07} has a plurality of substituents, the plurality of substituents may be the same as or different from each other.

When R^{d06} in the formula (d03) is an organic group, R^{d06} can be selected from various types of organic groups as long as the objects of the present invention are not inhibited. Preferred examples when R^{d06} is an organic group in the formula (d03) include alkyl groups having 1 or more and 6 or less carbon atoms; alkoxy groups having 1 or more and 6 or less carbon atoms; saturated aliphatic acyl groups having 2 or more and 7 or less carbon atoms; alkoxycarbonyl groups having 2 or more and 7 or less carbon atoms; saturated aliphatic acyloxy groups having 2 or more and 7 or less carbon atoms; a phenyl group; a naphthyl group; a benzoyl group; a naphthoyl group; benzoyl groups substituted with a group selected from the group consisting of an alkyl group having 1 or more and 6 or less carbon atoms, a morpholin-1-yl group, a piperazin-1-yl group and a phenyl group; monoalkylamino groups having an alkyl group having 1 or more and 6 or less carbon atoms; dialkylamino groups having alkyl groups having 1 or more and 6 or less carbon atoms; a morpholin-1-yl group; a piperazin-1-yl group; halogen; a nitro group; a cyano group; a 2-methylphenylcarbonyl group; a 4-(piperazin-1-yl)phenylcarbonyl group; and a 4-(phenyl)phenylcarbonyl group.

Among R^{d08}, a benzoyl group; a naphthoyl group; a benzoyl groups substituted with a group selected from the group consisting of an alkyl group having 1 or more and 6 or less carbon atoms, a morpholin-1-yl group, a piperazin-1-yl group, and a phenyl group; and a nitro group are preferred, and a benzoyl group; a naphthoyl group; a 2-methylphenylcarbonyl group; a 4-(piperazine-1-yl)phenylcarbonyl group; and a 4-(phenyl)phenylcarbonyl group are more preferred.

In the formula (d03), t3 is preferably an integer of 0 or more and 3 or less, more preferably an integer of 0 or more and 2 or less, and particularly preferably 0 or 1. When t3 is 1, the position at which R^{d08} bonds is preferably the para-position to the bonding through which the phenyl group (to which R^{d08} bonds) bonds to a sulfur atom.

R^{d03} represents a hydrogen atom, an alkyl group having 1 or more and 6 or less carbon atoms, or an optionally substituted phenyl group. When an optionally substituted phenyl group is represented, the substituent that the phenyl group may have is the same as the substituent for the case in which R^{d01} is an optionally substituted phenyl group. R^{d03} is preferably a methyl group, an ethyl group, or a phenyl group, and more preferably a methyl group or a phenyl group.

Examples of the compound represented by the formula (d01) include a compound represented by the following formula (d04).

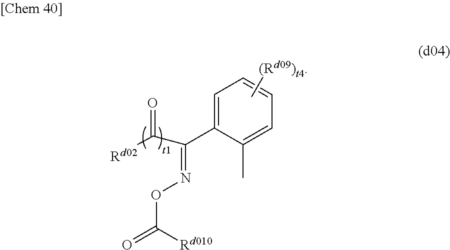

In the formula (d04), t1 and R^{d02} are as described above. R^{d09} represents a group selected from the group consisting of a monovalent organic group, an amino group, a halogen, a nitro group, and a cyano group, t4 is an integer of 0 or more and 4 or less, and R^{d010} represents a hydrogen atom or an alkyl group having 1 or more and 6 or less carbon atoms.

In the formula (d04), R^{d09} is not particularly limited as long as the objects of the present invention are not inhibited, and when it is an organic group, it is appropriately selected from various organic groups. Suitable examples of R^{d09} include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an amino group, an amino group substituted with one or two organic groups, a morpholin-1-yl group, a piperazin-1-yl group, a halogen, a nitro group, and a cyano group. When t4 is an integer of 2 or more and 4 or less, R^{d09} may be the same as or different from each other. The number of carbon atoms of the substituent does not include the number of carbon atoms of any further substituents of the substituent.

When R^{d09} is an alkyl group, the number of carbon atoms is preferably 1 or more and 20 or less, and more preferably 1 or more and 6 or less. When R^{d09} is an alkyl group, the alkyl group may be a linear or branched alkyl group. When R^{d09} is an alkyl group, specific examples thereof include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. When R^{d09} is an alkyl group, the alkyl group may contain an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, a methoxypropyl group, and the like.

When R^{d09} is an alkoxy group, the number of carbon atoms is preferably 1 or more and 20 or less, and more preferably 1 or more and 6 or less. When R^{d09} is an alkoxy group, the alkoxy group may be linear or branched. When R^{d09} is an alkoxy group, specific examples thereof include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, and an isodecyloxy group. When R^{d09} is an alkoxy group, the alkoxy group may contain an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, and a methoxypropyloxy group.

When R^{d09} is a cycloalkyl group or a cycloalkoxy group, the number of carbon atoms is preferably 3 or more and 10 or less, and more preferably 3 or more and 6 or less. When R^{d09} is a cycloalkyl group, specific examples thereof include a cyclopropyl group, a cyclobutyl group, a cyclopentyl group, a cyclohexyl group, a cycloheptyl group, and a cyclooctyl group. When R^{d09} is a cycloalkoxy group, specific examples thereof include a cyclopropyloxy group, a cyclobutyloxy group, a cyclopentyloxy group, a cyclohexyloxy group, a cycloheptyloxy group, and a cyclooctyloxy group.

When R^{d09} is a saturated aliphatic acyl group or a saturated aliphatic acyloxy group, the number of carbon atoms is preferably 2 or more and 20 or less, and more preferably 2 or more and 7 or less. When R^{d09} is a saturated aliphatic acyl group, specific examples thereof include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, and an n-hexadecanoyl group. When R^{d09} is a saturated aliphatic acyloxy group, specific examples thereof include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, and an n-hexadecanoyloxy group.

When R^{d09} is an alkoxycarbonyl group, the number of carbon atoms is preferably 2 or more and 20 or less, and preferably 2 or more and 7 or less. When R^{d09} is an alkoxycarbonyl group, specific examples thereof include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, and an isodecyloxycarbonyl group.

When R^{d09} is a phenylalkyl group, the number of carbon atoms is preferably 7 or more and 20 or less, and more preferably 7 or more and 10 or less. When R^{d09} is a naphthylalkyl group, the number of carbon atoms is preferably 11 or more and 20 or less, and more preferably 11 or more and 14 or less. When R^{d09} is a phenylalkyl group, specific examples thereof include a benzyl group, a 2-phenylethyl group, a 3-phenylpropyl group, and a 4-phenylbutyl group. When R^{d09} is a naphthylalkyl group, specific examples thereof include an α-naphthylmethyl group, a β-naphthylmethyl group, a 2-(α-naphthyl)ethyl group, and a 2-(β-naphthyl)ethyl group. When R^{d09} is a phenylalkyl group or a naphthylalkyl group, R^{d09} may further have a substituent on a phenyl group or a naphthyl group.

When R^{d09} is a heterocyclyl group, the heterocyclyl group is a 5- or 6-membered monocycle including one or more N, S, and O, or a heterocyclyl group in which these monocycles are condensed with each other, or the monocycle and a benzene ring are condensed. When the heterocyclyl group is a condensed ring, the number of rings constituting the condensed ring is 3 or less. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, and the like. When R^{d09} is a heterocyclyl group, the heterocyclyl group may have a further substituent.

When R^{d09} is an amino group substituted with one or two organic groups, suitable examples of the organic group include an alkyl group having 1 or more and 20 or less carbon atoms, a cycloalkyl group having 3 or more and 10 or less carbon atoms, a saturated aliphatic acyl group having 2 or more and 20 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more and 20 or less carbon atoms, a heterocyclyl group, and the like. Specific examples of suitable organic group are the same as those in R^{d09}. Specific examples of the amino group substituted with one or two organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoylamino group, an n-hexanoylamino group, an n-heptanoylamino group, an n-octanoylamino group, an n-decanoylamino group, a benzoylamino group, an α-naphthoylamino group, a β-naphthoylamino group, and the like.

When a phenyl group, a naphthyl group, and a heterocyclyl group included in R^{d09} further have a substituent, examples of the substituent include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group which has an alkyl group having 1 or more and 6 or less carbon atoms, a dialkylamino group which has an alkyl group having 1 or more and 6 or less carbon atoms, a morpholin-1-yl group, a piperazin-1-yl group, halogen, a nitro group, a cyano group, and the like. When a phenyl group, a naphthyl group, and a heterocyclyl group included in R^{d09} further have a substituent, the number of substituents is not particularly limited as long as the object of the present invention is not inhibited, and is preferably 1 or more and 4 or less. When a phenyl group, a naphthyl group, and a heterocyclyl group included in R^{d09} have a plurality of substituents, the plurality of substituents may be the same as or different from each other.

Among R^{d09}, a group selected from the group consisting of an alkyl group having 1 or more and 6 or less carbon atoms, an alkoxy group having 1 or more and 6 or less carbon atoms, and a saturated aliphatic acyl group having 2 or more and 7 or less carbon atoms is preferable, an alkyl having 1 or more and 6 or less carbon atoms is more preferable, and a methyl group is particularly preferable, since these are chemically stable and facilitate the synthesis of an oxime ester compound due to little steric hindrance.

When the position of a bond of the phenyl group and the main skeleton of an oxime ester compound is regarded as the 1-position and the position of the methyl group is regarded as the 2-position with respect to the phenyl group to which R^{d09} is bonded, the position at which R^{d09} is bonded to the phenyl group is preferably the 4-position or the 5-position, and more preferably the 5-position. t4 is preferably an integer of 0 or more and 3 or less, more preferably an integer of 0 or more and 2 or less, and particularly preferably 0 or 1.

R^{d010} in the formula (d04) is a hydrogen atom, or an alkyl group having 1 or more and 6 or less carbon atoms. R^{d010} is preferably a methyl group or an ethyl group, and more preferably a methyl group.

Specific examples of a particularly suitable compound as an oxime ester compound represented by the formula (d01) are as follows.

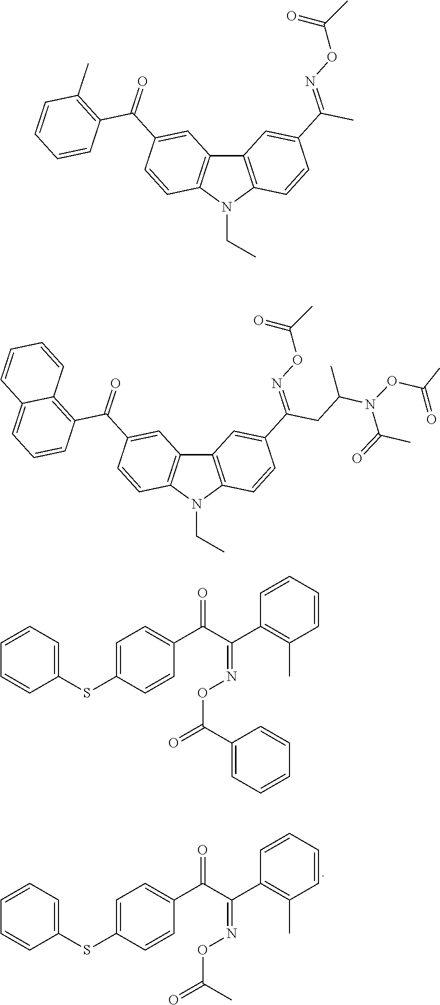

A compound represented by the following formula (d05) is also suitably used as an oxime ester compound.

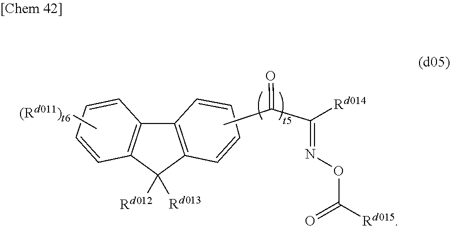

R^{d011} is a hydrogen atom, a nitro group, or a monovalent organic group; R^{d012} and R^{d013} each represent an optionally substituted chain alkyl group, an optionally substituted cyclic organic group, or a hydrogen atom, and R^{d012} and R^{d013} may be bonded to one another to form a ring; R^{d014} is a monovalent organic group; R^{d015} is a hydrogen atom, an optionally substituted alkyl group having 1 or more and 11 or less carbon atoms, or an optionally substituted aryl group; t6 is an integer of 0 or more and 4 or less; and t5 is 0 or 1.

In the formula (d05), R^{d011} is a hydrogen atom, a nitro group, or a monovalent organic group. R^{d011} is bonded to a 6-membered aromatic ring which is different from the 6-membered aromatic ring bonded to a group represented as —(CO)ₜ₅— on a fluorene ring in the formula (d05). In the formula (d05), the bond position of R^{d011} to a fluorene ring is not particularly limited. When a compound represented by the formula (d05) has one or more R^{d011}, one of the one or more R^{d011} is preferably bonded at the 2-position in the fluorene ring since synthesis of the compound represented by the formula (d05) becomes easy. When a plurality of R^{d011} exist, the plurality of R^{d011} may be the same or different.

When R^{d011} is an organic group, R^{d011} is not particularly limited as long as the object of the present invention is not inhibited, and is appropriately selected from various organic groups. When R^{d011} is an organic group, suitable examples thereof include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or two organic groups, a morpholin-1-yl group, and a piperazin-1-yl group.

When R^{d011} is an alkyl group, the number of carbon atoms of the alkyl group is preferably 1 or more and 20 or less, and more preferably 1 or more and 6 or less. When R^{d011} is an alkyl group, the alkyl group may be a linear or branched alkyl group. When R^{d011} is an alkyl group, specific examples thereof include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, an isodecyl group, and the like. When R^{d011} is an alkyl group, the alkyl group may contain an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, a methoxypropyl group, and the like.

When R^{d011} is an alkoxy group, the number of carbon atoms of the alkoxy group is preferably 1 or more and 20 or less, and more preferably 1 or more and 6 or less. When R^{d011} is an alkoxy group, the alkoxy group may be linear or branched. When R^{d011} is an alkoxy group, specific examples thereof include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, and an isodecyloxy group. When R^{d011} is an alkoxy group, the alkoxy group may contain an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, and a methoxypropyloxy group.

When R^{d011} is a cycloalkyl group or a cycloalkoxy group, the number of carbon atoms of the cycloalkyl group or cycloalkoxy group is preferably 3 or more and 10 or less, and more preferably 3 or more and 6 or less. When R^{d011} is a cycloalkyl group, specific examples thereof include a cyclopropyl group, a cyclobutyl group, a cyclopentyl group, a cyclohexyl group, a cycloheptyl group, and a cyclooctyl group. When R^{d011} is a cycloalkoxy group, specific examples thereof include a cyclopropyloxy group, a cyclobutyloxy group, a cyclopentyloxy group, a cyclohexyloxy group, a cycloheptyloxy group, and a cyclooctyloxy group.

When R^{d011} is a saturated aliphatic acyl group or a saturated aliphatic acyloxy group, the number of carbon atoms of the saturated aliphatic acyl group or saturated aliphatic acyloxy group is preferably 2 or more and 21 or less, and more preferably 2 or more and 7 or less. When R^{d011} is a saturated aliphatic acyl group, specific examples thereof include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, and an n-hexadecanoyl group. When R^{d011} is a saturated aliphatic acyloxy group, specific examples thereof include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, and an n-hexadecanoyloxy group.

When R^{d011} is an alkoxycarbonyl group, the number of carbon atoms of the alkoxycarbonyl group is preferably 2 or more and 20 or less, and more preferably 2 or more and 7 or less. When R^{d011} is an alkoxycarbonyl group, specific examples thereof include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, and an isodecyloxycarbonyl group.

When R^{d011} is a phenylalkyl group, the number of carbon atoms of the phenylalkyl group is preferably 7 or more and 20 or less, and more preferably 7 or more and 10 or less. When R^{d011} is a naphthylalkyl group, the number of carbon atoms of the naphthylalkyl group is preferably 11 or more and 20 or less, and more preferably 11 or more and 14 or less. When R^{d011} is a phenylalkyl group, specific examples thereof include a benzyl group, a 2-phenylethyl group, a 3-phenylpropyl group, and a 4-phenylbutyl group. When R^{d011} is a naphthylalkyl group, specific examples thereof include an α-naphthylmethyl group, a β-naphthylmethyl group, a 2-(α-naphthyl)ethyl group, and a 2-(R-naphthyl)ethyl group. When R^{d011} is a phenylalkyl group or a naphthylalkyl group, R^{d011} may further have a substituent on the phenyl group or the naphthyl group.

When R^{d011} is a heterocyclyl group, the heterocyclyl group is a 5- or 6-membered monocycle including one or more N, S, and O, or a heterocyclyl group in which these monocycles are condensed with each other, or the monocycle and a benzene ring are condensed. When the heterocyclyl group is a condensed ring, the number of rings constituting the condensed ring is 3 or less. The heterocyclyl group may be an aromatic group (heteroaryl group) or a non-aromatic group. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, and tetrahydrofuran. When R^{d011} is a heterocyclyl group, the heterocyclyl group may further have a substituent.

When R^{d011} is a heterocyclylcarbonyl group, the heterocyclyl group included in the heterocyclylcarbonyl group is the same as that in the case where R^{d011} is a heterocyclyl group.

When R^{d011} is an amino group substituted with one or two organic groups, suitable examples of the organic groups include an alkyl group having 1 or more and 20 or less carbon atoms, a cycloalkyl group having 3 or more and 10 or less carbon atoms, a saturated aliphatic acyl group having 2 or more and 21 or less carbon atoms, an optionally substituted phenyl group, an optionally substituted benzoyl group, an optionally substituted phenylalkyl group having 7 or more and 20 or less carbon atoms, an optionally substituted naphthyl group, an optionally substituted naphthoyl group, an optionally substituted naphthylalkyl group having 11 or more and 20 or less carbon atoms, and a heterocyclyl group. The specific examples of these suitable organic groups are the same as those of R^{d011}. Specific examples of the amino group substituted with one or two organic groups include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, a propanoylamino group, an n-butanoylamino group, an n-pentanoylamino group, an n-hexanoylamino group, an n-heptanoylamino group, an n-octanoylamino group, an n-decanoylamino group, a benzoylamino group, an α-naphthoylamino group, and a β-naphthoylamino group.

When the phenyl group, the naphthyl group, and the heterocyclyl group included in R^{d011} further have a substituent, examples thereof include an alkyl group having 1 or more and 6 or less carbon atoms, an alkoxy group having 1 or more and 6 or less carbon atoms, a saturated aliphatic acyl group having 2 or more and 7 or less carbon atoms, an alkoxycarbonyl group having 2 or more and 7 or less carbon atoms, a saturated aliphatic acyloxy group having 2 or more and 7 or less carbon atoms, a monoalkylamino group having an alkyl group which has 1 or more and 6 or less carbon atoms, a dialkylamino group having an alkyl group which has 1 or more and 6 or less carbon atoms, a morpholin-1-yl group, a piperazin-1-yl group, halogen, a nitro group, and a cyano group. When a phenyl group, a naphthyl group, and a heterocyclyl group included in R^{d011} further have substituents, the number of substituents is not particularly limited as long as the object of the present invention is not inhibited, and is preferably 1 or more and 4 or less. When a phenyl group, a naphthyl group, and a heterocyclyl group included in R^{d011} have a plurality of substituents, the plurality of substituents may be the same or different.

Among the above-described groups, R^{d011} is preferably a nitro group or a group represented as R^{d016}—CO— since the sensitivity tends to be improved. R^{d016} is not particularly limited as long as the object of the present invention is not inhibited, and can be selected from various organic groups. Examples of the group suitable as R^{d016} include an alkyl group having 1 or more and 20 or less carbon atoms, an optionally substituted phenyl group, an optionally substituted naphthyl group, and an optionally substituted heterocyclyl group. Among these groups, R^{d016} is particularly preferably a 2-methylphenyl group, a thiophen-2-yl group, and an α-naphthyl group. R^{d011} is also preferably a hydrogen atom. When R^{d011} is a hydrogen atom, R^{d014} is preferably a group represented by the following formula (d07).

In the formula (d05), R_{d012} and R^{d013} each represent an optionally substituted chain alkyl group, an optionally substituted cyclic organic group, or a hydrogen atom. R^{d012} and R^{d013} may be bonded to one another to form a ring. Among these groups, preferably, R^{d012} and R^{d013} are optionally substituted chain alkyl groups. When R^{d012} and R^{d013} are optionally substituted chain alkyl groups, a chain alkyl group may be a linear alkyl group or a branched alkyl group.

When R^{d012} and R^{d013} are chain alkyl groups having no substituents, the number of carbon atoms of the chain alkyl group is preferably 1 or more and 20 or less, more preferably 1 or more and 10 or less, and particularly preferably 1 or more and 6 or less. When R^{d012} and R^{d013} are chain alkyl groups, specific examples thereof include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, and an isodecyl group. When R^{d012} and R^{d013} are alkyl groups, the alkyl group may have an ether bond (—O—) in a carbon chain. Examples of the alkyl group having an ether bond in a carbon chain include a methoxyethyl group, an ethoxyethyl group, a methoxyethoxyethyl group, an ethoxyethoxyethyl group, a propyloxyethoxyethyl group, and a methoxypropyl group.

When R^{d012} and R^{d013} are chain alkyl groups having a substituent, the number of carbon atoms of the chain alkyl group is preferably 1 or more and 20 or less, more preferably 1 or more and 10 or less, and particularly preferably 1 or more and 6 or less. In this case, the number of carbon atoms of the substituent is not included in the number of carbon atoms of the chain alkyl group. The chain alkyl group having a substituent is preferably a linear group. The substituent, with which the alkyl group is optionally substituted, is not particularly limited as long as the object of the present invention is not inhibited. Suitable examples of the substituent include a cyano group, a halogen atom, a cyclic organic group, and an alkoxycarbonyl group. Examples of the halogen atom include a fluorine atom, a chlorine atom, a bromine atom, and an iodine atom. Among these, a fluorine atom, a chlorine atom, and a bromine atom are preferable. Examples of the cyclic organic group include a cycloalkyl group, an aromatic hydrocarbon group, and a heterocyclyl group. Specific examples of the cycloalkyl group are the same as suitable examples in the case where R^{d011} is a cycloalkyl group. Specific examples of the aromatic hydrocarbon group include a phenyl group, a naphthyl group, a biphenylyl group, an anthryl group, and a phenanthryl group. Specific examples of the heterocyclyl group are the same as suitable examples in the case where R^{d011} is a heterocyclyl group. When R^{d011} is an alkoxycarbonyl group, the alkoxy group included in the alkoxycarbonyl group may be a linear or branched group, and preferably a linear group. The number of carbon atoms of an alkoxy group included in the alkoxycarbonyl group is preferably 1 or more and 10 or less, and more preferably 1 or more and 6 or less.

When the chain alkyl group has a substituent, the number of substituents is not particularly limited. The number of substituents preferably varies depending on the number of carbon atoms of the chain alkyl group. The number of substituents is typically 1 or more and 20 or less, preferably 1 or more and 10 or less, and more preferably 1 or more and 6 or less.

When R^{d012} and R^{d013} are cyclic organic groups, the cyclic organic groups may be an alicyclic group or an aromatic group. Examples of the cyclic organic group include an aliphatic cyclic hydrocarbon group, an aromatic hydrocarbon group, and a heterocyclyl group. When R^{d012} and R^{d013} are cyclic organic groups, the substituent, with which the cyclic organic group is optionally substituted, is the same as in the case where R^{d012} and R^{d013} are chain alkyl groups.

When R^{d012} and R^{d013} are aromatic hydrocarbon groups, the aromatic hydrocarbon group is preferably a phenyl group, or a group formed by bonding multiple benzene rings through a carbon-carbon bond, or a group formed by condensing multiple benzene rings. When the aromatic hydrocarbon group is a phenyl group, or a group formed by bonding or condensing multiple benzene rings, the number of benzene rings included in the aromatic hydrocarbon group is not particularly limited, and is preferably 3 or less, more preferably 2 or less, and particularly preferably 1. Preferred specific examples of the aromatic hydrocarbon group include a phenyl group, a naphthyl group, a biphenylyl group, an anthryl group, and a phenanthryl group.

When R^{d012} and R^{d013} are aliphatic cyclic hydrocarbon groups, the aliphatic cyclic hydrocarbon group may be a monocyclic or polycyclic group. The number of carbon atoms of the aliphatic cyclic hydrocarbon group is not particularly limited, and is preferably 3 or more and 20 or less, and more preferably 3 or more and 10 or less. Examples of the monocyclic cyclic hydrocarbon group include cyclopropyl group, a cyclobutyl group, a cyclopentyl group, a cyclohexyl group, a cycloheptyl group, a cyclooctyl group, a norbornyl group, an isobornyl group, a tricyclononyl group, a tricyclodecyl group, a tetracyclododecyl group, and an adamantyl group.

When R^{d012} and R^{d013} are heterocyclyl groups, the heterocyclyl group is a 5- or 6-membered monocycle including one or more N, S, and O, or a heterocyclyl group in which these monocycles are condensed with each other, or the monocycle and a benzene ring are condensed. When the heterocyclyl group is a condensed ring, the number of rings constituting the condensed ring is 3 or less. The heterocyclyl group may be an aromatic group (heteroaryl group) or a non-aromatic group. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, and tetrahydrofuran.

R^{d012} and R^{d013} may be bonded to one another to form a ring. The group composed of the ring formed by R^{d012} and R^{d013} is preferably a cycloalkylidene group. When R^{d012} and R^{d013} are bonded to form a cycloalkylidene group, the ring constituting the cycloalkylidene group is preferably a 5- to 6-membered ring, and more preferably a 5-membered ring.

When the group formed by bonding R^{d012} and R^{d013} is a cycloalkylidene group, the cycloalkylidene group may be condensed with one or more other rings. Examples of the ring which may be condensed with the cycloalkylidene group include a benzene ring, a naphthalene ring, a cyclobutane ring, a cyclopentane ring, a cyclohexane ring, a cycloheptane ring, a cyclooctane ring, a furan ring, a thiophene ring, a pyrrole ring, a pyridine ring, a pyrazine ring, a pyrimidine ring, and the like.

Examples of a suitable group among R^{d012} and R^{d013} described above include a group represented by the formula: -A^{d1}-A^{d2}. In the formula, A^{d2} is a linear alkylene group, and A^{d2} is an alkoxy group, a cyano group, a halogen atom, a halogenated alkyl group, a cyclic organic group, or an alkoxycarbonyl group.

The number of carbon atoms of the linear alkylene group for A^{d1} is preferably 1 or more and 10 or less, and more preferably 1 or more and 6 or less. When A^{d2} is an alkoxy group, the alkoxy group may be a linear or branched alkoxy group, and preferably a linear alkoxy group. The number of carbon atoms of the alkoxy group is preferably 1 or more and 10 or less, and more preferably 1 or more and 6 or less. When A^{d2} is a halogen atom, a fluorine atom, a chlorine atom, a bromine atom, or an iodine atom is preferable, and a fluorine atom, a chlorine atom, or a bromine atom is more preferable. When A^{d2} is a halogenated alkyl group, a halogen atom included in the halogenated alkyl group is preferably a fluorine atom, a chlorine atom, a bromine atom, or an iodine atom, and more preferably is a fluorine atom, a chlorine atom, or a bromine atom. The halogenated alkyl group may be a linear or branched halogenated alkyl group, preferably a linear halogenated alkyl group. When A^{d2} is a cyclic organic group, examples of the cyclic organic group are the same as the cyclic organic group possessed by R^{d012} and R^{d013} as a substituent. When A^{d2} is an alkoxycarbonyl group, examples of the alkoxycarbonyl group are the same as the alkoxycarbonyl group possessed by R^{d012} and R^{d013} as a substituent.

Suitable specific examples of R^{d012} and R^{d013} include alkyl groups such as an ethyl group, an n-propyl group, an n-butyl group, an n-hexyl group, an n-heptyl group, and an n-octyl group; alkoxyalkyl groups such as a 2-methoxyethyl group, a 3-methoxy-n-propyl group, a 4-methoxy-n-butyl group, a 5-methoxy-n-pentyl group, a 6-methoxy-n-hexyl group, a 7-methoxy-n-heptyl group, a 8-methoxy-n-octyl group, a 2-ethoxyethyl group, a 3-ethoxy-n-propyl group, a 4-ethoxy-n-butyl group, a 5-ethoxy-n-pentyl group, a 6-ethoxy-n-hexyl group, a 7-ethoxy-n-heptyl group, and a 8-ethoxy-n-octyl group; cyanoalkyl groups such as a 2-cyanoethyl group, a 3-cyano-n-propyl group, a 4-cyano-n-butyl group, a 5-cyano-n-pentyl group, a 6-cyano-n-hexyl group, a 7-cyano-n-heptyl group, and a 8-cyano-n-octyl group; phenylalkyl groups such as a 2-phenylethyl group, a 3-phenyl-n-propyl group, a 4-phenyl-n-butyl group, a 5-phenyl-n-pentyl group, a 6-phenyl-n-hexyl group, a 7-phenyl-n-heptyl group, and a 8-phenyl-n-octyl group; cycloalkylalkyl groups such as a 2-cyclohexylethyl group, a 3-cyclohexyl-n-propyl group, a 4-cyclohexyl-n-butyl group, a 5-cyclohexyl-n-pentyl group, a 6-cyclohexyl-n-hexyl group, a 7-cyclohexyl-n-heptyl group, a 8-cyclohexyl-n-octyl group, a 2-cyclopentylethyl group, a 3-cyclopentyl-n-propyl group, a 4-cyclopentyl-n-butyl group, a 5-cyclopentyl-n-pentyl group, a 6-cyclopentyl-n-hexyl group, a 7-cyclopentyl-n-heptyl group, and a 8-cyclopentyl-n-octyl group; alkoxycarbonylalkyl groups such as a 2-methoxycarbonylethyl group, a 3-methoxycarbonyl-n-propyl group, a 4-methoxycarbonyl-n-butyl group, a 5-methoxycarbonyl-n-pentyl group, a 6-methoxycarbonyl-n-hexyl group, a 7-methoxycarbonyl-n-heptyl group, a 8-methoxycarbonyl-n-octyl group, a 2-ethoxycarbonylethyl group, a 3-ethoxycarbonyl-n-propyl group, a 4-ethoxycarbonyl-n-butyl group, a 5-ethoxycarbonyl-n-pentyl group, a 6-ethoxycarbonyl-n-hexyl group, a 7-ethoxycarbonyl-n-heptyl group, and a 8-ethoxycarbonyl-n-octyl group; and halogenated alkyl groups such as a 2-chloroethyl group, a 3-chloro-n-propyl group, a 4-chloro-n-butyl group, a 5-chloro-n-pentyl group, a 6-chloro-n-hexyl group, a 7-chloro-n-heptyl group, a 8-chloro-n-octyl group, a 2-bromoethyl group, a 3-bromo-n-propyl group, a 4-bromo-n-butyl group, a 5-bromo-n-pentyl group, a 6-bromo-n-hexyl group, a 7-bromo-n-heptyl group, a 8-bromo-n-octyl group, a 3,3,3-trifluoropropyl group, and a 3,3,4,4,5,5,5-heptafluoro-n-pentyl group.

Among groups mentioned above, groups suitable as R^{d012} and R^{d013} are an ethyl group, an n-propyl group, an n-butyl group, an n-pentyl group, a 2-methoxyethyl group, a 2-cyanoethyl group, a 2-phenylethyl group, a 2-cyclohexylethyl group, a 2-methoxycarbonylethyl group, a 2-chloroethyl group, a 2-bromoethyl group, a 3,3,3-trifluoropropyl group, and a 3,3,4,4,5,5,5-heptafluoro-n-pentyl group.

In the same manner as R^{d011}, examples of a suitable organic group for R^{d014} include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or two organic groups, a morpholin-1-yl group, a piperazin-1-yl group, and the like. Specific examples of these groups are the same as the specific examples described for R^{d011}. R^{d014} is also preferably a cycloalkylalkyl group, a phenoxyalkyl group which may have a substituent on the aromatic ring, and a phenylthioalkyl group which may have a substituent on the aromatic ring. The substituent which may be possessed by a phenoxyalkyl group and phenylthioalkyl group is the same as the substituent which may be possessed by a phenyl group included in R^{d011}.

Among the organic groups, R^{d014} is preferably an alkyl group, a cycloalkyl group, an optionally substituted phenyl group or cycloalkylalkyl group, or a phenylthioalkyl group which may have a substituent on the aromatic ring. The alkyl group is preferably an alkyl group having 1 or more and 20 or less carbon atoms, more preferably an alkyl group having 1 or more and 8 or less carbon atoms, particularly preferably an alkyl group having 1 or more and 4 or less carbon atoms, and most preferably a methyl group. Among an optionally substituted phenyl groups, a methylphenyl group is preferable, and a 2-methylphenyl group is more preferable. The number of carbon atoms of the cycloalkyl group included in the cycloalkylalkyl group is preferably 5 or more and 10 or less, more preferably 5 or more and 8 or less, and particularly preferably 5 or 6. The number of carbon atoms of the alkylene group included in the cycloalkylalkyl group is preferably 1 or more and 8 or less, more preferably 1 or more and 4 or less, and particularly preferably 2. Among cycloalkylalkyl groups, a cyclopentylethyl group is preferable. The number of carbon atoms of the alkylene group included in the phenylthioalkyl group which may have a substituent on the aromatic ring is preferably 1 or more and 8 or less, more preferably 1 or more and 4 or less, and particularly preferably 2. Among the phenylthioalkyl groups which may have a substituent on the aromatic ring, a 2-(4-chlorophenylthio)ethyl group is preferable.

R^{d014} is also preferably a group represented by -A^{d3}-CO—O-A^{d4}. A^{d3} is a divalent organic group, preferably a divalent hydrocarbon group, and more preferably an alkylene group. A^{d4} is a monovalent organic group, and preferably a monovalent hydrocarbon group.

When A^{d3} is an alkylene group, the alkylene group may be a linear or branched alkylene group, preferably a linear alkylene group. When Ada is an alkylene group, the number of carbon atoms of the alkylene group is preferably 1 or more and 10 or less, more preferably 1 or more and 6 or less, and particularly preferably 1 or more and 4 or less.

Suitable examples of A^{d4} include an alkyl group having 1 or more and 10 or less carbon atoms, an aralkyl group having 7 or more and 20 or less carbon atoms, and an aromatic hydrocarbon group having 6 or more and 20 or less carbon atoms. Suitable specific examples of A^{d4} include a methyl group, an ethyl group, an n-propyl group, an isopropyl group, an n-butyl group, an isobutyl group, a sec-butyl group, a tert-butyl group, an n-pentyl group, an n-hexyl group, a phenyl group, a naphthyl group, a benzyl group, a phenethyl group, an α-naphthylmethyl group, a β-naphthylmethyl group, and the like.

Specific examples of a suitable group represented by -A^{d3}-CO—O-A^{d4} include a 2-methoxycarbonylethyl group, a 2-ethoxycarbonylethyl group, a 2-n-propyloxycarbonylethyl group, a 2-n-butyloxycarbonylethyl group, a 2-n-pentyloxycarbonylethyl group, a 2-n-hexyloxycarbonylethyl group, a 2-benzyloxycarbonylethyl group, a 2-phenoxycarbonylethyl group, a 3-methoxycarbonyl-n-propyl group, a 3-ethoxycarbonyl-n-propyl group, a 3-n-propyloxycarbonyl-n-propyl group, a 3-n-butyloxycarbonyl-n-propyl group, a 3-n-pentyloxycarbonyl-n-propyl group, a 3-n-hexyloxycarbonyl-n-propyl group, a 3-benzyloxycarbonyl-n-propyl group, a 3-phenoxycarbonyl-n-propyl group, and the like.

While R^{d014} has been described above, R^{d014} is preferably a group represented by the following formula (d06) or (d07):

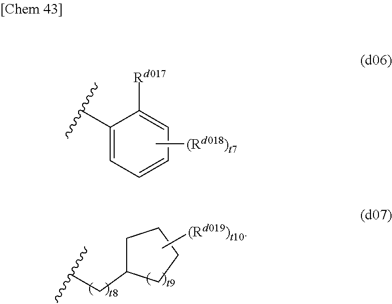

in which, in the formulas (d06) and (d07), R^{d017} and R^{d018} are each an organic group; t7 is an integer of 0 or more and 4 or less; when R^{d017} and R^{d018} are adjacent to each other on the benzene ring, R^{d017} and R^{d018} may be bonded to each other to form a ring; t8 is an integer of 1 or more and 8 or less; t9 is an integer of 1 or more and 5 or less; t10 is an integer of 0 or more and (t9+3) or less; and R^{d019} represents an organic group.

Examples of the organic group for R^{d017} and R^{d018} in the formula (d06) are the same as those in R^{d011}, R^{d017 is} preferably an alkyl group or a phenyl group. When R^{d017} is an alkyl group, the number of carbon atoms thereof is preferably 1 or more and 10 or less, more preferably 1 or more and 5 or less, particularly preferably 1 or more and 3 or less, and most preferably 1. Namely, R^{d017} is most preferably a methyl group. When R^{d017} and R^{d018} are bonded to form a ring, the ring may be an aromatic ring or an aliphatic ring. Suitable examples of the group represented by the formula (d06) in which R^{c117} and R^{c118} form a ring include a naphthalen-1-yl group, a 1,2,3,4-tetrahydronaphthalen-5-yl group, and the like. In the above formula (d06), t7 is an integer of 0 or more and 4 or less, preferably 0 or 1, and more preferably 0.

In the above formula (d07), R^{d019} is an organic group. Examples of the organic group include the same groups as the organic groups described for R^{d011}. Among the organic groups, an alkyl group is preferable. The alkyl group may be a linear or branched alkyl group. The number of carbon atoms of the alkyl group is preferably 1 or more and 10 or less, more preferably 1 or more and 5 or less, and particularly preferably 1 or more and 3 or less. Preferable examples of R^{d019} include a methyl group, an ethyl group, an isopropyl group, a butyl group and the like. Among these, a methyl group is more preferable.

In the formula (d07), t9 is an integer of 1 or more and 5 or less, preferably an integer of 1 or more and 3 or less, more preferably 1 or 2. In the formula (d07), t10 is 0 or more and (t9+3) or less, preferably an integer of 0 or more and 3 or less, more preferably an integer of 0 or more and 2 or less, particularly preferably 0. In the formula (d07), t8 is an integer of 1 or more and 8 or less, preferably an integer of 1 or more and 5 or less, more preferably an integer of 1 or more and 3 or less, particularly preferably 1 or 2.

In the formula (d05), R^{d015} is a hydrogen atom, an optionally substituted alkyl group having 1 or more and 11 or less carbon atoms, or an optionally substituted aryl group. When R^{d015} is an alkyl group, preferable examples of the substituent which may be possessed include a phenyl group, a naphthyl group, or the like. When R^{d011} is an aryl group, preferable examples of the substituent which may be possessed include an alkyl group having 1 or more and 5 or less carbon atoms, an alkoxy group, a halogen atom, or the like.

In the formula (d05), preferable examples of R^{d015} include a hydrogen atom, a methyl group, an ethyl group, an n-propyl group, an isopropyl group, an n-butyl group, a phenyl group, a benzyl group, a methylphenyl group, a naphthyl group, and the like. Among these, a methyl group or a phenyl group is more preferable.

The method of producing the compound represented by the formula (d05) is not particularly limited, and the compound represented by the formula (d05) can be obtained by a known method.

Specific examples of a suitable compound represented by the formula (d05) include the following compounds 1 to 41.

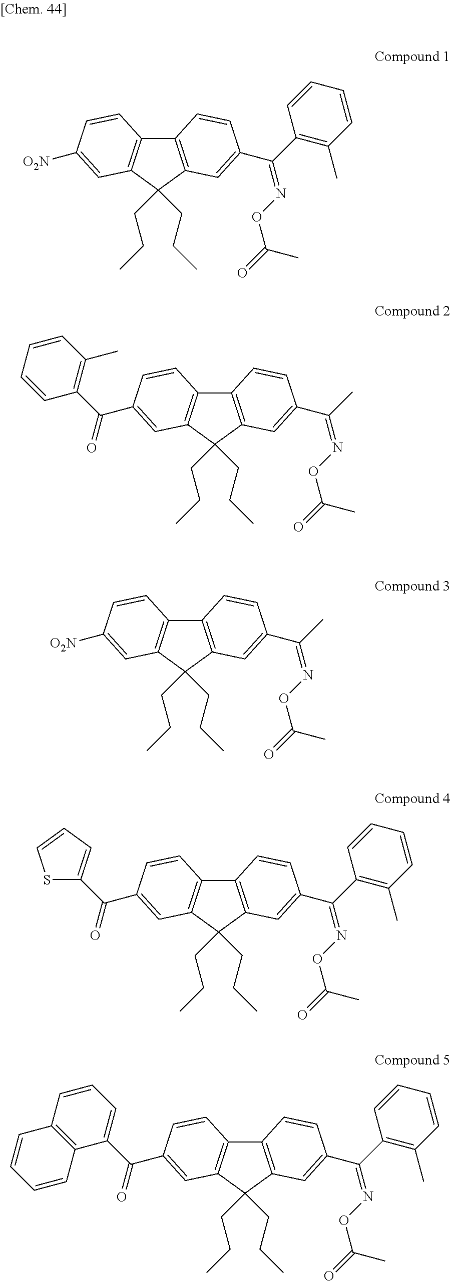 [SMILES: CCCC1(CCC)c2cc(/C(=N\OC(C)=O)c3ccccc3C)ccc2-c2ccc([N+](=O)[O-])cc21 ; CCCC1(CCC)c2cc(C(=O)c3ccccc3C)ccc2-c2ccc(/C(C)=N\OC(C)=O)cc21 ; CCCC1(CCC)c2cc(/C(C)=N\OC(C)=O)ccc2-c2ccc([N+](=O)[O-])cc21 ; CCCC1(CCC)c2cc(C(=O)c3cccs3)ccc2-c2ccc(/C(=N\OC(C)=O)c3ccccc3C)cc21 ; CCCC1(CCC)c2cc(C(=O)c3cccc4ccccc34)ccc2-c2ccc(/C(=N\OC(C)=O)c3ccccc3C)cc21]

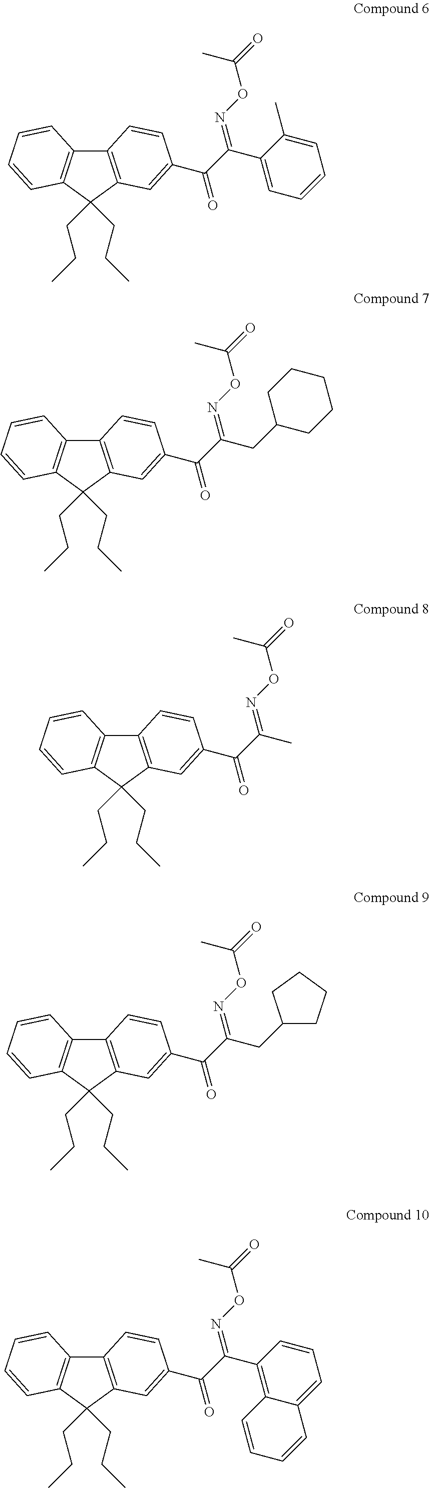 [SMILES: CCCC1(CCC)c2ccccc2-c2ccc(C(=O)/C(=N/OC(C)=O)c3ccccc3C)cc21 ; CCCC1(CCC)c2ccccc2-c2ccc(C(=O)/C(CC3CCCCC3)=N/OC(C)=O)cc21 ; CCCC1(CCC)c2ccccc2-c2ccc(C(=O)/C(C)=N/OC(C)=O)cc21 ; CCCC1(CCC)c2ccccc2-c2ccc(C(=O)/C(CC3CCCC3)=N/OC(C)=O)cc21 ; CCCC1(CCC)c2ccccc2-c2ccc(C(=O)/C(=N/OC(C)=O)c3cccc4ccccc34)cc21]

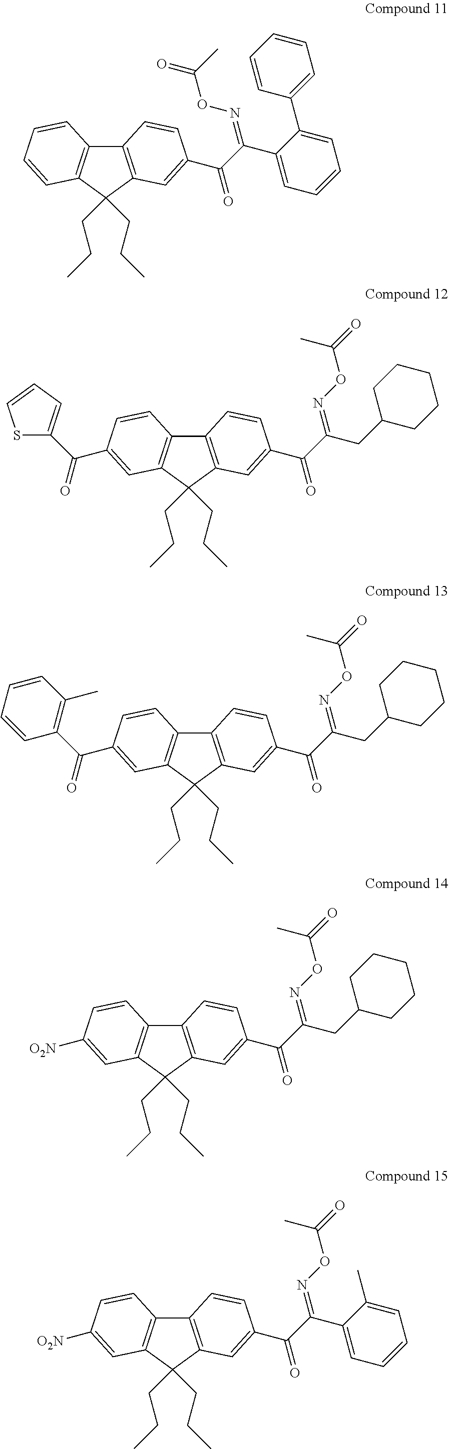 [SMILES: CCCC1(CCC)c2ccccc2-c2ccc(C(=O)/C(=N\OC(C)=O)c3ccccc3-c3ccccc3)cc21 ; CCCC1(CCC)c2cc(C(=O)/C(CC3CCCCC3)=N/OC(C)=O)ccc2-c2ccc(C(=O)c3cccs3)cc21 ; CCCC1(CCC)c2cc(C(=O)/C(CC3CCCCC3)=N/OC(C)=O)ccc2-c2ccc(C(=O)c3ccccc3C)cc21 ; CCCC1(CCC)c2cc(C(=O)/C(CC3CCCCC3)=N/OC(C)=O)ccc2-c2ccc([N+](=O)[O-])cc21 ; CCCC1(CCC)c2cc(C(=O)/C(=N/OC(C)=O)c3ccccc3C)ccc2-c2ccc([N+](=O)[O-])cc21]

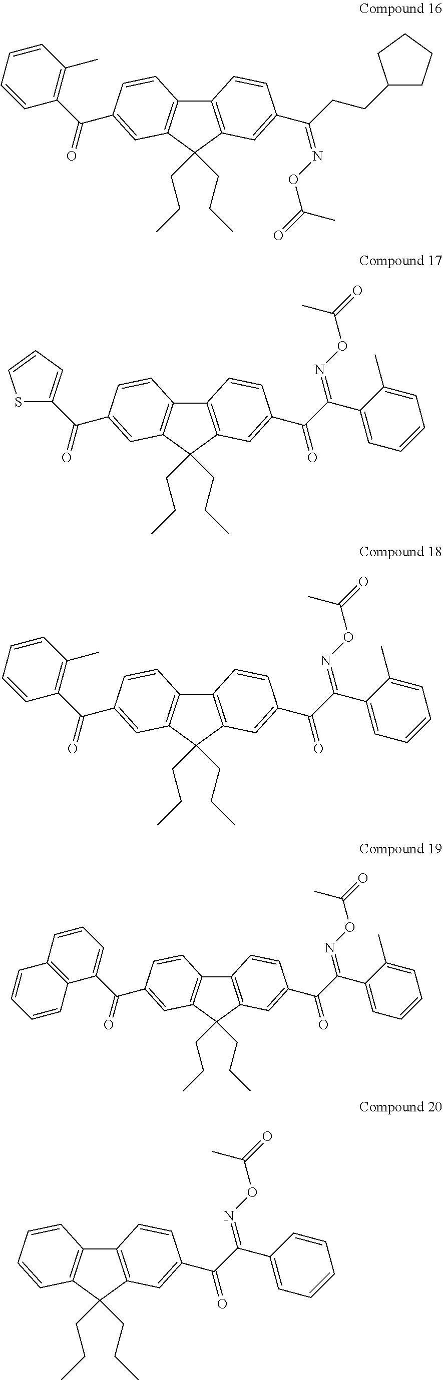 [SMILES: CCCC1(CCC)c2cc(C(=O)c3ccccc3C)ccc2-c2ccc(/C(CCC3CCCC3)=N\OC(C)=O)cc21 ; CCCC1(CCC)c2cc(C(=O)/C(=N/OC(C)=O)c3ccccc3C)ccc2-c2ccc(C(=O)c3cccs3)cc21 ; CCCC1(CCC)c2cc(C(=O)/C(=N/OC(C)=O)c3ccccc3C)ccc2-c2ccc(C(=O)c3ccccc3C)cc21 ; CCCC1(CCC)c2cc(C(=O)/C(=N/OC(C)=O)c3ccccc3C)ccc2-c2ccc(C(=O)c3cccc4ccccc34)cc21 ; CCCC1(CCC)c2ccccc2-c2ccc(C(=O)/C(=N/OC(C)=O)c3ccccc3)cc21]

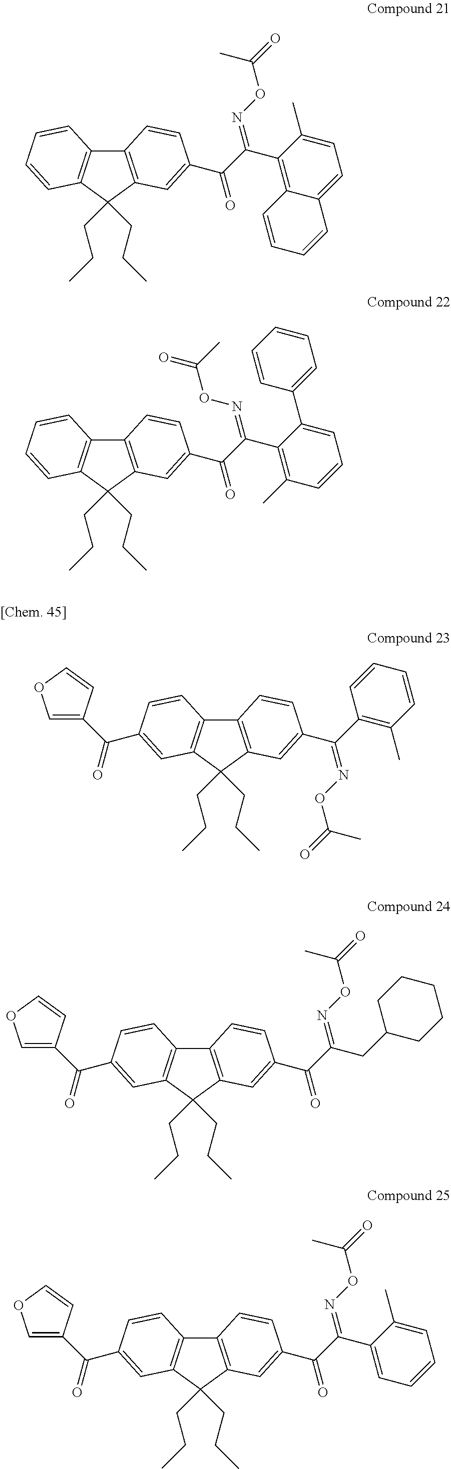 [SMILES: CCCC1(CCC)c2ccccc2-c2ccc(C(=O)/C(=N/OC(C)=O)c3c(C)ccc4ccccc34)cc21 ; CCCC1(CCC)c2ccccc2-c2ccc(C(=O)/C(=N\OC(C)=O)c3c(C)cccc3-c3ccccc3)cc21 ; CCCC1(CCC)c2cc(C(=O)c3ccoc3)ccc2-c2ccc(/C(=N\OC(C)=O)c3ccccc3C)cc21 ; CCCC1(CCC)c2cc(C(=O)/C(CC3CCCCC3)=N/OC(C)=O)ccc2-c2ccc(C(=O)c3ccoc3)cc21 ; CCCC1(CCC)c2cc(C(=O)/C(=N/OC(C)=O)c3ccccc3C)ccc2-c2ccc(C(=O)c3ccoc3)cc21]

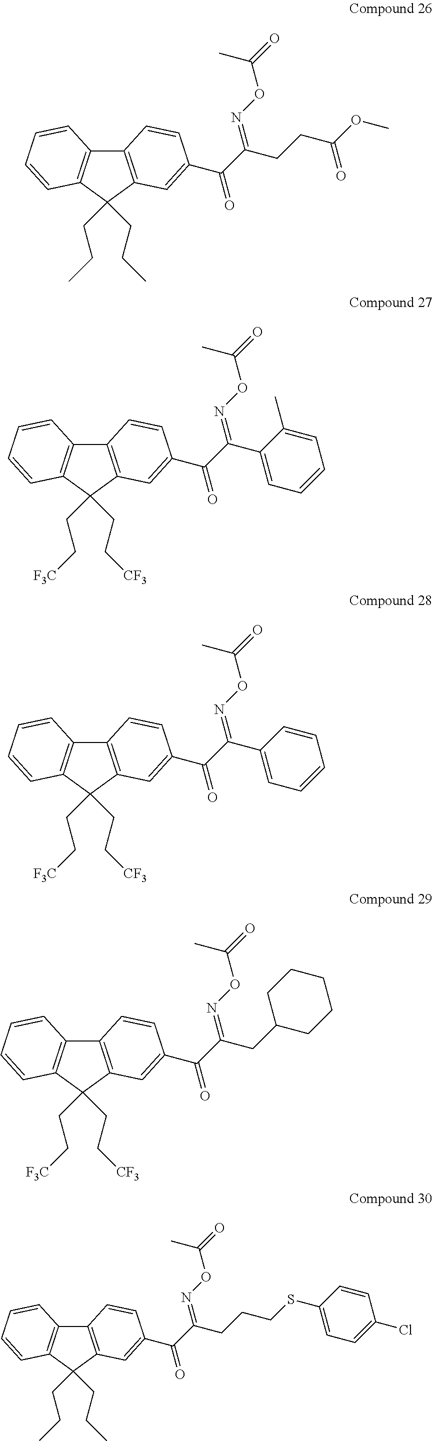 [SMILES: CCCC1(CCC)c2ccccc2-c2ccc(C(=O)/C(CCC(=O)OC)=N/OC(C)=O)cc21 ; CC(=O)O/N=C(/C(=O)c1ccc2c(c1)C(CCC(F)(F)F)(CCC(F)(F)F)c1ccccc1-2)c1ccccc1C ; CC(=O)O/N=C(/C(=O)c1ccc2c(c1)C(CCC(F)(F)F)(CCC(F)(F)F)c1ccccc1-2)c1ccccc1 ; CC(=O)O/N=C(\CC1CCCCC1)C(=O)c1ccc2c(c1)C(CCC(F)(F)F)(CCC(F)(F)F)c1ccccc1-2 ; CCCC1(CCC)c2ccccc2-c2ccc(C(=O)/C(CCCSc3ccc(Cl)cc3)=N/OC(C)=O)cc21]

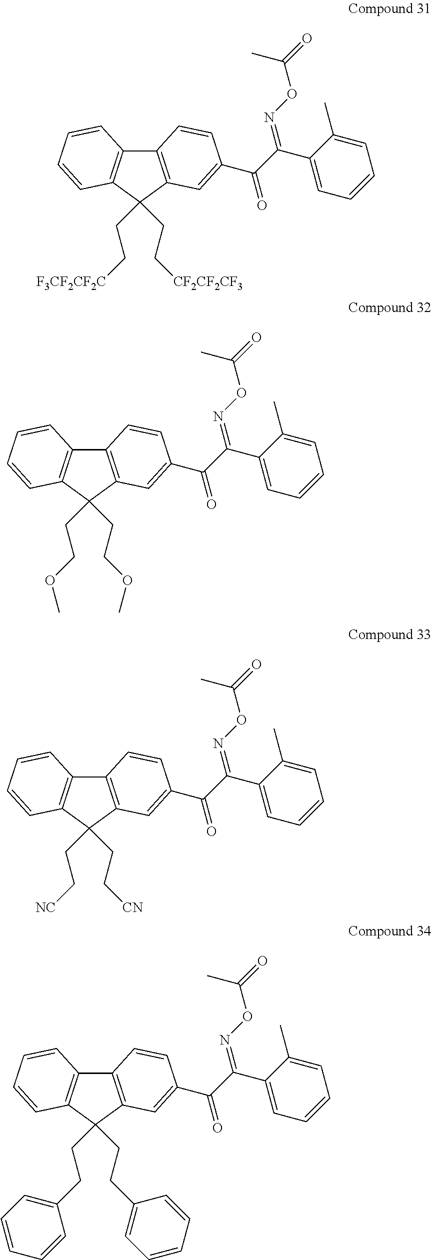

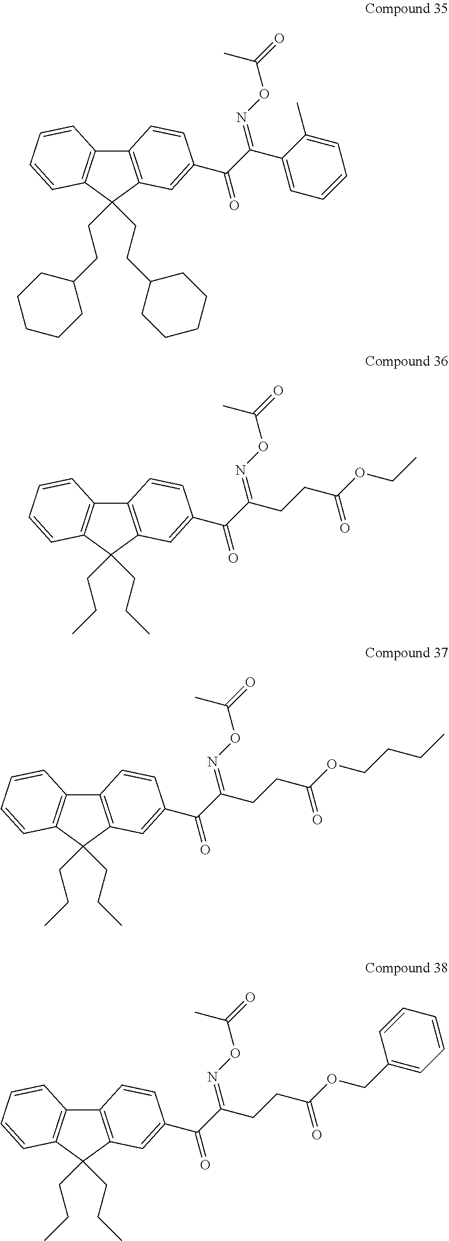 [SMILES: CC(=O)O/N=C(/C(=O)c1ccc2c(c1)C(CCC1CCCCC1)(CCC1CCCCC1)c1ccccc1-2)c1ccccc1C ; CCCC1(CCC)c2ccccc2-c2ccc(C(=O)/C(CCC(=O)OCC)=N/OC(C)=O)cc21 ; CCCCOC(=O)CC/C(=N\OC(C)=O)C(=O)c1ccc2c(c1)C(CCC)(CCC)c1ccccc1-2 ; CCCC1(CCC)c2ccccc2-c2ccc(C(=O)/C(CCC(=O)OCc3ccccc3)=N/OC(C)=O)cc21]

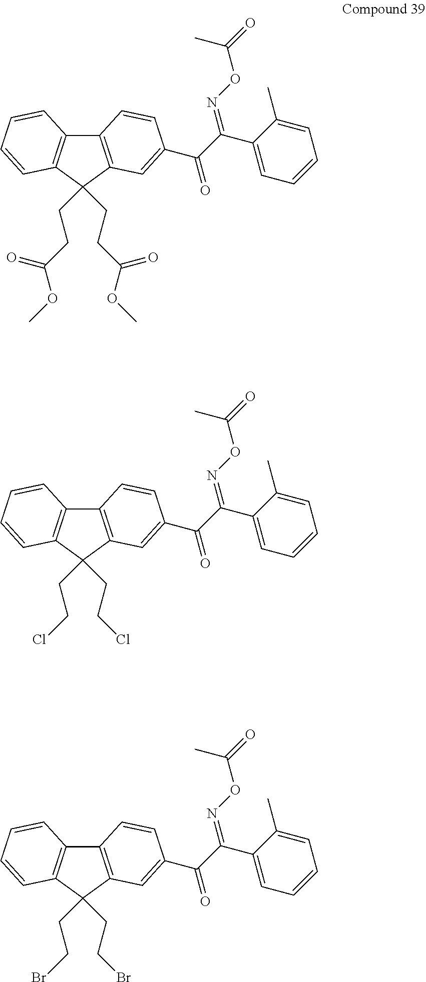 [SMILES: COC(=O)CCC1(CCC(=O)OC)c2ccccc2-c2ccc(C(=O)/C(=N/OC(C)=O)c3ccccc3C)cc21 ; CC(=O)O/N=C(/C(=O)c1ccc2c(c1)C(CCCl)(CCCl)c1ccccc1-2)c1ccccc1C ; CC(=O)O/N=C(/C(=O)c1ccc2c(c1)C(CCBr)(CCBr)c1ccccc1-2)c1ccccc1C]

The curing agent (D4) in the composition may contain two or more curing agents in different categories or of different types. Typically, the content of the curing agent (D4) in the composition is preferably 0.01% by mass or more and 40% by mass or less, more preferably 0.1% by mass or more and 20% by mass or less, and particularly preferably 1% by mass or more and 10% by mass or less relative to the mass of the solid content of the composition.

### [Solvent (5)]

The solvent (S) is a solvent contained in the composition for producing the quantum dot-containing film. The Solvent (S) includes an organic solvent (S1) comprising a chalcogen element. The chalcogen elements are as described for chalcogenides with respect to quantum dots (A).

### (Organic Solvent (S1))

The organic solvent (S1) is an organic compound comprising a chalcogen element. Examples of the compound comprising the chalcogen element include a sulfur-containing compound, a selenium-containing compound and a tellurium-containing compound. Among these, the sulfur-containing compound and the selenium-containing compound are preferable, and the sulfur-containing compound is more preferable from the viewpoints of easy availability and low cost.

When the organic solvent (S1) is present as an organic solvent (S1) with a relatively low molecular weight, the organic solvent (S1) is more likely to exert the desired effect on the quantum dots (A). For this reason, it is preferable that the composition for producing the quantum dot-containing film does not contain compounds that can polymerize with the organic solvent (S1) by condensation, addition, or cross-linking reactions. The composition for producing the quantum dot-containing films, which do not contain compounds that can polymerize with organic solvents (S1), also have excellent stability during storage.

For example, the sulfur-containing compound such as a thiol compound, a sulfide compound, a disulfide compound, a thiophene compound, a sulfoxide compound, a sulfone compound, a thioketone compound, a sulfonic acid compound, a sulfonic acid ester compound, a sulfonic acid amide compound, and the like can be used as the sulfur-containing compound which is the organic solvent (S1). In view of excellent affinity for the surface of the quantum dots (A) and easily obtaining desired effect of using an organic solvent (S1), among the sulfur-containing compounds described above, the thiol compound, the sulfide compound, and the disulfide compound are preferred.

For example, a selenol compound, a selenide compound, a diselenide compound, a selenoxide compound, a selenone compound and the like can be used as the selenium-containing compound as the organic solvent (S1). In view of excellent affinity for the surface of the quantum dots (A) and easily obtaining desired effect of using an organic solvent (S1), among the selenium-containing compounds described above, the selenol compound, the selenide compound, and the diselenide compound are preferred.

For example, a tellurol compound, a telluride compound, and a ditelluride compound can be used as the tellurium-containing compound as the organic solvent (S1).

Specific examples of the sulfur-containing compound as the organic solvent (S1) will now be described.

For example, suitable thiol compounds as the organic solvent (S1) are exemplified by compounds represented by the following formula (s01).

R^{s01}—SH (s01)

In the formula (s01), R^{s01} represents an optionally substituted monovalent hydrocarbon group.

Suitable examples of the monovalent hydrocarbon group as R^{s01} include an optionally substituted alkyl group, an optionally substituted cycloalkyl group, an optionally substituted alkenyl group, an optionally substituted aryl group, an optionally substituted aralkyl group, and an optionally substituted alkylaryl group. The number of carbon atoms in the optionally substituted alkyl group is preferably 1 or more and 20 or less, more preferably 1 or more and 10 or less, and further preferably 1 or more and 6 or less. The number of carbon atoms in the optionally substituted cycloalkyl group is preferably 3 or more and 20 or less, more preferably 3 or more and 10 or less, and further preferably 3 or more and 8 or less. The number of carbon atoms in the optionally substituted alkenyl group is preferably 2 or more and 20 or less, more preferably 2 or more and 10 or less, and further preferably 2 or more and 6 or less. The number of carbon atoms in the optionally substituted aryl group is preferably 6 or more and 20 or less, more preferably 6 or more and 10 or less, and further preferably 6 or more and 8 or less. The number of carbon atoms in the optionally substituted aralkyl group is preferably 7 or more and 20 or less, more preferably 7 or more and 12 or less, and further preferably 7 or 8. The number of carbon atoms in the optionally substituted alkylaryl group is preferably 7 or more and 20 or less, more preferably 7 or more and 12 or less, and further preferably 7 or 8. Examples of optional substituents on these hydrocarbon groups include hydroxy group, thiol group, carboxy group, halogen atom, amino group, and the like. The number of substituents on the hydrocarbon group may be 2 or more.

Specific examples of thiol compounds include aliphatic thiol compounds such as thioglycerol, 2-mercaptoethanol, thioglycolic acid, 2,3-dimercapto-1-propanol, 1-propanethiol, 2-propanethiol, 2-methyl-2-propanethiol, 1,2-ethanedithiol, cyclohexanethiol, and 1-octanethiol, and aromatic thiol compounds such as thiophenol, p-toluenethiol, and aminobenzenethiol, and the like.

Suitable sulfide compounds as the organic solvent (S1) are exemplified by compounds represented by the following formula (s02).

R^{s02}—S—R^{s02} (s02)

In the formula (s02), R^{s02} represents an optionally substituted monovalent hydrocarbon group. Suitable examples of the monovalent hydrocarbon group as R^{s02} are same as suitable examples of the monovalent hydrocarbon group as R^{s01}. Specific examples of sulfide compounds include dimethylsulfide, diethylsulfide, di-n-propylsulfide, ethylmethylsulfide, thioanisole, ethylthiobenzene, diphenylsulfide, dibenzylsulfide, and the like.

Suitable disulfide compounds as the organic solvent (S1) are exemplified by compounds represented by the following formula (s03).

R^{s03}—S—S—Rₛ₀₃ (s03)

In the formula (s03), R^{s03} represents an optionally substituted monovalent hydrocarbon group. Suitable examples of the monovalent hydrocarbon group as R^{s03} are same as suitable examples of the monovalent hydrocarbon group as R^{s01}. Specific examples of disulfide compounds include dialkyldisulfides having linear or branched alkyl groups having 1 or more and 10 or less carbon atoms. Such dialkyl disulfides include dimethyldisulfide, diethyldisulfide, di-n-propyl disulfide, diisopropyldisulfide, di-n-butyldisulfide, di-n-pentyldisulfide, and di-n-hexyl disulfide. Suitable examples of disulfide compounds other than those described above include diallyldisulfide, cyclohexyldisulfide, diphenyldisulfide, dibenzyldisulfide, di(p-tolyl)disulfide, 4,4′-dichlorodiphenyldisulfide, di(3,4-dichlorophenyl)disulfide, 2,2′-dithiobis(5-chloroaniline), di(2,4-xylyl)disulfide, and di(2,4-dichlorophenyl)disulfide. dichlorodiphenyldisulfide, di(3,4-dichlorophenyl)disulfide, 2,2′-dithiobis(5-chloroaniline), di(2,4-xylyl) disulfide, di(2,3-xylyl)disulfide, di(3,5-xylyl)disulfide, 2,4-xylyl-2,6-xylyldisulfide, 2,2′-dithiosalicylic acid, and 2,2′-dithiobis(4-tert-butylphenol).

For example, an ester compound in which an aliphatic polyhydric alcohol and an aliphatic carboxylic acid having a mercapto group and/or a selenol group is preferred as the organic solvent (S1). Such compounds have an ester bond, a mercapto group, and/or a selenol group. Due to the presence of these bonds or functional groups, the organic solvent (S1) has excellent affinity for the surface of the quantum dot (A). Therefore, when the above ester compound is used as the organic solvent (S1), it is easy to obtain the desired effect of the organic solvent (S1).

Specific examples of the aliphatic polyhydric alcohol include ethyleneglycol, diethyleneglycol, triethyleneglycol, propyleneglycol, dipropyleneglycol, tripropyleneglycol, glycerin, trimethylolpropane, pentaerythritol, dipentaerythritol, sorbitol, mannitol, sorbitan, diglycerine, sucrose, glucose, mannose, fructose, methyl glucoside and the like.

Suitable examples of the aliphatic carboxylic acid include a thioglycolic acid and a 3-mercaptopropionic acid.

Preferable examples of ester compounds described above include ethyleneglycol di-3-mercaptopropionate, diethyleneglycol di-3-mercaptopropionate, propyleneglycol di-3-mercaptopropionate, dipropyleneglycol di-3-mercaptopropionate, glycerin tri-3-mercaptopropionate, trimethylolpropane tri-3-mercaptopropionate (TMMP) and pentaerythritol tetra-3-mercaptopropionate (PEMP).

The boiling point of the organic solvent (S1) described above under atmospheric pressure is preferably 60° C. or higher and 400° C. or lower, more preferably 80° C. or higher and 350° C. or lower, and further preferably 100° C. or more and 300° C. or less. When the organic solvent (S1) having a boiling point within such a range is used, it is easy to prepare the solid concentration of the composition by condensation, etc., or to remove excess organic solvent (S1) when a film is produced by using the composition.

A content of the organic solvent (S1) in the composition is not particularly limited as long as the desired effect is obtained. Amount of the organic solvent (S1) in the composition is preferably 10 parts by mass or more and 2000 parts by mass or less, more preferably 10 parts by mass or more and 1500 parts by mass or less, further preferably 30 parts by mass or more and 1200 parts by mass or less, and especially preferably 50 parts by mass or more and 1000 parts by mass or less relative to 100 parts by mass of the quantum dots (A).

The ratio of the mass of the organic solvent (S1) to the total mass of the solvent (S) is not particularly limited. The ratio of the mass of the organic solvent (S1) to the total mass of the solvent (S) is preferably 50% by mass or more, more preferably 70% by mass or more, further preferably 80% by mass or more, particularly preferably 90% by mass or more, and most preferably 100% by mass, from the view point of easily obtaining the desired effect of using the organic solvent (S1). In addition, ratio of the mass of the organic solvent (S1) to the total mass of the composition for producing the quantum dot-containing film is preferably 50% by mass or more, more preferably 70% by mass or more, and further preferably 80% by mass or more, from the view point of easily obtaining the desired effect of using the organic solvent (S1). Ratio of the mass of the organic solvent (S1) to the total mass of the composition for producing the quantum dot-containing film may be 90% by mass or more, or 95% by mass or more.

### (Organic Solvent (S2))

The solvent (S) may include an organic solvent (S2), which is a solvent other than organic solvent (S1), along with the above organic solvent (S1) as long as it does not interfere with the purpose of the invention.

From the viewpoint of dispersion stabilization of the quantum dots (A), an organic solvent (S2a) which is a compound having a cyclic skeleton and including a heteroatom other than a hydrogen atom, a carbon atom, and an atom of the chalcogen element is preferable as the organic solvent (S2). The organic solvent (S2a) including a heteroatom is not a hydrocarbon solvent as described above. Examples of heteroatoms which can be included in the organic solvent (S2a) include N, O, P and the like.

It is unclear why the use of the organic solvent (S2a) is effective in promoting and stabilizing the dispersion of quantum dots (A). For example, it is assumed that a cyclic skeleton of the organic solvent (S2a) has the effect of inhibiting the aggregation of quantum dots (A).

As for a cyclic skeleton of the organic solvent (S2a), an alicyclic skeleton is preferred. Herein, a cyclic skeleton which exhibits no aromaticity is deemed as an alicyclic skeleton. In addition, in the case in which the organic solvent (S2a) has both an aromatic ring skeleton and an alicyclic skeleton like a tetralin ring, the solvent (S2a) is deemed as having an alicyclic skeleton. It is inferred that greater bulkiness of the alicyclic skeleton to some extent than the aromatic ring skeleton, which has a planar steric structure, favorably contributes to promoting dispersion of the quantum dots (A) and the stabilization of the dispersion, although the reasons therefor are unclear.

The organic solvent (S2a) preferably has at least one type of bond selected from the group consisting of an ester bond (—CO—O—), an amide bond (—CO—NH—), a carbonate bond (—O—CO—O—), a ureido bond (—NH—CO—NH—), and a urethane bond (—O—CO—NH—). In the present description, when the ester bond and the amide bond are simply referred to, the ester bond and the amide bond respectively mean a “carboxylic acid ester bond” and a “carboxylic acid amide bond”. In the amide bond, the ureido bond, and the urethane bond, an organic group may be bonded to a nitrogen atom. The type of the organic group is not particularly limited. The organic group is preferably an alkyl group, more preferably an alkyl group having 1 or more and 6 or less carbon atoms, and further preferably a methyl group or an ethyl group. In addition, in the case in which the organic solvent (S2a) includes any of these bonds, a resin component and a monomer component are likely to be favorably dissolved in the composition for producing the quantum dot-containing film.

Preferred examples of the organic solvent (S2a) include: aromatic solvents such as anisole, phenetole, propyl phenyl ether, butyl phenyl ether, cresyl methyl ether, ethyl benzyl ether, diphenyl ether, dibenzyl ether, acetophenone, propiophenone, benzophenone, pyridine, pyrimidine, pyrazine, and pyridazine; alicyclic alcohols such as cyclopentanol, cyclohexanol, 1,4-cyclohexanediol, 1,3-cyclohexanediol, 1,4-cyclohexanedimethanol, and 1,3-cyclohexanedimethanol; alicyclic ethers such as cyclohexyl methyl ether, cyclohexyl ethyl ether, tetrahydrofuran, tetrahydropyran, and dioxane; alicyclic ketones such as cyclopentanone, cyclohexanone, cycloheptanone, 2-methylcyclohexanone, 1,4-cyclopentanedione, and 1,3-cyclopentanedione; lactones such as β-propiolactone, γ-butyrolactone, β-methyl-γ-butyrolactone, δ-valerolactone, ε-valerolactone, ε-caprolactone, α-methyl-ε-caprolactone, and ε-methyl-ε-caprolactone; cyclic amides or cyclic ureas such as N-methyl-2-pyrrolidone, N-ethyl-2-pyrrolidone, 1,3-dimethyl-2-imidazolidinone, and N,N-dimethylpropyleneurea; cyclic carbonate such as ethylene carbonate, and propylene carbonate; and the like.

In addition, as the solvent (S2a), a cycloalkyl ester of carboxylic acid is preferable. The cycloalkyl ester of carboxylic acid is preferably a cycloalkyl ester of carboxylic acid represented by the following formula (s1):

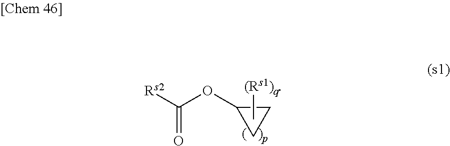

in which in the formula (S1), R^{s1} represents an alkyl group having 1 or more and 3 or less carbon atoms; R^{s2} represents an alkyl group having 1 or more and 6 or less carbon atoms; p is an integer of 1 or more and 6 or less; and q is an integer of 0 or more and (p+1) or less.

R^{s1} in the formula (s1) is exemplified by a methyl group, an ethyl group, an n-propyl group, and an isopropyl group, and is preferably a methyl group. R^{s2} in the formula (s1) is exemplified by a methyl group, an ethyl group, an n-propyl group, an isopropyl group, an n-butyl group, an isobutyl group, a sec-butyl group, a tert-butyl group, an n-pentyl group, and an n-hexyl group. As the alkyl group represented by R^{s2}, a methyl group, an ethyl group, an n-propyl group, an isopropyl group, and an n-butyl group, are preferable, and a methyl group and an ethyl group are more preferable.

Preferred examples of the carboxylic acid cycloalkyl ester represented by the formula (s1) include cyclopropyl acetate, cyclobutyl acetate, cyclopentyl acetate, cyclohexyl acetate, cycloheptyl acetate, cyclooctyl acetate, cyclopropyl propionate, cyclobutyl propionate, cyclopentyl propionate, cyclohexyl propionate, cycloheptyl propionate, and cyclooctyl propionate. Among these, cyclopentyl acetate and cyclohexyl acetate are preferable, since they are readily available and have a preferable boiling point.

Among the organic solvents (S2a) described above, the carboxylic acid cycloalkyl ester represented by the formula (s1) is preferable, and cyclopentyl acetate and cyclohexyl acetate are particularly preferable.

Examples of the organic solvent (S2) other than examples of the organic solvent (s2a) include: alcohols such as methanol, ethanol, propanol and n-butanol; polyhydric alcohols such as ethylene glycol, diethylene glycol, propylene glycol and dipropylene glycol; ketones such as acetone, methyl ethyl ketone, methyl n-amyl ketone, methyl isoamyl ketone and 2-heptanone; compounds having an ester bond such as ethylene glycol monoacetate, diethylene glycol monoacetate, propylene glycol monoacetate, or dipropylene glycol monoacetate; ether derivatives such as monomethyl ethers, monoethyl ethers, monopropyl ethers, monobutyl ethers, monophenyl ethers or the like of the polyhydric alcohols or the compounds having an ester bond; esters such as methyl lactate, ethyl lactate, methyl acetate, ethyl acetate, butyl acetate, methyl pyruvate, ethyl pyruvate, methyl methoxypropionate and ethyl ethoxypropionate; aliphatic hydrocarbon organic solvents such as pentane, hexane, heptane and octane; aromatic organic solvents such as ethylbenzene, diethylbenzene, amylbenzene, isopropylbenzene, toluene, xylene, cymene and mesitylene; nitrogen-containing organic solvents such as N,N,N′,N′-tetramethylurea, N,N,2-trimethylpropionamide, N,N-dimethylacetamide, N,N-dimethylformamide, N,N-diethylacetamide, N,N-diethylformamide and N-ethylpyrrolidone. Two or more of these organic solvents may be used in combination.

Amount of the solvent (S) is not particularly limited as long as sufficient amount of the organic solvent (S1) to obtain desired effect is included in the solvent (S). Amount of the solvent (S) is preferably an amount in which the concentration of quantum dots (A) in the composition for producing the quantum dot-containing film is 0.1% by mass or more and 70% by mass or less, more preferably an amount of 1% by mass or more and 60% by mass or less, and further preferably an amount of 5% by mass or more and 50% by mass or less.

### <Other Component>

The composition may include other component than the quantum dots (A), the base component (C), the curing agent (D) and the solvent (S), as long as the objects of the present invention are not inhibited. Other component is exemplified by a silane coupling agent, an adhesion enhancer, a dispersant, a surfactant, an ultraviolet ray-absorbing agent, an antioxidant, an antifoaming agent, a viscosity modifier, a resin, rubber particles, a colorant, and the like. Moreover, in the case in which the composition includes the rubber particles, elasticity is imparted to the formed quantum dot-containing film, and thereby the brittleness of the quantum dot-containing film is likely to be eliminated.

In view of promoting and stabilizing dispersion of quantum dots (A), the composition preferably includes an ionic liquid (I). When the composition includes the ionic liquid (I), the composition preferably includes the ionic liquid (I) in combination with the organic solvent (S2a) described above. When the composition for producing the quantum dot-containing film includes the ionic liquid (I) in combination with the organic solvent (S2a), effects of promoting and stabilizing dispersion of quantum dots (A) are more easily enhanced.

As the ionic liquid (I), ionic liquids that are used in the field of organic synthesis and in electrolytes for batteries etc. can be used without any particular limitation. The ionic liquid (I) is typically a salt capable of being molten in a temperature region of 140° C. or lower, and is preferably a stable salt that is liquid at 140° C. or lower.

The melting point of the ionic liquid (I) is preferably 120° C. or lower, more preferably 100° C. or lower, and even more preferably 80° C. or lower from the viewpoint of, for example, more reliable achievement of desired effects of and the handleability of the ionic liquid (I) and the composition for producing the quantum dot-containing film.

The ionic liquid (I) is preferably composed of an organic cation and an anion. The ionic liquid (I) is preferably composed of a nitrogen-containing organic cation, a phosphorus-containing organic cation, or a sulfur-containing organic cation, and a counteranion, and more preferably of a nitrogen-containing organic cation or a phosphorus-containing organic cation, and a counteranion.

As the organic cation constituting the ionic liquid (I), at least one selected from the group consisting of an alkyl chain quaternary ammonium cation, a piperidinium cation, a pyrimidinium cation, a pyrrolidinium cation, an imidazolium cation, a pyridinium cation, a pyrazolium cation, a guanidinium cation, a morpholinium cation, a phosphonium cation and a sulfonium cation is preferable, and an alkyl chain quaternary ammonium cation, a piperidinium cation, a pyrrolidinium cation, an imidazolium cation, a morpholinium cation, or a phosphonium cation is more preferable in light of e.g. their favorable affinity for the solvent (S), and a pyrrolidinium cation, an imidazolium cation, or a phosphonium cation is even more preferable from the viewpoint that the effects of the invention are particularly likely to be achieved.

Specific examples of the alkyl chain quaternary ammonium cation include a quaternary ammonium cation represented by the following formula (L1). More specifically, the alkyl chain quaternary ammonium cation is exemplified by, for example, a tetramethylammonium cation, an ethyltrimethylammonium cation, a diethyldimethylammonium cation, a triethylmethylammonium cation, a tetraethylammonium cation, a methyltributylammonium cation, an octyltrimethylammonium cation, a hexyltrimethylammonium cation, a methyltrioctylammonium cation, and the like. Specific examples of the piperidinium cation include a piperidinium cation represented by the following formula (L2). More specifically, the piperidinium cation is exemplified by, for example, a 1-propylpiperidinium cation, a 1-pentylpiperidinium cation, a 1,1-dimethylpiperidinium cation, a 1-methyl-1-ethylpiperidinium cation, a 1-methyl-1-propylpiperidinium cation, a 1-methyl-1-butylpiperidinium cation, a 1-methyl-1-pentylpiperidinium cation, a 1-methyl-1-hexylpiperidinium cation, a 1-methyl-1-heptylpiperidinium cation, a 1-ethyl-1-propylpiperidinium cation, a 1-ethyl-1-butylpiperidinium cation, a 1-ethyl-1-pentylpiperidinium cation, a 1-ethyl-1-hexylpiperidinium cation, a 1-ethyl-1-heptylpiperidinium cation, a 1,1-dipropylpiperidinium cation, a 1-propyl-1-butylpiperidinium cation, a 1,1-dibutylpiperidinium cation, and the like. Specific examples of the pyrimidinium cation include a 1,3-dimethyl-1,4,5,6-tetrahydropyrimidinium cation, a 1,2,3-trimethyl-1,4,5,6-tetrahydropyrimidinium cation, a 1,2,3,4-tetramethyl-1,4,5,6-tetrahydropyrimidinium cation, a 1,2,3,5-tetramethyl-1,4,5,6-tetrahydropyrimidinium cation, a 1,3-dimethyl-1,4-dihydropyrimidinium cation, a 1,3-dimethyl-1,6-dihydropyrimidinium cation, a 1,2,3-trimethyl-1,4-dihydropyrimidinium cation, a 1,2,3-trimethyl-1,6-dihydropyrimidinium cation, a 1,2,3,4-tetramethyl-1,4-dihydropyrimidinium cation, a 1,2,3,4-tetramethyl-1,6-dihydropyrimidinium cation, and the like.

Specific examples of the pyrrolidinium cation include a pyrrolidinium cation represented by the following formula (L3), and more specifically, a 1,1-dimethylpyrrolidinium cation, a 1-ethyl-1-methylpyrrolidinium cation, a 1-methyl-1-propylpyrrolidinium cation, a 1-methyl-1-butylpyrrolidinium cation, a 1-methyl-1-pentylpyrrolidinium cation, a 1-methyl-1-hexylpyrrolidinium cation, a 1-methyl-1-heptylpyrrolidinium cation, a 1-ethyl-1-propylpyrrolidinium cation, a 1-ethyl-1-butylpyrrolidinium cation, a 1-ethyl-1-pentylpyrrolidinium cation, a 1-ethyl-1-hexylpyrrolidinium cation, a 1-ethyl-1-heptylpyrrolidinium cation, a 1,1-dipropylpyrrolidinium cation, a 1-propyl-1-butylpyrrolidinium cation, a 1,1-dibutylpyrrolidinium cation, and the like. Specific examples of the imidazolium cation include an imidazolium cation represented by the following formula (L5), and more specifically, a 1,3-dimethylimidazolium cation, a 1,3-diethylimidazolium cation, a 1-ethyl-3-methylimidazolium cation, a 1-propyl-3-methylimidazolium cation, a 1-butyl-3-methylimidazolium cation, a 1-hexyl-3-methylimidazolium cation, a 1-octyl-3-methylimidazolium cation, a 1-decyl-3-methylimidazolium cation, a 1-dodecyl-3-methylimidazolium cation, a 1-tetradecyl-3-methylimidazolium cation, a 1,2-dimethyl-3-propylimidazolium cation, a 1-ethyl-2,3-dimethylimidazolium cation, a 1-butyl-2,3-dimethylimidazolium cation, a 1-hexyl-2,3-dimethylimidazolium cation, and the like. Specific examples of the pyridinium cation include a pyridinium cation represented by the following formula (L6), and more specifically, a 1-ethylpyridinium cation, a 1-butylpyridinium cation, a 1-hexylpyridinium cation, a 1-butyl-3-methylpyridinium cation, a 1-butyl-4-methylpyridinium cation, a 1-hexyl-3-methylpyridinium cation, a 1-butyl-3,4-dimethylpyridinium cation, and the like.

Specific examples of the pyrazolium cation include a 1,3-dimethyl-1,4,5,6-tetrahydropyrimidinium cation, a 1,2,3-trimethyl-1,4,5,6-tetrahydropyrimidinium cation, a 1,2,3,4-tetramethyl-1,4,5,6-tetrahydropyrimidinium cation, a 1,2,3,5-tetramethyl-1,4,5,6-tetrahydropyrimidinium cation, a 1,3-dimethyl-1,4-dihydropyrimidinium cation, a 1,3-dimethyl-1,6-dihydropyrimidinium cation, a 1,2,3-trimethyl-1,4-dihydropyrimidinium cation, a 1,2,3-trimethyl-1,6-dihydropyrimidinium cation, a 1,2,3,4-tetramethyl-1,4-dihydropyrimidinium cation, a 1,2,3,4-tetramethyl-1,6-dihydropyrimidinium cation, and the like.

Specific examples of the phosphonium cation include a phosphonium cation represented by the following formula (L4). More specifically, the phosphonium cation is exemplified by tetraalkylphosphonium cations such as a tetrabutylphosphonium cation, a tributylmethylphosphonium cation, and a tributylhexylphosphonium cation, and a triethyl(methoxymethyl)phosphonium cation, and the like. Specific examples of the sulfonium cation include a triethylsulfonium cation, a dimethylethylsulfonium cation, a triethylsulfonium cation, an ethylmethylpropylsulfonium cation, a butyldimethylsulfonium cation, a 1-methyltetrahydrothiophenium cation, a 1-ethyltetrahydrothiophenium cation, a 1-propyltetrahydrothiophenium cation, a 1-butyltetrahydrothiophenium cation, or a 1-methyl-[1,4]-thioxonium cation, and the like. Among these, as the sulfonium cation, a sulfonium cation having a cyclic structure such as a tetrahydrothiophenium-based or hexahydrothiopyrylium-based 5-membered ring or 6-membered ring is preferable, and the sulfonium cation may have a heteroatom such as an oxygen atom in the cyclic structure.

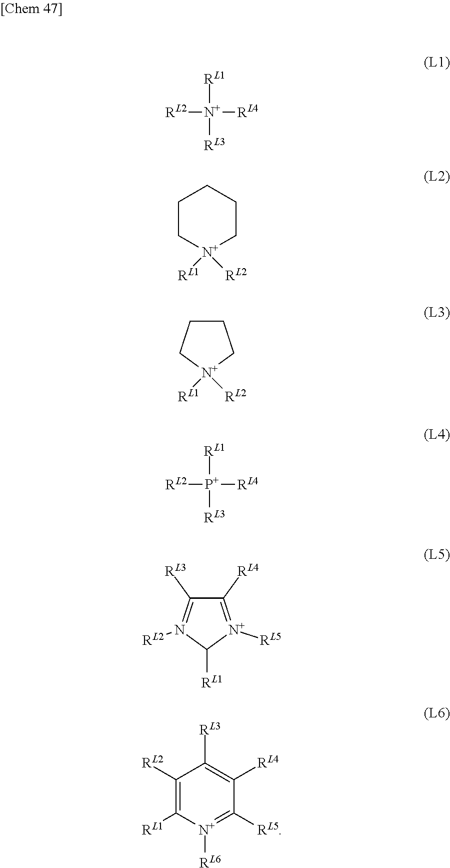

In the formulas (L1) to (L4), R^{L1} to R^{L4} each independently represent an alkyl group having 1 or more and 20 or less carbon atoms, or an alkoxyalkyl group represented by R^{L7}—O—(CH₂)_{Ln}— (wherein, R^{L7} represents a methyl group or an ethyl group, and Ln is an integer of 1 or more and 4 or less). In the formula (L5), R^{L1} to R^{L4} each independently represent an alkyl group having 1 or more and 20 or less carbon atoms, an alkoxyalkyl group represented by R^{L7}—O—(CH₂)_{Ln}— (wherein, R^{L7} represents a methyl group or an ethyl group, and Ln is an integer of 1 or more and 4 or less), or a hydrogen atom. In the formula (L6), R^{L1} to R^{L6} each independently represent an alkyl group having 1 or more and 20 or less carbon atoms, an alkoxyalkyl group represented by R^{L7}—O—(CH₂)_{Ln}— (wherein, R^{L7} represents a methyl group or an ethyl group, and Ln is an integer of 1 or more and 4 or less), or a hydrogen atom.

The anion constituting the ionic liquid (I) may be an organic anion or an inorganic anion. Since the ionic liquid (I) has good affinity for the solvent (S), the organic anion is preferred. The organic anion is preferably at least one selected from the group consisting of a carboxylic acid-based anion, an N-acylamino acid ion, an acidic amino acid anion, a neutral amino acid anion, an alkyl sulfuric acid-based anion, a fluorine-containing compound-based anion and a phenol-based anion, more preferably a carboxylic acid-based anion or an N-acylamino acid ion.

Specific examples of the carboxylic acid-based anion include an acetate ion, a decanoate ion, a 2-pyrrolidone-5-carboxylate ion, a formate ion, an α-lipoate ion, a lactate ion, a tartarate ion, a hippurate ion, an N-methylhippurate ion, and the like. Among these, an acetate ion, a 2-pyrrolidone-5-carboxylate ion, a formate ion, a lactate ion, a tartarate ion, a hippurate ion and an N-methylhippurate ion are preferable, and an acetate ion, an N-methylhippurate ion and a formate ion are more preferable. Specific examples of the carboxylic acid-based anion include an acetate ion, a decanoate ion, a 2-pyrrolidone-5-carboxylate ion, a formate ion, an α-lipoate ion, a lactate ion, a tartarate ion, a hippurate ion, an N-methylhippurate ion, and the like. Specific examples of the N-acylamino acid ion include an N-benzoylalanine ion, an N-acetylphenylalanine ion, an aspartate ion, a glycine ion, an N-acetylglycine ion, and the like, and among these, an N-benzoylalanine ion, an N-acetylphenylalanine ion and an N-acetylglycine ion are preferable, and an N-acetylglycine ion is more preferable. Specific examples of the acidic amino acid anion include an aspartate ion, a glutamate ion, and the like, and specific examples of the neutral amino acid anion include a glycine ion, an alanine ion, a phenylalanine ion, and the like.

Specific examples of the alkyl sulfuric acid-based anion include a methanesulfonate ion, and the like. Specific examples of the fluorine-containing compound-based anion include a trifluoromethanesulfonate ion, a hexafluorophosphonate ion, a trifluorotris(pentafluoroethyl)phosphonate ion, a bis(fluoroalkylsulfonyl)imide ion (for example, a bis(trifluoromethanesulfonyl)imide ion), a trifluoroacetate ion, a tetrafluoroborate ion, and the like. Specific examples of the phenol-based anion include a phenol ion, a 2-methoxyphenol ion, a 2,6-di-tert-butylphenol ion, and the like.

In view of achieving the effects of the invention more reliably, above inorganic anion is preferably at least one selected form the group consisting of F⁻, Cl⁻, Br⁻, I⁻, BF₄⁻, PF₆⁻, and N(SO₂F)₂⁻, more preferably BF₄⁻, PF₆⁻, or N(SO₂F)₂⁻, and further preferably BF₄⁻ or PF₆⁻.

The ionic liquid (I) can be produced by, for example, a procedure disclosed in paragraph 0045 of PCT International Publication No. 2014/178254, etc. The ionic liquid (I) can be used individually or two or more ionic liquids (I) can be used in combination. The content of the ionic liquid (I) relative to 100 parts by mass of the quantum dots (A) is preferably 10 parts by mass or more and 500 parts by mass or less, more preferably 90 parts by mass or more and 400 parts by mass or less, and even more preferably 100 parts by mass or more and 300 parts by mass or less from the viewpoint of a favorable effect of dispersion of the quantum dots (A) in the composition for producing the quantum dot-containing film.

### {Method for Producing the Composition}

A method for producing the composition described above is not particularly limited. The composition is not particularly limited as long as the quantum dots (A), the base component (C), and solvent (S) can be uniformly mixed with other optional components as needed. An order in which the various components included in the composition are mixed is not particularly limited.

In a production described above, during or after the production of the composition, it is preferable that the quantum dots (A) are heated to between 50° C. or higher and 300° C. or lower in the presence of organic solvent (S1). Heating temperature is preferably 70° C. or higher and 270° C. or lower, and more preferably 100° C. or higher and 250° C. or lower. By doing so, it is easy to produce the composition in which quantum dots (A) are well dispersed.

The preferred method of producing the composition is to mix the pre-prepared quantum dot dispersion with the other components. In this case, quantum dot dispersion includes the quantum dots (A) and a dispersion medium (B). An organic solvent same as the solvent (S) described above can be used as the dispersion medium (B). In addition, it is preferable that the dispersion medium (B) includes the organic solvent (S1) described above, from the view point of easily recovering the quantum yield of the quantum dot-containing film to the desired degree by the heating step under the low oxygen concentration atmosphere described above.

A method for producing the quantum dot dispersion includes dispersing the quantum dots (A) in the dispersion medium (B). Method for dispersing the quantum dots (A) in the dispersing medium (B) is not particularly limited. For example, the method for dispersing quantum dots (A) in the dispersion medium (B) may be a method of dispersing solid quantum dots (A) produced by a well-known method into the dispersion medium (B).

Preferred example of a method for dispersing the quantum dots (A) in the dispersion medium (B) include a method including:

preparing a preliminary dispersion containing the quantum dots (A) and a preliminary dispersion medium (pB); and replacing the preliminary dispersion medium (pB) contained in the preliminary dispersion with the dispersion medium (B).

Here, the preliminary dispersion is a preliminary dispersion used to prepare the quantum dot dispersion containing the quantum dots (A) and dispersion medium (B). Method for preparing the preliminary dispersion is not particularly limited. Commercially available quantum dot dispersion can be used as the preliminary dispersion. In addition, the preliminary dispersion can also be prepared by removing the preliminary dispersion (pB) from the commercially available quantum dot dispersion by volatilizing or other method, and then adding the dispersion medium (B) to the residue containing the quantum dots (A) to disperse the quantum dots (A).

As the preliminary dispersion medium (pB), the same type of solvent as the other solvents (S2) other than the organic solvent (S1), described for solvent (S), can be used.

Concentration of the quantum dots (A) in the preliminary dispersion is not particularly limited. Concentration of the quantum dots (A) in the preliminary dispersion or the quantum dot dispersion is preferably in an amount of 0.1% by mass or more and 70% by mass or less, more preferably in an amount of 1% by mass or more and 60% by mass or less, and further preferably in an amount of 5% by mass or more and 50% by mass or less.

Examples of preferred method to replace the preliminary dispersion medium (pB) in the preliminary dispersion with the dispersion medium (B) includes a method including:

removing at least a part of the preliminary dispersion medium (pB) from the preliminary dispersion, and adding the dispersion medium (B) to the mixture containing the quantum dots (A) and the remaining preliminary dispersion medium (pB), or quantum dots (A) after the preliminary dispersion medium (pB) has been removed.

Method of removing at least a part of the preliminary dispersion medium (pB) is not particularly limited. An example of such a method is to volatilize the preliminary dispersion medium (pB). Method of volatilizing the preliminary dispersion medium (pB) is not particularly limited. For example, volatilizing the preliminary dispersion medium (pB) is conducted by heating under atmospheric pressure or reduced pressure. For example, the preliminary dispersion medium (pB) may be removed, by a method in which the quantum dots (A) are allowed to settle in the vessel by means of centrifugal sinking or other methods, and then the preliminary dispersion medium (pB) is removed as supernatant.

Since it may be difficult to settle quantum dots (A) depending on the material and particle size of the quantum dots (A), as a method of removing at least a part of the preliminary dispersion medium (pB), removing the preliminary dispersion medium by volatilizing the preliminary dispersion medium (pB) is preferred.

When at least a part of the preliminary dispersion medium pB) is removed, an amount of the removed preliminary dispersion medium (pB) is not particularly limited as long as it does not interfere with the purpose of the invention. Amount of the removed preliminary dispersion medium (pB) may be 50% by mass or more, 70% by mass or more, 90% by mass or more, or 100% of the mass of the preliminary dispersion medium (pB) before removal.

After at least a part of the preliminary dispersion medium (pB) is removed in this manner, the dispersion medium (B) is added to the residue, and then the quantum dots (A) are dispersed in the dispersion medium (B) to prepare a quantum dot dispersion. The amount of the dispersion medium (B) used is not particularly limited. As described above, amount of dispersion medium (B) used is an amount where the content of the organic solvent (B1) in the quantum dot dispersion is preferably 10 parts by mass or more and 2000 parts by mass or less, more preferably 10 parts by mass or more and 1500 parts by mass or less, even more preferably 30 parts by mass or more and 1200 parts by mass or less, and especially preferably 50 parts by mass or more and 1000 parts by mass or less relative to 100 parts by mass of the quantum dot (A).

Above method for replacing preferably include:

preparing a liquid including the quantum dots (A), the dispersion medium (B) and the preliminary dispersion medium (pB) by adding the dispersion medium to the preliminary dispersion, and
removing the preliminary dispersion medium (pB) from the liquid including the quantum dots (A), the dispersion medium (B), and the preliminary dispersion medium (pB). According to this method, the preliminary dispersion medium (pB) is replaced by the dispersion medium (B) because the preliminary dispersion medium (pB) is distilled off while the dispersion medium (B) is added.

Removal of the preliminary dispersion medium (pB) from the liquid including the quantum dots (A), the dispersion medium (B) and the preliminary dispersion medium (pB) may be removal of the preliminary dispersion medium (pB) alone or removal of the preliminary dispersion medium (pB) and the dispersion medium (B). Removal of the preliminary dispersion medium (pB) alone is generally difficult, and typically the preliminary dispersion medium (pB) is removed along with the dispersion medium (B). The removal of the preliminary dispersion medium (pB) may be conducted in any way as long as the desired amount of the preliminary dispersion medium (pB) can be removed. In terms of preventing an excessive decrease in the amount of dispersion medium (B), it is preferable that the removal of the preliminary dispersion medium (pB) is carried out under conditions where the amount of preliminary dispersion medium (pB) removed is greater than the amount of dispersion medium (B) removed.

For example, when the boiling point of the preliminary dispersion medium (pB) is lower than the boiling point of the dispersion medium (B), the preliminary dispersion medium (pB) can be preferentially removed by heating the liquid containing the quantum dots (A), the dispersion medium (B), and the preliminary dispersion medium (pB) at a temperature of the boiling point of the preliminary dispersion medium (pB) or higher and below the boiling point of the dispersion medium (B).

When the boiling point of the preliminary dispersion medium (pB) is higher than that of the dispersion medium (B), the vapor generated by heating the liquid including the quantum dots (A), the dispersion medium (B), and the preliminary dispersion medium (pB) is introduced into the condenser, and reflux is carried out by cooling in the condenser at a temperature at which the vapor of the preliminary dispersion medium (pB) is not sufficiently condensed while the vapor of the dispersion medium (B) condenses sufficiently. By doing so, the dispersion medium (B)-rich condensate can be refluxed into the liquid containing the quantum dots (A). Meanwhile, the preliminary dispersion medium (pB)-rich vapor is distilled off.

If the amount of the dispersion medium (B) that is distilled off along with the preliminary dispersion medium (pB) is too large, the above method may be carried out while adding dispersion medium (B) to the liquid containing the quantum dots (A).

Other methods other than those mentioned above for removing the preliminary dispersion medium (pB) from the liquid containing the quantum dots (A), the dispersion medium (B), and the preliminary dispersion medium (pB) include centrifugal separation, membrane separation methods using differences in molecular size, methods using differences in freezing point, freeze drying methods, and the like.

By the method described above, the quantum dot dispersion is obtained by removing the preliminary dispersion medium (pB) from the liquid containing the quantum dots (A), the dispersion medium (B), and the preliminary dispersion medium (pB). In this case, the amount of preliminary dispersion medium (pB) to be removed is not particularly limited, as long as the concentration of the quantum dots (A) in the quantum dot dispersion is within the desired range and the desired amount of organic solvent (B1) is present in the quantum dot dispersion. The amount of preliminary dispersion medium (pB) removed may be 50% by mass or more, 70% by mass or more, 90% by mass or more, or 100% of the mass of preliminary dispersion medium (pB) before removal.

In the method of producing the quantum dot dispersion described above, it is preferable that the quantum dots (A) are heated at 50° C. or higher and 300° C. or lower in the presence of organic solvent (B1) during or after the production of the quantum dot dispersion. The heating temperature is preferably 70° C. or higher and 270° C. or lower, and more preferably 100° C. or higher and 250° C. or lower. By doing so, it is easy to produce the quantum dot dispersion in which the quantum dots (A) are well dispersed.

### <Method for Producing the Quantum Dot-Containing Film Before Heating Subjected to the Heating Step Under the Low Oxygen Concentration Atmosphere>

A coating film consisting of the composition described above is dried and/or cured to form the quantum dot-containing film. When the composition for producing the quantum dot-containing film is photosensitive or heat-sensitive, the method for producing the quantum dot-containing film preferably includes varying the solubility of the quantum dot-containing film in an organic solvent or basic solution by exposing or heating the quantum dot-containing film. This could enable development and patterning of the quantum dot-containing film with organic solvents or basic solutions, or improve the resistance of the quantum dot-containing film to organic solvents or basic solutions. Exposure or heating of quantum dot-containing film to vary solubility of the quantum dot-containing film in organic solvents or basic solutions may be performed either before or after the heating step under the low oxygen concentration atmosphere.

When the composition is cured, a curing method is not particularly limited, and heating, light exposure, or a combination of heating and light exposure may be employed.

Typical examples of the method for producing the quantum dot-containing film subjected to a heating step under the low oxygen concentration atmosphere will now be described. The quantum dot-containing film may be directly formed on various functional layers in a laminated body, a light-emitting display element panel or the like, or may be formed on a substrate of any material such as a metal substrate, a glass substrate or the like, and then peeled from the substrate for use. In addition, the quantum dot-containing film may be formed in a region surrounded by light-shielding partition walls that define pixels in a light-emitting display element panel or the like.

First, the composition is coated on e.g. any substrate or a functional layer to form a coating film. Examples of the coating method include methods in which a contact transfer-type applicator such as a roll coater, a reverse coater or a bar coater, and a non-contact type applicator such as a spinner (a rotary applicator), a slit coater, or a curtain flow coater are used. After adjusting the viscosity of the composition within an appropriate range, the composition may be coated by a printing method such as ink-jet printing or screen printing to form a coating film which is patterned into a desired shape.

Then, a volatile component such as the solvent (S) is removed as needed to dry the coating film. The method of drying is not particularly limited, and examples thereof include a method in which the coating film is dried under reduced pressure at room temperature using a vacuum dryer (VCD) and then dried on a hot plate at a temperature of 60° C. or higher and 120° C. or lower, and preferably 70° C. or higher and 100° C. or lower, for 60 seconds or longer and 180 seconds or shorter. After forming the coating film in this manner, the coating film is subjected to light exposure and/or heating.

Light exposure is carried out by irradiation with active energy rays such as excimer laser light. The dose of energy used in the irradiation varies depending on the composition of the composition, and is for example preferably 30 mJ/cm² or more and 2,000 mJ/cm² or less, and more preferably 50 mJ/cm² or more and 500 mJ/cm² or less. By such exposure, exposed portion is cured when the composition is a negative type, and exposed portion is solubilized in a developing solution such as a basic solution when the composition is a positive type.

The temperature for heating is not particularly limited, and is preferably 180° C. or higher and 280° C. or lower, more preferably 200° C. or higher and 260° C. or lower, and particularly preferably 220° C. or higher and 250° C. or lower. The heating time is typically preferably 1 minute or longer and 60 minutes or shorter, more preferably 10 minutes or longer and 50 minutes or shorter, and particularly preferably 20 minutes or longer and 40 minutes or shorter. An atmosphere when above heating is conducted is not particularly limited. An atmosphere when above heating is conducted may be the low oxygen concentration atmosphere.

It should be noted that in the case in which the composition includes a silicon-containing resin as the base component (C), a coating film of the composition is baked to produce the quantum dot-containing film. In this case, the material of the substrate is not particularly limited as long as the material can withstand the baking. Preferable examples of the material of the substrate include inorganic materials such as metals, silicon, and glass, and heat-resistant materials such as polycarbonate, polyethylene terephthalate, polyethersulfone, polyimide resin, and polyamide imide resin. The thickness of the substrate is not particularly limited, and the substrate may be in the form of a film or a sheet.

The substrate including the coating film is then baked. The baking method is not particularly limited, but the baking is typically conducted using electric furnace or the like. Typically, the baking temperature is preferably 300° C. or higher, and more preferably 350° C. or higher. The upper limit of the baking temperature is not particularly limited, but is, for example, 1,000° C. or lower. In the case in which the composition includes the curing agent (D4), the quantum dot-containing film, which is a silica film, can have a reduced amount of residue (impurities derived from the silica film) even when the lower limit of the baking temperature is decreased to 200° C. A baking atmosphere is not particularly limited, and the baking may be conducted in an inert gas atmosphere such as a nitrogen atmosphere or an argon atmosphere, under vacuum, or under reduced pressure. The baking may be conducted in ambient air, or under appropriate control of the oxygen concentration.

The film thickness of the dot-containing film is not particularly limited. The film thickness of the quantum dot-containing film is typically 0.1 μm or more and 10 μm or less, preferably 0.2 μm or more and 5 μm or less, and more preferably 0.5 μm or more and 3 μm or less.

The quantum dot-containing film exhibiting desired quantum yield can be produced by subjecting the quantum dot-containing film formed in this way to the heating step under the low oxygen concentration atmosphere.

### «Quantum Dot-Containing Film»

The quantum dot-containing film produced by the above method may or may not include the organic solvent (S1). The quantum dot-containing film preferably includes the organic solvent (S1), since quantum yield can be recovered by heating the quantum dot-containing film under the low oxygen concentration atmosphere again, when quantum yield of the quantum dot-containing film is lowered. A content of the organic solvent (S1) is not particularly limited. The quantum dot-containing film preferably includes an amount that can improve the quantum yield by heating under the low oxygen concentration atmosphere of the organic solvent (S1). The quantum dot-containing film is suitably used as an optical film for a light-emitting display element.

The film thickness of the dot-containing film is not particularly limited. The film thickness of the dot-containing film is typically 0.1 μm or more and 10 μm or less, preferably 0.2 μm or more and 5 μm or less, and more preferably 0.5 μm or more and 3 μm or less.

A quantum dot-containing film including quantum dots (A) formed by the method described above can be suitably used as an optical film for a light-emitting display element because of good fluorescence efficiency. The quantum dot-containing film also can be suitably used to produce a laminated body suitably used in a light-emitting display element.

### «Laminated Body»

The laminated body is a laminated body including the dot-containing film formed by the aforementioned method. Such a laminated body can be a laminated body made of only a dot-containing film including the quantum dots (A), or a laminated body made of a dot-containing film including the quantum dots (A) and other functional layers.

### <Laminated Body of Quantum Dot-Containing Film>

In Laminated body, for example, two or more quantum dot-containing films including quantum dots (A) dispersed in various matrix materials derived from the base component (C) are laminated. Such a laminated body may be a laminated body in which only quantum dot-containing films formed by the aforementioned method are laminated, or a laminated body in which a quantum dot-containing film formed by the aforementioned method, and another film including quantum dots (A) formed by a method other than the aforementioned method are laminated.

It is preferred that the quantum dot-containing film includes quantum dots producing red light by wavelength conversion of incident light from a light source, and quantum dots producing green light by wavelength conversion of incident light from a light source. It is also preferred that a film including quantum dots producing red light and a film including quantum dots producing green light be alternately laminated. When a laminated body having such a structure is applied to a light-emitting display element panel, because green light and red light having high color purity can be extracted by wavelength conversion, the range of hue reproduction in a light-emitting display equipped with the light-emitting display element panel can be enlarged. It should be noted that blue light and white light can be typically used as a light source. Red light, green light and blue light having high color purity can be extracted by using such a light source in combination with the above laminated body, and a clear image with good hues can be shown.

The light-emitting display is not particularly limited as long as it is a device to show an image using light emission of a light source, and examples thereof include a liquid crystal display, an organic EL display and the like.

### <Laminated Body Including Film Including Quantum Dots (A) and Other Functional Layers>

It is also preferred that the quantum dot-containing film formed by the aforementioned method is laminated with other functional layers. It is preferred that a quantum dot-containing film include quantum dots producing red light by wavelength conversion of incident light from a light source, and quantum dots producing green light by wavelength conversion of incident light from a light source. In addition, blue light and white light can be typically used as a light source.

Examples of other functional layers include a diffusion layer to diffuse light rays, a low refractive index layer having a lower refractive index than that of the quantum dot-containing film, a reflection layer to reflect part of the incident light from a light source, a light guide plate to allow light emitted by a light source to enter the laminated body and the like. In addition, a gap may be provided in the laminated body as needed. The gap may be, for example, an air layer, and a layer of an inert gas such as nitrogen.

As the diffusion layer, various diffusion layers which have been conventionally used for various displays and optical devices can be used without particular limitation. Typical examples thereof include a film having a fine structure such as a prism on the surface thereof, a film in which beads are scattered or embedded on the surface thereof, and a film including fine particles and e.g. an interface or a gap structured to scatter light rays in the inside thereof.

The low refractive index layer is not particularly limited as long as it is a film having a lower refractive index than that of the above-described quantum dot-containing film and the above-described silica film, and films made of various materials can be used.

Examples of the reflection layer include a reflective polarizing film, a film having a fine structure such as a prism on the surface thereof to reflect part of the incident light, a metallic foil, a multilayer optical film and the like. The reflection layer reflects preferably 30% or more of the incident light, more preferably 40% or more and particularly preferably 50% or more. It is preferred that the reflection layer be provided so that light having passed through a quantum dot-containing film is reflected and reflected light is allowed to enter the quantum dot-containing film again. The color purity of green light and red light emitted from a quantum dot-containing film can be increased by reflecting light incident from a reflection layer to a quantum dot-containing film in the direction of the reflection layer again by e.g. a diffusion layer, compared to a case where a reflection layer is not used.

As the light guide plate, various light guide plates which have been conventionally used for various displays and optical devices can be used without particular limitation.

Typical examples of preferred layer constitution of the laminated body including a quantum dot-containing film and other functional layers include layer constitution in 1) to 8) below. It should be noted that in laminated bodies having the constitution in 1) to 8), light rays emitted from a light source are allowed to enter the layer described on the leftmost end, and light rays after wavelength conversion by a quantum dot-containing film are extracted from the layer described on the rightmost end. A display panel is commonly provided so that light rays extracted from a laminated body are allowed to enter, and red light, green light and blue light having high color purity are used to show an image.

1) Diffusion layer/quantum dot-containing film/low refractive index layer/reflection layer,
2) light guide plate/diffusion layer/quantum dot-containing film/low refractive index layer/reflection layer,
3) low refractive index layer/quantum dot-containing film/gap/reflection layer,
4) light guide plate/low refractive index layer/quantum dot-containing film/gap/reflection layer,
5) low refractive index layer/quantum dot-containing film/low refractive index layer/reflection layer,
6) light guide plate/low refractive index layer/quantum dot-containing film/low refractive index layer/reflection layer, 7) reflection layer/low refractive index layer/quantum dot-containing film/low refractive index layer/reflection layer, and
8) light guide plate/reflection layer/low refractive index layer/quantum dot-containing film/low refractive index layer/reflection layer.

### «Light-Emitting Display Element Panel and Light-Emitting Display»

The quantum dot-containing film formed using the above-described composition and the above-described laminated body are incorporated into various light-emitting display element panels, and are preferably used to extract red light, green light and blue light having high color purity from light rays emitted from a light source. Here, “quantum dot sheet” is a general term for the quantum dot-containing film formed using the above-described composition and the above-described laminated body.

The light-emitting display element panel typically includes the combination of a backlight as a light source, a quantum dot sheet and a display panel. When the quantum dot sheet is equipped with a light guide plate, a light source is typically provided so that light rays are allowed to enter the lateral side of the light guide plate. The light rays having entered from the lateral side of the light guide plate pass through the quantum dot sheet and enter the display panel. When the quantum dot sheet is not equipped with a light guide plate, light rays from a surface light source are allowed to enter the main surface of the quantum dot sheet, and light rays having passed through the quantum dot sheet are allowed to enter the display panel. The type of the display panel is not particularly limited as long as an image can be formed using light rays having passed through a quantum dot sheet, and the type is typically a liquid crystal display panel.

Because red light, green light and blue light having particularly high color purity are easily extracted from light rays emitted from a light source, the quantum dot sheet is preferably the above-described laminated body. When the quantum dot sheet is a laminated body, preferred combinations of constitution of a light-emitting display element panel include the following a) to h) combinations. In the combinations described in a) to h) below, laminating is carried out from the constitution described on the leftmost end in the order described to form a light-emitting display element panel.

a) Surface light source/diffusion layer/quantum dot sheet/low refractive index layer/reflection layer/display panel,
b) light guide plate with light source/diffusion layer/quantum dot sheet/low refractive index layer/reflection layer/display panel,
c) surface light source/low refractive index layer/quantum dot sheet/gap/reflection layer/display panel,
d) light guide plate with light source/low refractive index layer/quantum dot sheet/gap/reflection layer/display panel,
e) surface light source/low refractive index layer/quantum dot sheet/low refractive index layer/reflection layer/display panel,
f) light guide plate with light source/low refractive index layer/quantum dot sheet/low refractive index layer/reflection layer/display panel,
g) surface light source/reflection layer/low refractive index layer/quantum dot sheet/low refractive index layer/reflection layer/display panel, and
h) light guide plate with light source/reflection layer/low refractive index layer/quantum dot sheet/low refractive index layer/reflection layer/display panel.

By using the light-emitting display element panel described above, a light-emitting display, which has a wide range of hue reproduction and can show a clear image with good hues, can be produced.

### EXAMPLES

Hereinafter, the present invention is described in more detail by way of Examples, but the present invention is not limited to these Examples.

In following examples, following PEMP and TMMP were used as the organic solvent (S1). Boiling points of PEMP and TMMP at atmospheric pressure are described below.

PEMP: Pentaerythritol tetra-3-mercaptopropionate (boiling point 250° C.)
TMMP: Trimethylolpropane tri-3-mercaptopropionate (boiling point 220° C.)

### Preparation Example 1

0.6 g of preliminary dispersion containing quantum dots (emission maximum 630 nm) in which ligands coordinated to particles with a core made of InP coated with a shell layer made of ZnS at a concentration of 20% by mass was added in a glass vessel. Under an inert gas atmosphere, preliminary dispersion was heated at 120° C. for 20 minutes to remove propylene glycol monomethyl ether acetate to obtain solid quantum dots in a glass vessel. To a glass vessel containing 0.12 g of solid quantum dots, 0.5 g of PEMP was added as organic solvent (S1), and the quantum dots were dispersed in the organic solvent (S1) to obtain a quantum dot dispersion.

### Preparation Example 2

0.5 g of preliminary dispersion containing quantum dots (emission maximum 630 nm) in which ligands coordinated to particles with a core made of InP coated with a shell layer made of ZnS at a concentration of 20% by mass was added in a glass vessel. Then, 0.5 g of PEMP was added as organic solvent (B1) in the glass vessel. Liquid in the glass vessel was heated at 200° C. for 1 hour to distill off propylene glycol monomethyl ether acetate to obtain quantum dot dispersion containing 0.12 g of quantum dots in 0.5 g of PEMP.

### Preparation Example 3

The quantum dot dispersion was obtained in the same manner as in Preparation Example 2, except that PEMP was changed to TMMP.

### Preparation Example 4

The quantum dot dispersion solution was obtained in the same manner as in Preparation Example 3, except that the quantum dots used in Preparation Example 3 were changed to quantum dots (emission maximum 620 nm) consisting of particles with a core made of InP coated with a shell layer made of ZnS and a ligand coordinated to the core (emission maximum 620 nm).

### Preparation Example 5

The quantum dot dispersion solution was obtained in the same manner as in Preparation Example 3, except that the quantum dots used in Preparation Example 3 were changed to quantum dots (emission maximum 530 nm) consisting of particles with a core made of InP coated with a shell layer made of ZnS and a ligand coordinated to the core.

### Preparation Example 6

A dispersion of quantum dots (emission maximum of 630 nm) consisting of particles with a core made of InP coated with a shell layer made of ZnS and a ligand coordinated to the core in propylene glycol monomethyl ether acetate with a concentration of 20% by mass was used.

Using the quantum dot dispersions of the above preparation examples, quantum yield was evaluated according to following method. First, 0.6 g of the quantum dot dispersions of the types listed in Table 1 were mixed with 0.5 g of the negative type photosensitive composition to prepare photosensitive compositions for producing film containing quantum dots. Composition consisting of 35 parts by mass of alkali-soluble resin and 7 parts by mass of dipentaerythritol hexaacrylate as the base component (C), 4 parts by mass of photopolymerization initiator having following structure as the curing agent, 0.7 parts by mass of 3-methacryloxypropyltrimethoxysilane, and 54 parts by mass of propylene glycol monomethyl ether acetate as the solvent (S) was used as negative type photosensitive composition. A resin consisting of the following constituent units was used as an alkali-soluble resin. The numerical character on the lower right of the parentheses in each constituent unit represents the molar ratio of constituent unit in the resin.

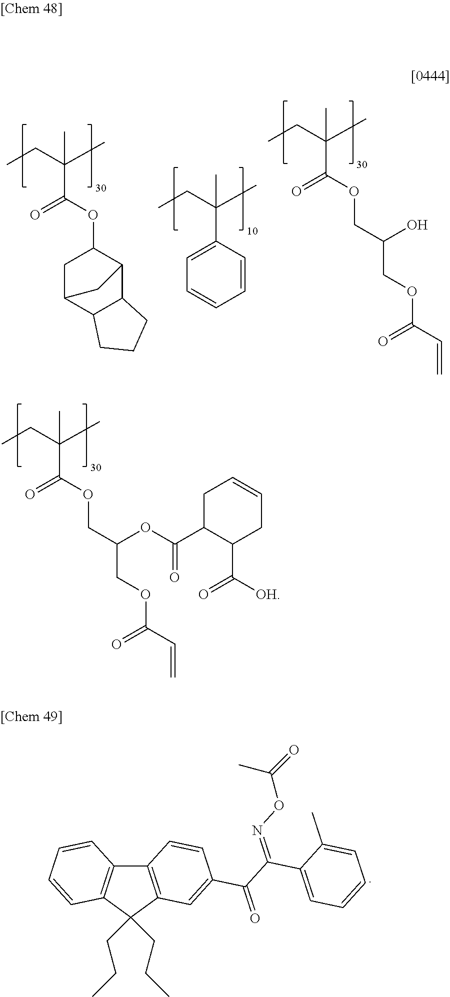

The obtained compositions for producing film were applied to glass substrates by spin-coating method to form coating films with a thickness of 5 μm. Quantum yields of the formed coating films were measured using Quantaurus-QY C11347 (Hamamatsu Photonics, Inc.). Quantum yields of films are noted as QY1 in Table 1. Then, the coating films were baked at 100° C. in air, and the entire surface of the coating films was exposed and cured at an exposure amount of 50 mJ/cm². Quantum yields of the obtained cured films were measured. Quantum yields of cured films are noted as QY2 in Table 1. Further, cured films were baked at 200° C. for 60 minutes under nitrogen atmosphere. Quantum yields of cured films baked were measured. Quantum yields of cured films after baking under nitrogen atmosphere is noted as QY3 in Table 1.

TABLE 1

| | | Quantum | | | | | QY3 |
|---|---|---|---|---|---|---|---|
| | | dot | | Preparation | | | Cured film |
| | Quantum | (Core/Shell/ | Organic | method of | QY1 | | (After baking |
| | dot | Emission | solvent | Quantum dot | Coating | QY2 | under N₂ |
| | dispersion | maximum) | (S1) | dispersion | film | Cured film | atmosphere) |
| Ex. 1 | Preparation | InP/ZnS/ | PEMP | 1st: Drying | 71.7% | 65.5% | 66.4% |
| | Ex. 1 | 630 nm | | 2nd: Addition | | | |
| | | | | of Organic | | | |
| | | | | solvent (B1) | | | |
| Ex. 2 | Preparation | InP/ZnS/ | PEMP | 1st: Addition | 70.5% | 65.3% | 68.0% |
| | Ex. 2 | 630 nm | | of Organic | | | |
| Ex. 3 | Preparation | InP/ZnS/ | TMMP | solvent (B1) | 68.0% | 63.1% | 68.2% |
| | Ex. 3 | 630 nm | | 2nd: | | | |
| Ex. 4 | Preparation | InP/ZnS/ | TMMP | Distillation | 71.8% | 66.4% | 72.6% |
| | Ex. 4 | 620 nm | | of preliminary | | | |
| Ex. 5 | Preparation | InP/ZnS/ | TMMP | dispersion | 48.5% | 42.9 | 50.4% |
| | Ex. 5 | 530 nm | | medium | | | |
| Comp. Ex.l | Preparation | InP/ZnS/ | — | — | 58.0% | 44.0% | 41.0% |
| | Ex. 6 | 630 nm | | | | | |

According to table 2, from comparison between QY1 and QY2, it is shown that quantum yield was lowered by baking and exposure in air. However, in all Examples where the compositions for producing quantum dot-containing films were prepared using organic solvents (S1) containing chalcogen elements, the quantum yield was recovered by baking the cured films under nitrogen atmosphere. On the other hand, in Comparative Example 1 on a composition for producing quantum dot-containing film prepared using quantum dot dispersion that do not contain the organic solvent (S1) containing chalcogen elements, quantum yield lowered by baking and exposure in air was not recovered by baking the cured film under nitrogen atmosphere.

1. A method for producing a quantum dot-containing film using a composition comprising quantum dots (A), a base component (C) and a solvent (S), wherein a material of surface of the quantum dots (A) comprises a chalcogenide,
a ligand can bound to the surface of the quantum dots (A),
the solvent (S) comprises an organic solvent (S1) comprising a chalcogen element, and the method comprising heating the quantum dot-containing film in an atmosphere with a lower oxygen concentration than air.

2. The method for producing the quantum dot-containing film according to claim 1,
wherein the quantum dots (A) are heated at 50° C. or higher and 300° C. or lower in the presence of organic solvent (B1) during or after the production of the composition.

3. The method for producing the quantum dot-containing film according to claim 1,
wherein the content of the organic solvent (S1) in the composition is 10 parts by mass or more and 2000 parts by mass or less relative to 100 parts by mass of the quantum dots (A).

4. The method for producing the quantum dot-containing film according to claim 1,
wherein a boiling point of the organic solvent (S1) under atmospheric pressure is 60° C. or higher and 400° C. or lower.

5. The method for producing the quantum dot-containing film according to claim 1, comprising varying solubility of the quantum dot-containing film in organic solvents or basic solutions by exposure of heating.

6. A composition for producing a quantum dot-containing film comprising quantum dots (A), a base component (C),
wherein a material of surface of the quantum dots (A) comprises a chalcogenide,
a ligand can bound to the surface of the quantum dots (A), and
the solvent (S) comprises an organic solvent (S1) comprising a chalcogen element.

7. The composition for producing the quantum dot-containing film according claim 6,
wherein the content of the organic solvent (S1) is 10 parts by mass or more and 2000 parts by mass or less relative to 100 parts by mass of the quantum dots (A).

8. The composition for producing the quantum dot-containing film according to claim 6,
wherein a boiling point of the organic solvent (S1) under atmospheric pressure is 60° C. or higher and 400° C. or lower.
